(19) United States
(12) Patent Application Publication
(10) Pub. No.: US 2026/0068324 A1
(43) Pub. Date: Mar. 5, 2026

(54) INTEGRATED CIRCUIT AND METHOD OF FORMING THE SAME

(71) Applicant: TAIWAN SEMICONDUCTOR MANUFACTURING COMPANY, LTD., Hsinchu (TW)

(72) Inventors: Wen-Sheng CHEN, Hsinchu (TW); Wei Ling CHANG, Hsinchu (TW)

(21) Appl. No.: 18/825,262

(22) Filed: Sep. 5, 2024

(51) Int. Cl. H01L 27/02; H01L 21/8234; H01L 29/423

(52) U.S. Cl. CPC H10D 89/10; H10D 64/518; H10D 84/0142; H10D 84/038

(57) ABSTRACT

An integrated circuit includes a first set of active regions and a first and second set of gates. The first set of active regions extends in a first direction, and is on a first level. The first set of active regions corresponds to a first transistor. The second set of gates extends in a second direction, are on a second level, and overlaps the first set of active regions. The first set of gates corresponds to the first transistor. Each gate of the first set of gates is separated from an adjacent gate of the second set of gates in the second direction by a first pitch. Each gate of the second set of gates is separated from an adjacent gate of the second set of gates in the second direction by a second pitch different from the first pitch.

### BACKGROUND

The recent trend in miniaturizing integrated circuits (ICs) has resulted in smaller devices which consume less power yet provide more functionality at higher speeds. The miniaturization process has also resulted in stricter design and manufacturing specifications as well as reliability challenges. Various electronic design automation (EDA) tools generate, optimize and verify standard cell layout designs for integrated circuits while ensuring that the standard cell layout design and manufacturing specifications are met.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a schematic diagram of an integrated circuit, in accordance with some embodiments.

FIG. 1B is a schematic diagram of an integrated circuit, in accordance with some embodiments.

FIG. 2A is a schematic diagram of an integrated circuit, in accordance with some embodiments.

FIG. 2B is a schematic diagram of an integrated circuit, in accordance with some embodiments.

FIGS. 3A and 3B are diagrams of an integrated circuit, in accordance with some embodiments.

FIGS. 3C and 3D are diagrams of an integrated circuit, in accordance with some embodiments.

FIGS. 4A and 4B are diagrams of an integrated circuit, in accordance with some embodiments.

FIGS. 4C and 4D are diagrams of an integrated circuit, in accordance with some embodiments.

FIG. 5A is a diagram of an integrated circuit, in accordance with some embodiments.

FIG. 5B is a diagram of an integrated circuit, in accordance with some embodiments.

FIG. 6A is a diagram of an integrated circuit, in accordance with some embodiments.

FIG. 6B is a diagram of an integrated circuit, in accordance with some embodiments.

FIG. 7 is a diagram of an integrated circuit, in accordance with some embodiments.

FIG. 8 is a diagram of an integrated circuit, in accordance with some embodiments.

FIGS. 9A-9C are diagrams of an integrated circuit, in accordance with some embodiments.

FIG. 10 is a flowchart of a method of forming or manufacturing an integrated circuit in accordance with some embodiments.

FIG. 11 is a flowchart of a method of generating a layout design of an integrated circuit, in accordance with some embodiments.

FIG. 12 is a schematic view of a system for designing an integrated circuit (IC) layout design and manufacturing an IC circuit in accordance with some embodiments.

FIG. 13 is a block diagram of an IC manufacturing system, and an IC manufacturing flow associated therewith, in accordance with at least one embodiment of the present disclosure.

FIG. 14 is a functional flow chart of a method of manufacturing an IC device, in accordance with some embodiments.

### DETAILED DESCRIPTION

The following disclosure provides different embodiments, or examples, for implementing features of the provided subject matter. Specific examples of components, materials, values, steps, arrangements, or the like, are described below to simplify the present disclosure. These are, of course, merely examples and are not limiting. Other components, materials, values, steps, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In accordance with some embodiments, an integrated circuit includes a first set of active regions extending in a first direction, and being on a first level of a substrate, the first set of active regions corresponding to a first transistor.

In some embodiments, the first set of active regions extends in a first direction, and is on a first level of a substrate. In some embodiments, the first set of active regions corresponds to a first transistor.

In some embodiments, the integrated circuit further includes a first set of gates. In some embodiments, the first set of gates extends in a second direction different from the first direction. In some embodiments, the first set of gates is on a second level different from the first level. In some embodiments, the first set of gates overlaps the first set of active regions. In some embodiments, the first set of gates corresponds to the first transistor.

In some embodiments, the integrated circuit further includes a second set of gates. In some embodiments, the second set of gates extends in the second direction, is on the second level, overlaps the first set of active regions, and is separated from the first set of gates in the first direction.

In some embodiments, each gate of the first set of gates is separated from an adjacent gate of the second set of gates in the second direction by a first pitch.

In some embodiments, each gate of the second set of gates is separated from an adjacent gate of the second set of gates in the second direction by a second pitch different from the first pitch.

In some embodiments, by the integrated circuit including adjacent gates with different pitches, the integrated circuit has different electrical characteristics resulting in a more flexible design than other approaches, thereby resulting in improved performance than other approaches.

In some embodiments, the different electrical characteristics include one or more of intrinsic gain (gm/gds), parasitic capacitance, reduced resistance or noise figure (NF).

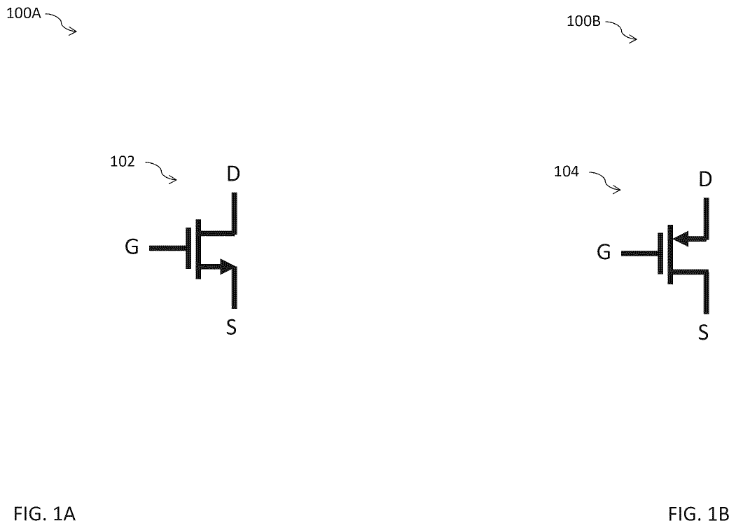

FIG. 1A is a schematic diagram of an integrated circuit 100A, in accordance with some embodiments.

Integrated circuit 100A comprises a transistor 102.

Transistor 102 is an N-type transistor. In some embodiments, transistor 102 is an N-type Metal Oxide Semiconductor (NMOS) transistor. Other transistor types for transistor 102 are within the scope of the present disclosure.

In some embodiments, transistor 102 is a fin field-effect transistor (FinFET). In some embodiments, transistor 102 is one or more of a nanosheet transistor, a nanowire transistor or a planar transistor.

Other configurations or transistor types for integrated circuit 100A types are within the scope of the present disclosure. Examples of transistors for at least integrated circuit 100A, 100B, 200A or 200B (described below) include, but are not limited to, metal oxide semiconductor field effect transistors (MOSFET), complementary metal oxide semiconductor (CMOS) transistors, bipolar junction transistors (BJT), high voltage transistors, high frequency transistors, p-channel and/or n-channel field effect transistors (PFETs/NFETs), etc.), FinFETs, and planar MOS transistors with raised source/drain.

FIG. 1B is a schematic diagram of an integrated circuit 100B, in accordance with some embodiments.

Integrated circuit 100B comprises a transistor 104.

Components that are the same or similar to those in one or more of FIGS. 1A-1B, 2A-2B, 3A-3D, 4A-4D, 5A-5B, 6A-6B, 7A-7B, 8A-8B and 9A-9C (shown below) are given the same reference numbers, and detailed description thereof is thus omitted.

Transistor 104 is an P-type transistor. In some embodiments, transistor 104 is an P-type Metal Oxide Semiconductor (PMOS) transistor. Other transistor types for transistor 104 are within the scope of the present disclosure.

In some embodiments, transistor 104 is a FinFET. In some embodiments, transistor 104 is one or more of a nanosheet transistor, a nanowire transistor or a planar transistor.

Other configurations or transistor types for integrated circuit 100B types are within the scope of the present disclosure.

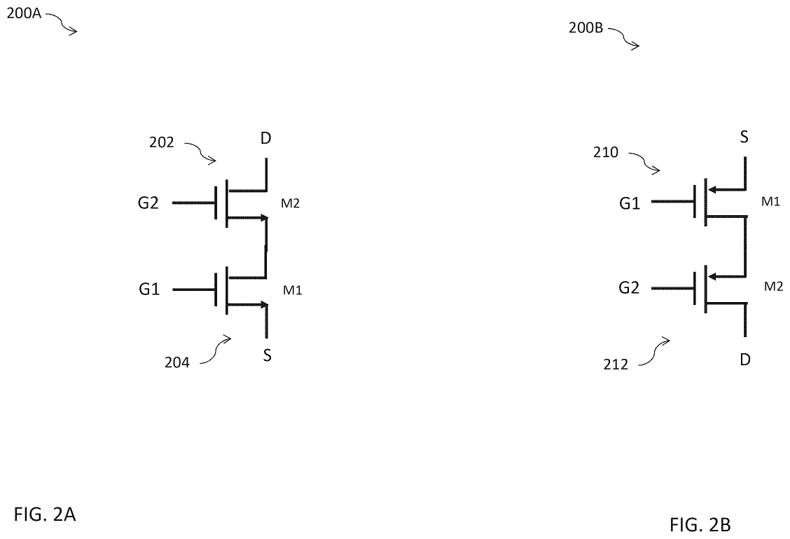

FIG. 2A is a schematic diagram of an integrated circuit 200A, in accordance with some embodiments.

Integrated circuit 200A comprises a transistor 202 and a transistor 204.

Transistors 202 and 204 are N-type transistors. In some embodiments, at least one of transistor 202 or 204 is an NMOS transistor. Other transistor types for at least one of transistor 202 or 204 are within the scope of the present disclosure.

In some embodiments, at least one of transistor 202 or 204 is a FinFET. In some embodiments, at least one of transistor 202 or 204 is one or more of a nanosheet transistor, a nanowire transistor or a planar transistor.

Transistor 202 is coupled to transistor 204. In some embodiments, transistors 202 and 204 are arranged in a cascode structure. In some embodiments, transistor 202 is arranged in a common gate (CG) configuration, and transistor 204 is arranged in a common source (CS) configuration.

In some embodiments, a gate G1 of transistor 204 is configured to receive an input signal (not labelled).

In some embodiments, a source S of transistor 204 is coupled to a ground terminal or a reference supply voltage VSS.

In some embodiments, a drain of transistor 204 is coupled to a source of transistor 202. In some embodiments, the source of transistor 202 is configured as an input node configured to receive an intermediate output signal (not labelled) from the drain of transistor 204.

In some embodiments, a gate G2 of transistor 202 is coupled to the ground terminal or the reference supply voltage VSS. In some embodiments, the gate G2 of transistor 202 is coupled to source S of transistor 204.

In some embodiments, the drain of transistor 202 is configured as an output node configured to output an output signal (not labelled) from the drain of transistor 202.

In some embodiments, transistor 202 and transistor 204 are arranged in a stacked configuration.

Other configurations or transistor types for integrated circuit 200A types are within the scope of the present disclosure.

FIG. 2B is a schematic diagram of an integrated circuit 200B, in accordance with some embodiments.

Integrated circuit 200B comprises a transistor 210 and a transistor 212.

Transistors 210 and 212 are P-type transistors. In some embodiments, at least one of transistor 210 or 212 is a PMOS transistor. Other transistor types for at least one of transistor 210 or 212 are within the scope of the present disclosure.

In some embodiments, at least one of transistor 210 or 212 is a FinFET. In some embodiments, at least one of transistor 210 or 212 is one or more of a nanosheet transistor, a nanowire transistor or a planar transistor.

Transistor 210 is coupled to transistor 212. In some embodiments, transistors 210 and 212 are arranged in a cascode structure. In some embodiments, transistor 212 is arranged in a CG configuration, and transistor 210 is arranged in a CS configuration.

In some embodiments, a gate G1 of transistor 210 is configured to receive an input signal (not labelled).

In some embodiments, a source S of transistor 210 is coupled to a voltage supply terminal or a supply voltage VDD.

In some embodiments, a drain of transistor 210 is coupled to a source of transistor 212. In some embodiments, the source of transistor 212 is configured as an input node configured to receive an intermediate output signal (not labelled) from the drain of transistor 210.

In some embodiments, a gate G2 of transistor 212 is coupled to the ground terminal or the reference supply voltage VSS.

In some embodiments, the drain of transistor 212 is configured as an output node configured to output an output signal (not labelled) from the drain of transistor 212.

In some embodiments, transistor 210 and transistor 212 are arranged in a stacked configuration.

Other configurations or transistor types for integrated circuit 200B types are within the scope of the present disclosure.

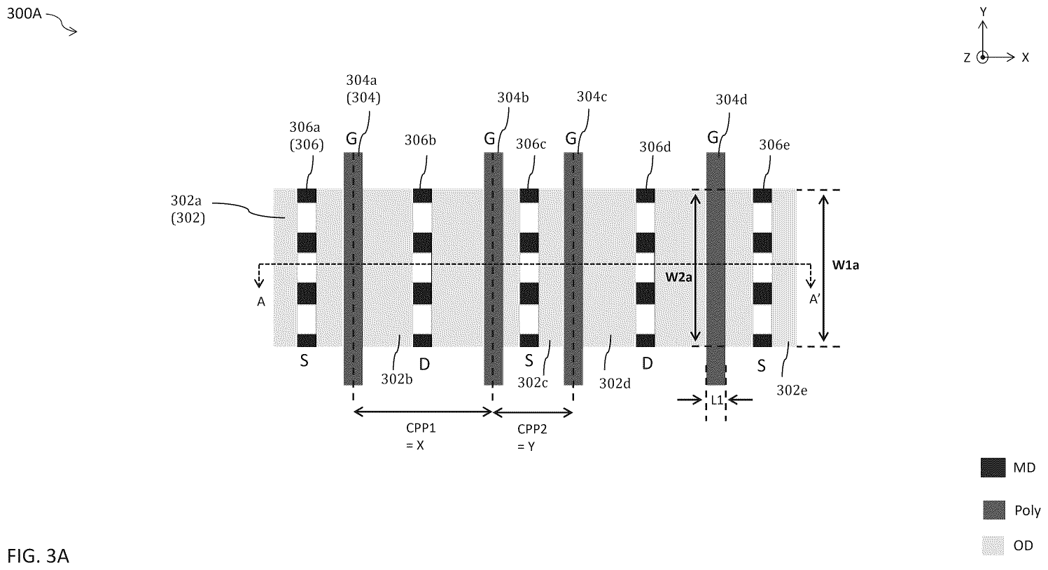

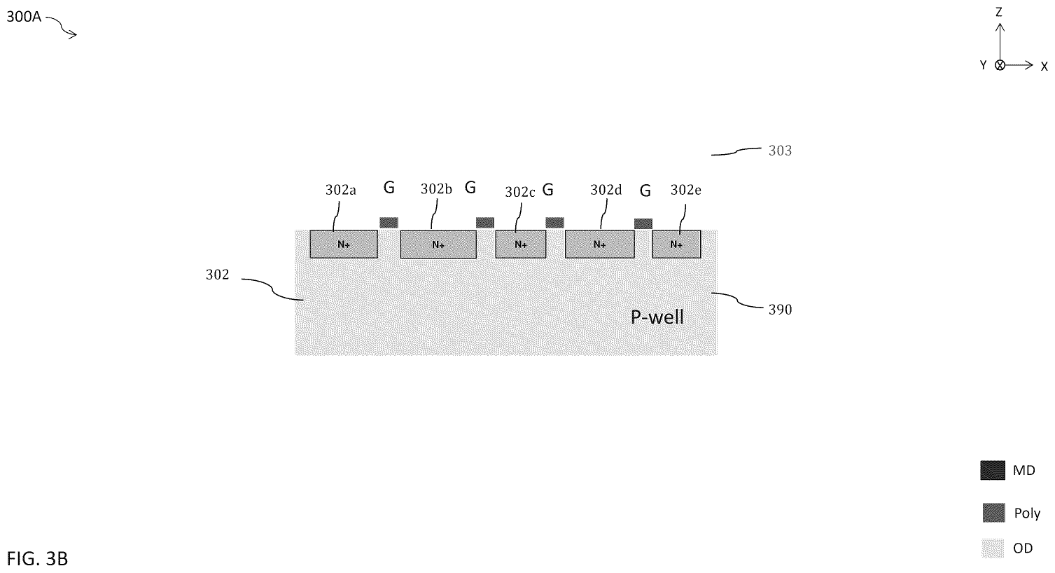

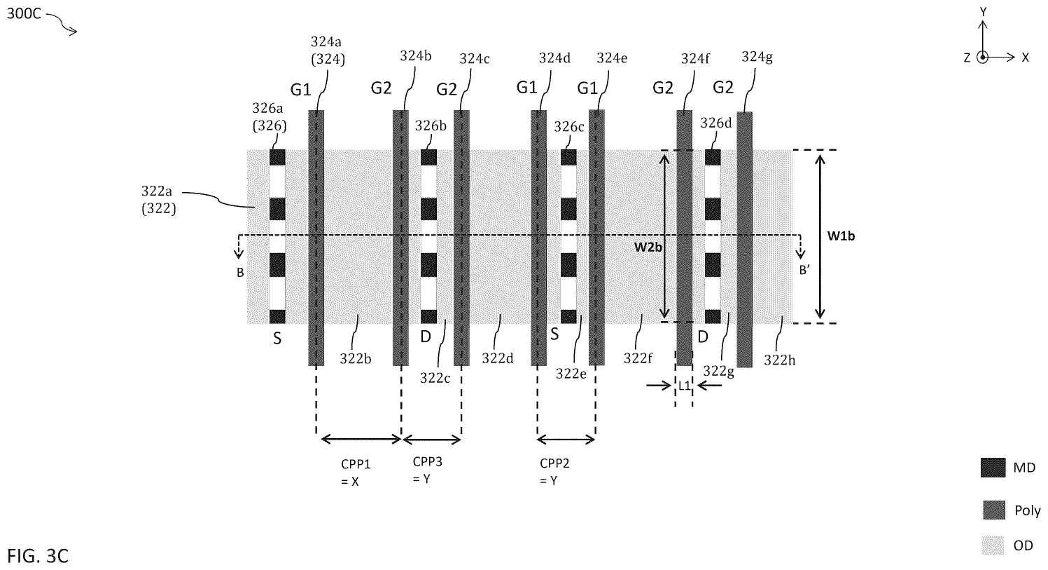

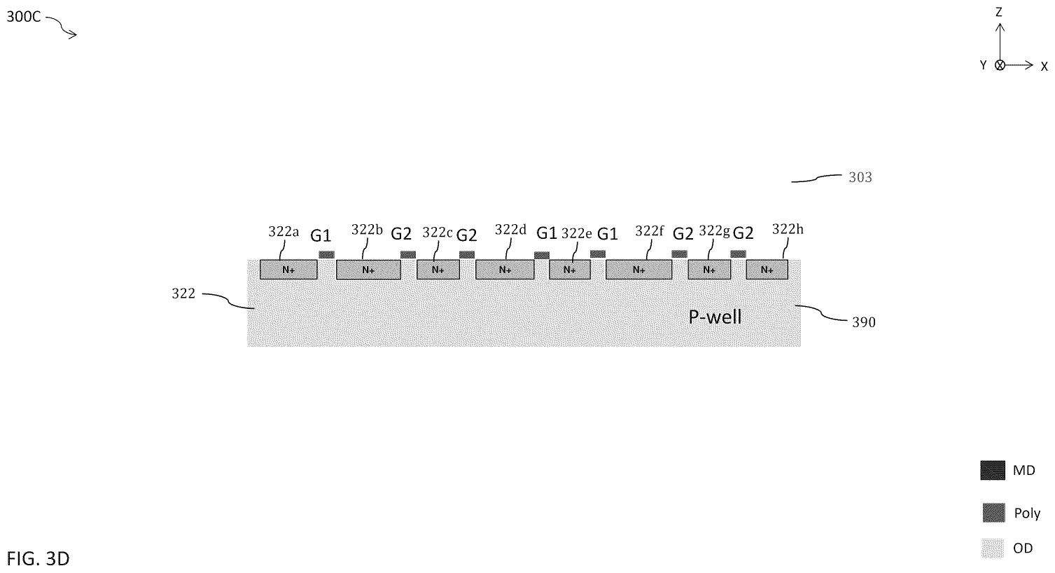

FIGS. 3A and 3B are diagrams of an integrated circuit 300A, in accordance with some embodiments.

FIG. 3A is a top view of integrated circuit 300A, in accordance with some embodiments.

FIG. 3B is a cross-sectional view of integrated circuit 300A, in accordance with some embodiments.

FIGS. 3C and 3D are diagrams of an integrated circuit 300C, in accordance with some embodiments.

FIG. 3C is a top view of integrated circuit 300C, in accordance with some embodiments.

FIG. 3D is a cross-sectional view of integrated circuit 300C, in accordance with some embodiments.

Integrated circuit 300A is an embodiment of integrated circuit 100A of FIG. 1A, and similar detailed description is therefore omitted.

FIG. 3B is a cross-sectional view of integrated circuit 300A as intersected by plane A-A′, in accordance with some embodiments.

Integrated circuits 300A and 300C are manufactured by a corresponding layout design similar to integrated circuits 300A and 300C. For brevity FIGS. 3A, 3C, 4A, 4C, 5A, 5B, 6A, 6B, 7A, 7B, 8A, 8B, 9A, 9B, 9C, 10, 11, 12, 13 and 14 are described as corresponding integrated circuit 300A, 300C, 400A, 400C, 500A, 500B, 600A, 600B, 700, 800, 900. In some embodiments, each of FIGS. 3A, 3B, 3C, 3D, 4A, 4B, 4C, 4D, 5A, 5B, 6A, 6B, 7A, 7B, 8A, 8B, 9A, 9B and 9C is also a corresponding layout design, and each structural element of integrated circuit 300A, 300C, 400A, 400C, 500A, 500B, 600A, 600B, 700, 800, 900 is a corresponding layout pattern, and structural relationships including alignment, lengths and widths, as well as configurations and layers of a corresponding layout design of integrated circuit 300A, 300C, 400A, 400C, 500A, 500B, 600A, 600B, 700, 800, 900 are similar to the structural relationships and configurations and layers of integrated circuit 300A, 300C, 400A, 400B, 400C, 400D, 500A, 500B, 600A, 600B, 700, 800, 900, and similar detailed description will not be described for brevity.

Integrated circuit 300A includes a substrate 390 (FIGS. 3B and 3D). In some embodiments, substrate 390 is a p-type substrate. In some embodiments, substrate 390 is a p-type well in an underlaying substrate (not shown). In some embodiments, substrate 390 includes an elemental semiconductor including silicon or germanium in crystal, polycrystalline, or an amorphous structure; a compound semiconductor including silicon carbide, gallium arsenic, gallium phosphide, indium phosphide, indium arsenide, and indium antimonide; an alloy semiconductor including SiGe, GaAsP, AlInAs, AlGaAs, GaInAs, GaInP, and GaInAsP; any other suitable material; or combinations thereof. In some embodiments, the alloy semiconductor substrate has a gradient SiGe feature in which the Si and Ge composition change from one ratio at one location to another ratio at another location of the gradient SiGe feature. In some embodiments, the alloy SiGe is formed over a silicon substrate. In some embodiments, substrate 390 is a strained SiGe substrate. In some embodiments, the semiconductor substrate has a semiconductor on insulator structure, such as a silicon on insulator (SOI) structure. In some embodiments, the semiconductor substrate includes a doped epi layer or a buried layer. In some embodiments, the compound semiconductor substrate has a multilayer structure, or the substrate includes a multilayer compound semiconductor structure.

In some embodiments, at least one of integrated circuit 300A, 300C, 400A, 400C, 500A, 500B, 600A, 600B, 700, 800, 900A, 900B, 900C or 900D is incorporated on a single integrated circuit (IC), or on a single semiconductor substrate. In some embodiments, at least one of integrated circuit 300A, 300C, 400A, 400C, 500A, 500B, 600A, 600B, 700, 800, 900A, 900B, 900C or 900D includes one or more ICs incorporated on one or more single semiconductor substrates.

Integrated circuit 300A further includes one or more active regions 302a, 302b, 302c, 302d or 302e (collectively referred to as a “set of active regions 302”) extending in a first direction X or a second direction Y.

The set of active regions is embedded in a substrate 390. Substrate 390 has a front-side (not labelled) and a back-side (not labelled) opposite from the front-side.

Active regions 302a, 302b, 302c, 302d or 302e of the set of active regions 302 are separated from one another in the second direction Y. The set of active regions 302 is manufactured by a corresponding set of active region layout patterns of a layout design similar to integrated circuit 300A.

In some embodiments, the set of active regions 302 are located on a front-side (not labelled) of at least integrated circuit 300A, 500A, 600A, 700, 800 or 900A. In some embodiments, active regions 302a, 302b, 302c, 302d or 302e of the set of active regions 302 are manufactured by corresponding active region layout patterns of the set of active region layout patterns.

In some embodiments, the set of active regions 302 is referred to as an oxide diffusion (OD) region which defines the source or drain diffusion regions of at least integrated circuit 300A, 500A, 700, 800 or 900A.

In some embodiments, each of active region 302a, 302b, 302c, 302d or 302e of the set of active regions 302 is a source region and/or a drain region of an NMOS transistor, such as transistor 102.

In some embodiments, active region 302a is a source region of transistor 102 and is designated in FIGS. 1A and 3A as “S.” In some embodiments, for brevity and clarity, one or more source regions are labelled in FIGS. 1A-9C, as an “S”.

In some embodiments, active region 302b is a drain region of transistor 102 and is designated in FIGS. 1A and 3A as “D.”. In some embodiments, for brevity and clarity, one or more drain regions are labelled in FIGS. 1A-9C, as a “D”.

In some embodiments, active region 302c is a source region of transistor 102.

In some embodiments, active region 302d is a drain region of transistor 102.

In some embodiments, active region 302e is a source region of transistor 102.

In some embodiments, at least one or more of active regions 302a, 302b, 302c, 302d or 302e is an N-type doped S/D region embedded in a dielectric material of substrate 390.

In some embodiments, integrated circuit 300A is a multi-finger transistor device, and thus two or more of active regions 302a, 302c or 302e which are source regions of integrated circuit 300A are electrically coupled together.

In some embodiments, integrated circuit 300A is a multi-finger transistor device, and thus two or more of active regions 302b or 302d which are drain regions of integrated circuit 300A are electrically coupled together.

In some embodiments, one or more of active regions 302a, 302c or 302e is a drain region of transistor 102, and one or more of active regions 302b or 302d is a source drain region of transistor 102.

In some embodiments, each active region 302a, 302b, 302c, 302d or 302e of the set of active regions 302 has a width W1a in the second direction Y.

In some embodiments, one or more of active regions 302a, 302b, 302c, 302d or 302e of the set of active regions 302 has a width in the second direction Y different from the width W1a.

In some embodiments, the set of active regions 302 is located on a first level. In some embodiments, the first level corresponds to an active level or an OD level of one or more of integrated circuits 300A, 300C, 400A, 400C, 500A, 500B, 600A, 600B, 700, 800, 900A, 900B or 900C.

Other numbers of active regions in the set of active regions 302 are within the scope of the present disclosure.

Other configurations, arrangements on other levels or quantities of regions in the set of active regions 302 are within the scope of the present disclosure.

Integrated circuit 300A further includes an insulating region 303.

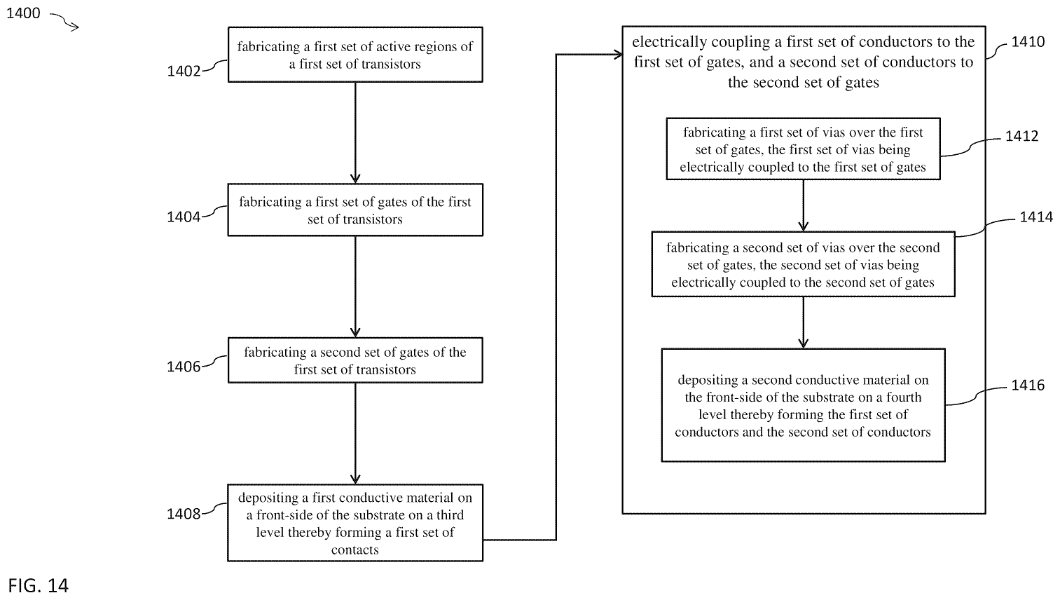

Insulating region 303 is configured to electrically isolate one or more elements of the set of active regions 302, the set of gates 304 or the set of contacts 306 from one another, or from other elements (not shown). In some embodiments, insulating region 303 includes multiple insulating regions deposited at different times from each other during method 1400 (FIG. 14). In some embodiments, insulating region 303 is a dielectric material. In some embodiments, the dielectric material includes silicon dioxide, silicon oxy-nitride, or the like.

Other configurations, arrangements on other layout levels or other numbers of portions in insulating region 303 are within the scope of the present disclosure.

Integrated circuit 300A further includes one or more of gates 304a, 304b, 304c or 304d (collectively referred to as a “set of gates 304”) extending in the second direction Y. Each of the gates of the set of gates 304 is separated from an adjacent gate of the set of gates 304 in the first direction X by a pitch CPP1 or a pitch CPP2. In some embodiments, adjacent elements are elements that are directly next to each other. For example, if a first element is adjacent to a second element, then the second element and the first element are directly next to each other.

Gates 304a and 304b of the set of gates 304 are separated from each other in the first direction X by a pitch CPP1. In some embodiments, gates 304a and 304b of the set of gates 304 are adjacent to each other.

Gates 304b and 304c of the set of gates 304 are separated from each other in the first direction X by a pitch CPP2. In some embodiments, gates 304b and 304c of the set of gates 304 are adjacent to each other.

Gates 304c and 304d of the set of gates 304 are separated from each other in the first direction X by the pitch CPP1. In some embodiments, gates 304c and 304d of the set of gates 304 are adjacent to each other.

In some embodiments, pitch CPP1 is not equal to pitch CPP2.

In some embodiments, pitch CPP1 is equal to pitch CPP2.

In some embodiments, the set of gates 304 is manufactured by a corresponding set of gate layout patterns. In some embodiments, gates 304a, 304b, 304c or 304d of the set of gates 304 are manufactured by a corresponding gate layout pattern of the set of gate layout patterns.

In some embodiments, one or more of gates 304a, 304b, 304c or 304d of the set of gates 304 is the gate of transistor 100A of FIG. 1A, and is designated in FIGS. 1A and 3A as “G.” In some embodiments, for brevity and clarity, one or more gates are labelled in FIGS. 1A-9C, as an “S.” In some embodiments, integrated circuit 300A is a multi-finger transistor device, and thus two or more of gates 304a, 304b, 304c or 304d are electrically coupled together.

In some embodiments, each gate 304a, 304b, 304c or 304d of the set of gates 304 has a length L1 in the first direction X.

In some embodiments, one or more of gates 304a, 304b, 304c or 304d of the set of gates 304 has a length L2 (not shown in FIG. 3A) in the first direction X. In some embodiments, the length L2 is different from the length L1.

In some embodiments, each gate 304a, 304b, 304c or 304d of the set of gates 304 has a width W2a in the second direction Y. In some embodiments, the width W2a is the portion of gate 304a, 304b, 304c or 304d that is directly above the set of active regions 302. Stated differently, in some embodiments, the width W2a is the portion of gate 304a, 304b, 304c or 304d that covers the set of active regions 302, but does not extend beyond the set of active regions 302.

In some embodiments, one or more of gates 304a, 304b, 304c or 304d of the set of gates 304 has a width in the second direction Y different from the width W2a.

The set of gates 304 is above the set of active regions 302. The set of gates 304 is positioned on a second level different from the first level. In some embodiments, the second level is different from the first level. In some embodiments, the second level corresponds to the POLY level of one or more of integrated circuits 300A, 300C, 400A, 400C, 500A, 500B, 600A, 600B, 700, 800, 900A, 900B or 900C.

In some embodiments, the POLY level is above the OD level.

Other configurations, arrangements on other levels or quantities of gates in the set of gates 304 are within the scope of the present disclosure.

Integrated circuit 300A further includes one or more of contacts 306a, 306b, 306c, 306d or 306e (collectively referred to as a “set of contacts 306”) extending in the second direction Y.

Each of the contacts of the set of contacts 306 is separated from an adjacent contact of the set of contacts 306 in at least the first direction X. In some embodiments, adjacent elements are elements that are directly next to each other. For example, if a first element is adjacent to a second element, then the second element and the first element are directly next to each other.

The set of contacts 306 is manufactured by a corresponding set of contact layout patterns. In some embodiments, contact 306a, 306b, 306c, 306d or 306e of the set of contacts 306 is manufactured by a corresponding contact layout pattern of the set of contact layout patterns.

In some embodiments, the set of contacts 306 is also referred to as a set of metal over diffusion (MD) structures.

In some embodiments, at least one of contact 306a, 306b, 306c, 306d or 306e of the set of contacts 306 is a source terminal or a drain terminal of an NMOS transistor, such as transistor 102.

In some embodiments, contact 306a is a source terminal of transistor 102.

In some embodiments, contact 306b is a drain terminal of transistor 102.

In some embodiments, contact 306c is a source terminal of transistor 102.

In some embodiments, contact 306d is a drain terminal of transistor 102.

In some embodiments, contact 306e is a source terminal of transistor 102.

In some embodiments, the set of contacts 306 overlap the set of active regions 302. The set of contacts 306 is located on a third level. In some embodiments, the third level corresponds to the contact level or an MD level of one or more of integrated circuit 300A, 300C, 400A, 400C, 500A, 500B, 600A, 600B, 700, 800, 900A, 900B or 900C. In some embodiments, the third level is the same as the second level. In some embodiments, the third level is different from the first level.

Other configurations, arrangements on other levels or quantities of contacts in the set of contacts 306 are within the scope of the present disclosure.

In some embodiments, at least one gate of the set of gates 304 are formed using a doped or non-doped polycrystalline silicon (or polysilicon). In some embodiments, at least one gate of the set of gates 304 include a metal, such as Al, Cu, W, Ti, Ta, TiN, TaN, NiSi, CoSi, other suitable conductive materials, or combinations thereof.

In some embodiments, at least one conductor of the set of contacts 306, at least one conductor of a set of conductors 1520, 1522 or 1532, at least one via of the set of vias 1510, at least one via of the set of vias 1512 or at least one via of the set of vias 1514 includes one or more layers of a conductive material, a metal, a metal compound or a doped semiconductor. In some embodiments, the conductive material includes Tungsten, Cobalt, Ruthenium, Copper, or the like or combinations thereof. In some embodiments, a metal includes at least Cu (Copper), Co, W, Ru, Al, or the like. In some embodiments, a metal compound includes at least AlCu, W—TiN, TiSix, NiSix, TiN, TaN, or the like. In some embodiments, a doped semiconductor includes at least doped silicon, or the like.

In some embodiments, by integrated circuit 300A including adjacent gates with different pitches, integrated circuit 300A has improved effective channel length, improved signal path, and improved parasitic capacitance effect than other approaches, resulting in a more flexible design than other approaches.

Other materials, configurations, arrangements on other levels or quantities of elements in integrated circuit 300A are within the scope of the present disclosure.

FIGS. 3C and 3D are diagrams of an integrated circuit 300C, in accordance with some embodiments. FIG. 3C is a top view of integrated circuit 300C, in accordance with some embodiments. FIG. 3D is a cross-sectional view of integrated circuit 300C, in accordance with some embodiments.

Integrated circuit 300C is an embodiment of integrated circuit 200A of FIG. 2A, and similar detailed description is therefore omitted.

FIG. 3C is a cross-sectional view of integrated circuit 300C as intersected by plane B-B′, in accordance with some embodiments.

Integrated circuit 300C is a variation of integrated circuit 300A of FIGS. 3A-3B, and similar detailed description is therefore omitted.

In comparison with integrated circuit 300A of FIGS. 3A-3B, a set of active regions 322 replaces the set of active regions 302 of FIGS. 3A-3B, a set of gates 324 replaces the set of gates 304 of FIGS. 3A-3B, and a set of contacts 326 replaces the set of contacts 306 of FIGS. 3A-3B, and similar detailed description is therefore omitted.

Integrated circuit 300A includes the substrate 390, the insulating region 303, the set of active regions 322, the set of gates 324 and the set of contacts 326.

The set of active regions 322 includes at least one or more of active regions 322a, 322b, 322c, 322d, 322e, 322f, 322g or 322h.

In some embodiments, at least one or more active regions 322a, 322b, 322c, 322d, 322e, 322f, 322g or 322h is similar to at least one or more of active regions 302a, 302b, 302c, 302d or 302e, and similar detailed description is therefore omitted.

The set of active regions 322 is manufactured by a corresponding set of active region layout patterns of a layout design similar to integrated circuit 300C.

In some embodiments, the set of active regions 322 are located on a front-side (not labelled) of at least integrated circuit 300C, 500B, 800, 800B or 900B. In some embodiments, active regions 322a, 322b, 322c, 322d, 322e, 322f, 322g or 322h of the set of active regions 302 are manufactured by corresponding active region layout patterns of the set of active region layout patterns.

In some embodiments, the set of active regions 322 is referred to as an OD region which defines the source or drain diffusion regions of at least integrated circuit 300c, 500B, 800, 800B or 900B.

In some embodiments, each of active region 322a, 322b, 322c, 322d, 322e, 322f, 322g or 322h of the set of active regions 322 is a source region and/or a drain region of one or more NMOS transistors, such as transistors 202 and 204.

In some embodiments, active region 322a is a source region of transistor 204.

In some embodiments, active region 322b is a drain region of transistor 204 and a source region of transistor 202.

In some embodiments, active region 322c is a drain region of transistor 202.

In some embodiments, active region 322d is a source region of transistor 202 and a drain region of transistor 204.

In some embodiments, active region 322e is a source region of transistor 204.

In some embodiments, active region 322f is a drain region of transistor 204 and a source region of transistor 202.

In some embodiments, active region 322g is a drain region of transistor 202.

In some embodiments, active region 322h is a source region of transistor 202.

In some embodiments, at least one or more of active regions 322a, 322b, 322c, 322d, 322e, 322f, 322g or 322h is an N-type doped S/D region embedded in a dielectric material of substrate 390.

In some embodiments, integrated circuit 300C is a multi-finger transistor device, and thus two or more of active regions 302a or 302e which are source regions of integrated circuit 300C are electrically coupled together.

In some embodiments, integrated circuit 300C is a multi-finger transistor device, and thus two or more of active regions 302c or 302g which are drain regions of integrated circuit 300C are electrically coupled together.

In some embodiments, integrated circuit 300C is a multi-finger transistor device, and thus two or more of active regions 302b, 302d, 302f or 302h are electrically coupled together.

In some embodiments, at least one of active region 322a is a drain region of transistor 204, active region 322b is a source region of transistor 204 and a drain region of transistor 202, active region 322c is a source region of transistor 202, active region 322d is a drain region of transistor 202 and a source region of transistor 204, active region 322e is a drain region of transistor 204, active region 322f is a source region of transistor 204 and a drain region of transistor 202, active region 322g is a source region of transistor 202 or active region 322h is a drain region of transistor 202.

In some embodiments, each active region 322a, 322b, 322c, 322d, 322e, 322f, 322g or 322h of the set of active regions 322 has a width W1b in the second direction Y.

In some embodiments, one or more of active regions 322a, 322b, 322c, 322d, 322e, 322f, 322g or 322h of the set of active regions 322 has a width in the second direction Y different from the width W1b.

In some embodiments, the set of active regions 322 is located on the first level.

Other numbers of active regions in the set of active regions 322 are within the scope of the present disclosure.

Other configurations, arrangements on other levels or quantities of regions in the set of active regions 322 are within the scope of the present disclosure.

The set of gates 324 includes at least one or more of gates 324a, 324b, 324c, 324d, 324e, 324f or 324g.

In some embodiments, at least one or more gates 324a, 324b, 324c, 324d, 324e, 324f or 324g is similar to at least one or more of gates 304a, 304b, 304c or 304d, and similar detailed description is therefore omitted.

Gates 324a and 324b of the set of gates 324 are separated from each other in the first direction X by a pitch CPP1.

Gates 324b and 324c of the set of gates 324 are separated from each other in the first direction X by a pitch CPP3.

Gates 324c and 324d of the set of gates 324 are separated from each other in the first direction X by the pitch CPP1.

Gates 324d and 324e of the set of gates 324 are separated from each other in the first direction X by a pitch CPP2.

Gates 324e and 324f of the set of gates 324 are separated from each other in the first direction X by a pitch CPP1.

Gates 324f and 324g of the set of gates 324 are separated from each other in the first direction X by a pitch CPP3.

In some embodiments, at least one of pitch CPP1, CPP2 or CPP3 is not equal to at least another of pitch CPP1, CPP2 or CPP3.

In some embodiments, at least one of pitch CPP1, CPP2 or CPP3 is equal to at least another of pitch CPP1, CPP2 or CPP3.

In some embodiments, the set of gates 324 is manufactured by a corresponding set of gate layout patterns. In some embodiments, gates 324a, 324b, 324c, 324d, 324e, 324f or 324g of the set of gates 324 are manufactured by a corresponding gate layout pattern of the set of gate layout patterns.

In some embodiments, one or more of gates 324a, 324d or 324e of the set of gates 324 is the gate of transistor 200A of FIG. 2A, and is designated in FIGS. 2A and 3C as “G1.”

In some embodiments, one or more of gates 324b, 324c, 324f or 324g of the set of gates 324 is the gate of transistor 200A of FIG. 2A, and is designated in FIGS. 2A and 3C as “G2.”

In some embodiments, for brevity and clarity, one or more gates are labelled in FIGS. 1A-9C, as a “G, G1 or G2”.

In some embodiments, integrated circuit 300C is a multi-finger transistor device, and thus two or more of gates 324a, 324d or 324e are electrically coupled together.

In some embodiments, integrated circuit 300C is a multi-finger transistor device, and thus two or more of gates 324b, 324c, 324f or 324g are electrically coupled together.

In some embodiments, each gate 324a, 324b, 324c, 324d, 324c, 324f or 324g of the set of gates 324 has a length L1 in the first direction X.

In some embodiments, one or more of gates 324a, 324b, 324c, 324d, 324c, 324f or 324g of the set of gates 324 has a length L2 (not shown in FIG. 3C) in the first direction X. In some embodiments, the length L2 is different from the length L1.

In some embodiments, each gate 324a, 324b, 324c, 324d, 324c, 324f or 324g of the set of gates 324 has a width W2b in the second direction Y. In some embodiments, the width W2b is the portion of gate 324a, 324b, 324c, 324d, 324c, 324f or 324g that is directly above the set of active regions 222. Stated differently, in some embodiments, the width W2b is the portion of gate 324a, 324b, 324c, 324d, 324c, 324f or 324g that covers the set of active regions 222, but does not extend beyond the set of active regions 222.

In some embodiments, one or more of gates 324a, 324b, 324c, 324d, 324c, 324f or 324g of the set of gates 324 has a width in the second direction Y different from the width W2b.

The set of gates 324 is above the set of active regions 322. The set of gates 324 is positioned on the second level.

Other configurations, arrangements on other levels or quantities of gates in the set of gates 324 are within the scope of the present disclosure.

The set of contacts 326 includes at least one or more of contacts 326a, 326b, 326c or 326d.

In some embodiments, at least one or more contacts 326a, 326b, 326c or 326d is similar to at least one or more of contacts 306a, 306b, 306c, 306d or 306e, and similar detailed description is therefore omitted.

The set of contacts 326 is manufactured by a corresponding set of contact layout patterns. In some embodiments, contact 326a, 326b, 326c or 326d of the set of contacts 326 is manufactured by a corresponding contact layout pattern of the set of contact layout patterns.

In some embodiments, at least one of contact 326a, 326b, 326c or 326d of the set of contacts 326 is a source terminal or a drain terminal of one or more NMOS transistors, such as transistors 202 and 204.

In some embodiments, contact 326a is a source terminal of transistor 204.

In some embodiments, contact 326b is a drain terminal of transistor 202.

In some embodiments, contact 326c is a source terminal of transistor 204.

In some embodiments, contact 326d is a drain terminal of transistor 202.

In some embodiments, the set of contacts 326 overlap the set of active regions 322. The set of contacts 326 is located on the third level.

Other configurations, arrangements on other levels or quantities of contacts in the set of contacts 326 are within the scope of the present disclosure.

In some embodiments, integrated circuit 300C is a stacked MOSFET device of a single cascode device with a compact design or layout style. For example, in some embodiments, one or more drain and source regions of integrated circuit 300C are shared with each other thereby reducing an area of integrated circuit 300C compared to other approaches.

In some embodiments, by integrated circuit 300C including adjacent gates with different pitches, integrated circuit 300C has improved effective channel length, improved signal path, and improved parasitic capacitance effect than other approaches, resulting in a more flexible design than other approaches.

Other materials, configurations, arrangements on other levels or quantities of elements in integrated circuit 300C are within the scope of the present disclosure.

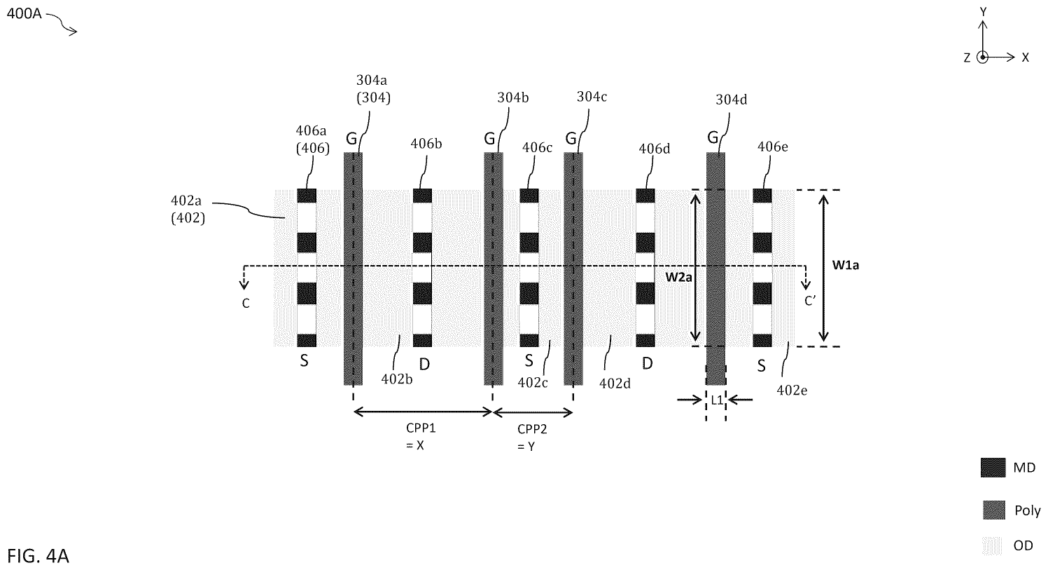

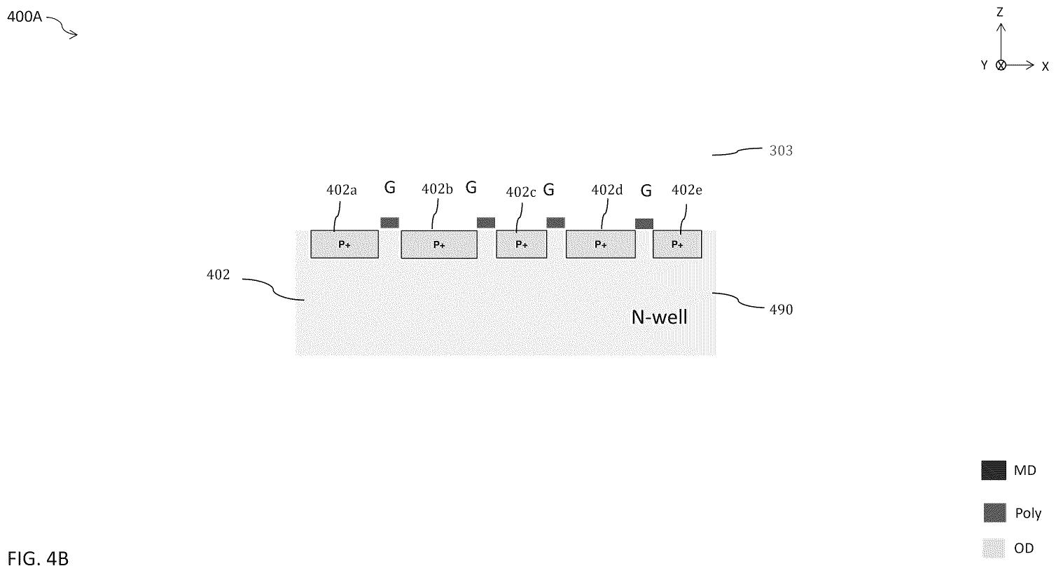

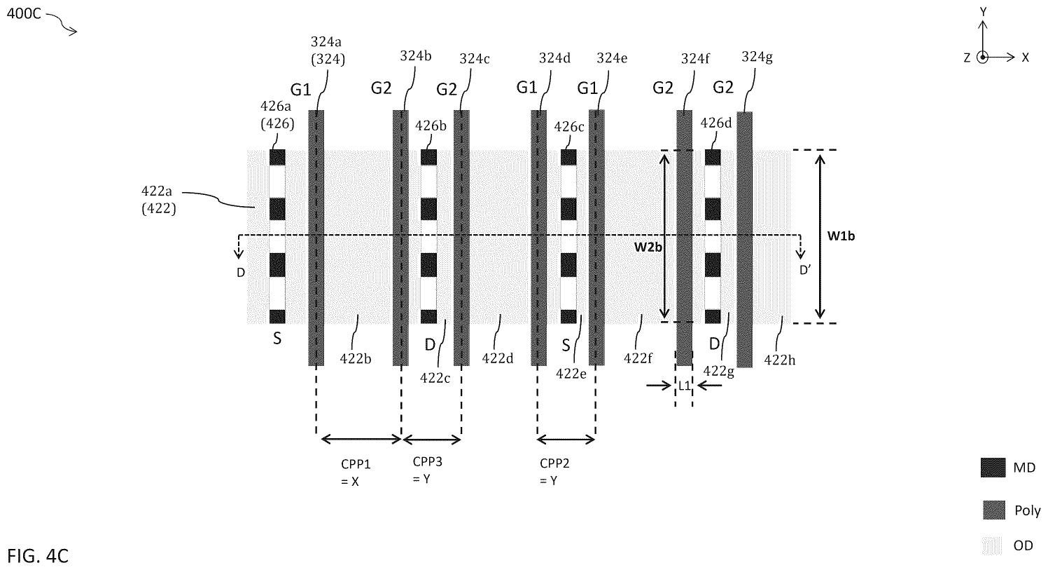

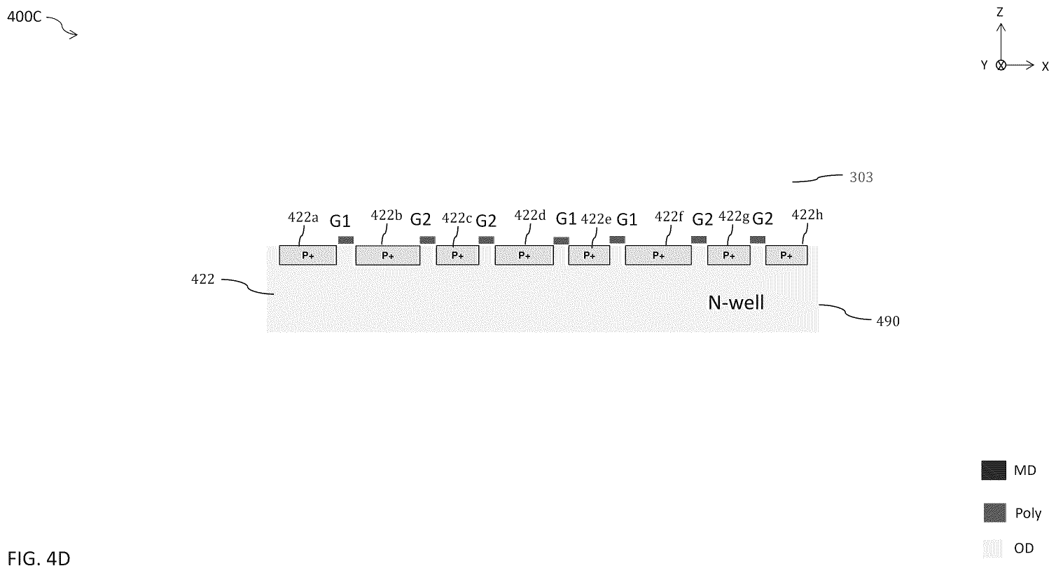

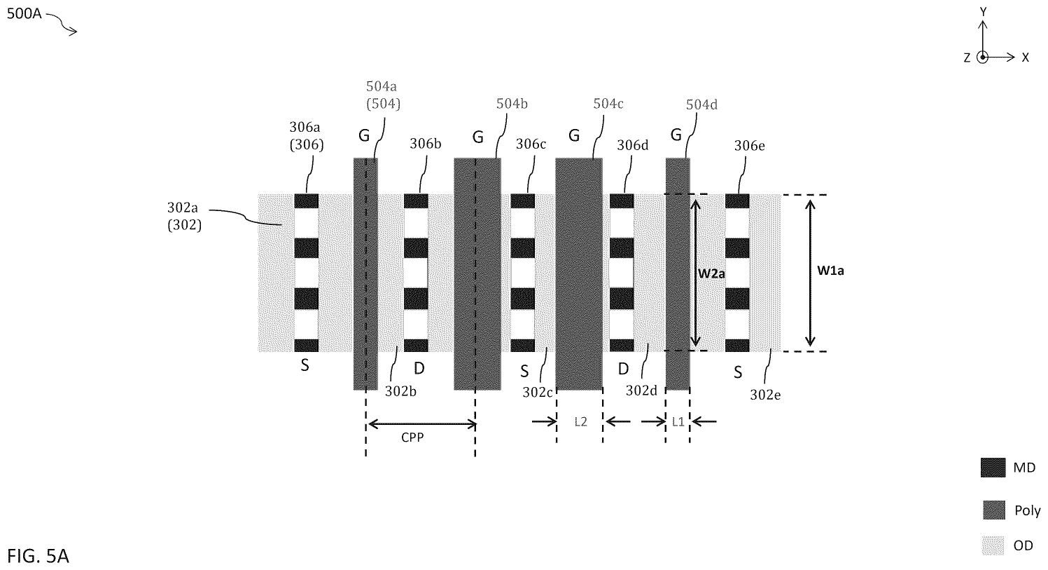

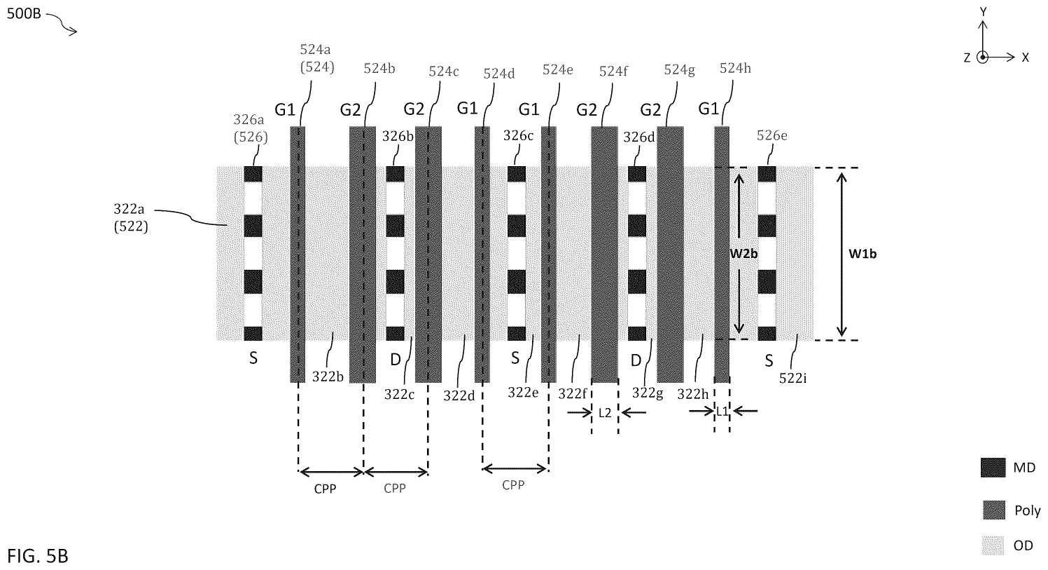

FIGS. 4A and 4B are diagrams of an integrated circuit 400A, in accordance with some embodiments.

FIG. 4A is a top view of integrated circuit 400A, in accordance with some embodiments.

FIG. 4B is a cross-sectional view of integrated circuit 400A, in accordance with some embodiments.

FIGS. 4C and 4D are diagrams of an integrated circuit 400C, in accordance with some embodiments.

FIG. 4C is a top view of integrated circuit 400C, in accordance with some embodiments.

FIG. 4D is a cross-sectional view of integrated circuit 400C, in accordance with some embodiments.

Integrated circuit 400A is an embodiment of integrated circuit 100B of FIG. 1B, and similar detailed description is therefore omitted.

FIG. 4B is a cross-sectional view of integrated circuit 400A as intersected by plane C-C′, in accordance with some embodiments.

Integrated circuit 400A is a variation of integrated circuit 300A of FIGS. 3A-3B, and similar detailed description is therefore omitted.

In comparison with integrated circuit 300A of FIGS. 3A-3B, a substrate 490 replaces the substrate 390 of FIGS. 3A-3B, a set of active regions 402 replaces the set of active regions 302 of FIGS. 3A-3B, and a set of contacts 406 replaces the set of contacts 306 of FIGS. 3A-3B, and similar detailed description is therefore omitted.

Integrated circuit 400A includes the substrate 490, the insulating region 303, the set of active regions 402, the set of gates 304 and the set of contacts 406.

In some embodiments, substrate 490 is an n-type substrate. In some embodiments, substrate 490 is an n-type well in an underlaying substrate (not shown). In some embodiments, substrate 490 includes an elemental semiconductor including silicon or germanium in crystal, polycrystalline, or an amorphous structure; a compound semiconductor including silicon carbide, gallium arsenic, gallium phosphide, indium phosphide, indium arsenide, and indium antimonide; an alloy semiconductor including SiGe, GaAsP, AlInAs, AlGaAs, GaInAs, GaInP, and GaInAsP; any other suitable material; or combinations thereof. In some embodiments, the alloy semiconductor substrate has a gradient SiGe feature in which the Si and Ge composition change from one ratio at one location to another ratio at another location of the gradient SiGe feature. In some embodiments, the alloy SiGe is formed over a silicon substrate. In some embodiments, substrate 490 is a strained SiGe substrate. In some embodiments, the semiconductor substrate has a semiconductor on insulator structure, such as a silicon on insulator (SOI) structure. In some embodiments, the semiconductor substrate includes a doped epi layer or a buried layer. In some embodiments, the compound semiconductor substrate has a multilayer structure, or the substrate includes a multilayer compound semiconductor structure.

The set of active regions 402 includes at least one or more of active regions 402a, 402b, 402c, 402d or 402e.

In some embodiments, at least one or more active regions 402a, 402b, 402c, 402d or 402e is similar to at least one or more of active regions 302a, 302b, 302c, 302d or 302e, and similar detailed description is therefore omitted.

In some embodiments, the set of active regions 402 is referred to as an OD region which defines the source or drain diffusion regions of at least integrated circuit 400A.

In some embodiments, each of active region 402a, 402b, 402c, 402d or 402e of the set of active regions 402 is a source region and/or a drain region of a PMOS transistor, such as transistor 104.

In some embodiments, active region 402a is a source region of transistor 104 and is designated in FIGS. 1B and 4A as “S.”

In some embodiments, active region 402b is a drain region of transistor 104 and is designated in FIGS. 1B and 4A as “D.”

In some embodiments, active region 402c is a source region of transistor 104.

In some embodiments, active region 402d is a drain region of transistor 104.

In some embodiments, active region 402e is a source region of transistor 104.

In some embodiments, at least one or more of active regions 402a, 402b, 402c, 402d or 402e is a P-type doped S/D region embedded in a dielectric material of substrate 490.

In some embodiments, integrated circuit 400A is a multi-finger transistor device, and thus two or more of active regions 402a, 402c or 402e which are source regions of integrated circuit 400A are electrically coupled together.

In some embodiments, integrated circuit 400A is a multi-finger transistor device, and thus two or more of active regions 402b or 402d which are drain regions of integrated circuit 400A are electrically coupled together.

In some embodiments, one or more of active regions 402a, 402c or 402e is a drain region of transistor 104, and one or more of active regions 402b or 402d is a source drain region of transistor 104.

In some embodiments, each active region 402a, 402b, 402c, 402d or 402e of the set of active regions 402 has a width W1a in the second direction Y.

In some embodiments, one or more of active regions 402a, 402b, 402c, 402d or 402c of the set of active regions 402 has a width in the second direction Y different from the width W1a.

In some embodiments, the set of active regions 402 is located on the first level.

Other numbers of active regions in the set of active regions 402 are within the scope of the present disclosure.

Other configurations, arrangements on other levels or quantities of regions in the set of active regions 402 are within the scope of the present disclosure.

The set of contacts 406 includes at least one or more of contacts 406a, 406b, 406c, 406d or 406c.

In some embodiments, at least one or more contacts 406a, 406b, 406c, 406d or 406c is similar to at least one or more of contacts 306a, 306b, 306c, 306d or 306e, and similar detailed description is therefore omitted.

The set of contacts 406 is manufactured by a corresponding set of contact layout patterns. In some embodiments, contact 406a, 406b, 406c, 406d or 406e of the set of contacts 406 is manufactured by a corresponding contact layout pattern of the set of contact layout patterns.

In some embodiments, at least one of contact 406a, 406b, 406c, 406d or 406e of the set of contacts 406 is a source terminal or a drain terminal of PMOS transistor, such as transistor 104.

In some embodiments, contact 406a is a source terminal of transistor 104.

In some embodiments, contact 406b is a drain terminal of transistor 104.

In some embodiments, contact 406c is a source terminal of transistor 104.

In some embodiments, contact 406d is a drain terminal of transistor 104.

In some embodiments, contact 406e is a source terminal of transistor 104.

Other configurations, arrangements on other levels or quantities of contacts in the set of contacts 406 are within the scope of the present disclosure.

In some embodiments, by integrated circuit 400A including adjacent gates with different pitches, integrated circuit 400A has improved effective channel length, improved signal path, and improved parasitic capacitance effect than other approaches, resulting in a more flexible design than other approaches.

Other materials, configurations, arrangements on other levels or quantities of elements in integrated circuit 400A are within the scope of the present disclosure.

FIGS. 4C and 4D are diagrams of an integrated circuit 400C, in accordance with some embodiments.

FIG. 4C is a top view of integrated circuit 400C, in accordance with some embodiments.

FIG. 4D is a cross-sectional view of integrated circuit 400C, in accordance with some embodiments.

Integrated circuit 400C is an embodiment of integrated circuit 200B of FIG. 2B, and similar detailed description is therefore omitted.

FIG. 4C is a cross-sectional view of integrated circuit 400C as intersected by plane D-D′, in accordance with some embodiments.

Integrated circuit 400C is a variation of integrated circuit 300C of FIGS. 3C-3D, and similar detailed description is therefore omitted.

In comparison with integrated circuit 300C of FIGS. 3C-3D, substrate 490 replaces the substrate 390 of FIGS. 3C-3D, a set of active regions 422 replaces the set of active regions 322 of FIGS. 3C-3D, and a set of contacts 426 replaces the set of contacts 326 of FIGS. 3C-3D, and similar detailed description is therefore omitted.

Integrated circuit 400C includes the substrate 490, the insulating region 303, the set of active regions 422, the set of gates 324 and the set of contacts 426.

The set of active regions 422 includes at least one or more of active regions 422a, 422b, 422c, 422d, 422e, 422f, 422g or 422h.

In some embodiments, at least one or more active regions 422a, 422b, 422c, 422d, 422e, 422f, 422g or 422h is similar to at least one or more of active regions 322a, 322b, 322c, 322d, 322e, 322f, 322g or 322h, and similar detailed description is therefore omitted.

The set of active regions 422 is manufactured by a corresponding set of active region layout patterns of a layout design similar to integrated circuit 400C.

In some embodiments, the set of active regions 422 is referred to as an OD region which defines the source or drain diffusion regions of at least integrated circuit 400C.

In some embodiments, each of active region 422a, 422b, 422c, 422d, 422c, 422f, 422g or 422h of the set of active regions 422 is a source region and/or a drain region of one or more PMOS transistors, such as transistors 210 and 212.

In some embodiments, active region 422a is a source region of transistor 210.

In some embodiments, active region 422b is a drain region of transistor 210 and a source region of transistor 212.

In some embodiments, active region 422c is a drain region of transistor 212.

In some embodiments, active region 422d is a source region of transistor 212 and a drain region of transistor 210.

In some embodiments, active region 422e is a source region of transistor 210.

In some embodiments, active region 422f is a drain region of transistor 210 and a source region of transistor 212.

In some embodiments, active region 422g is a drain region of transistor 212.

In some embodiments, active region 422h is a source region of transistor 212.

In some embodiments, at least one or more of active regions 422a, 422b, 422c, 422d, 422c, 422f, 422g or 422h is a P-type doped S/D region embedded in a dielectric material of substrate 290.

In some embodiments, integrated circuit 400C is a multi-finger transistor device, and thus two or more of active regions 402a or 402e which are source regions of integrated circuit 400C are electrically coupled together.

In some embodiments, integrated circuit 400C is a multi-finger transistor device, and thus two or more of active regions 402c or 402g which are drain regions of integrated circuit 400C are electrically coupled together.

In some embodiments, integrated circuit 400C is a multi-finger transistor device, and thus two or more of active regions 402b, 402d, 402f or 402h are electrically coupled together.

In some embodiments, at least one of active region 422a is a drain region of transistor 210, active region 422b is a source region of transistor 210 and a drain region of transistor 212, active region 422c is a source region of transistor 212, active region 422d is a drain region of transistor 212 and a source region of transistor 210, active region 422e is a drain region of transistor 210, active region 422f is a source region of transistor 210 and a drain region of transistor 212, active region 422g is a source region of transistor 212 or active region 422h is a drain region of transistor 212.

In some embodiments, each active region 422a, 422b, 422c, 422d, 422e, 422f, 422g or 422h of the set of active regions 422 has a width W1b in the second direction Y.

In some embodiments, one or more of active regions 422a, 422b, 422c, 422d, 422e, 422f, 422g or 422h of the set of active regions 422 has a width in the second direction Y different from the width W1b.

In some embodiments, the set of active regions 422 is located on the first level.

Other numbers of active regions in the set of active regions 422 are within the scope of the present disclosure.

Other configurations, arrangements on other levels or quantities of regions in the set of active regions 422 are within the scope of the present disclosure.

The set of contacts 426 includes at least one or more of contacts 426a, 426b, 426c or 426d.

In some embodiments, at least one or more contacts 426a, 426b, 426c or 426d is similar to at least one or more of contacts 326a, 326b, 326c or 326d, and similar detailed description is therefore omitted.

In some embodiments, at least one of contact 426a, 426b, 426c or 426d of the set of contacts 426 is a source terminal or a drain terminal of one or more PMOS transistors, such as transistors 210 and 212.

In some embodiments, contact 426a is a source terminal of transistor 210.

In some embodiments, contact 426b is a drain terminal of transistor 212.

In some embodiments, contact 426c is a source terminal of transistor 210.

In some embodiments, contact 426d is a drain terminal of transistor 212.

In some embodiments, the set of contacts 426 overlap the set of active regions 422. The set of contacts 426 is located on the third level.

Other configurations, arrangements on other levels or quantities of contacts in the set of contacts 426 are within the scope of the present disclosure.

In some embodiments, integrated circuit 400C is a stacked MOSFET device of a single cascode device with a compact design or layout style. For example, in some embodiments, one or more drain and source regions of integrated circuit 400C are shared with each other thereby reducing an area of integrated circuit 400C compared to other approaches.

In some embodiments, by integrated circuit 400C including adjacent gates with different pitches, integrated circuit 400C has improved effective channel length, improved signal path, and improved parasitic capacitance effect than other approaches, resulting in a more flexible design than other approaches.

Other materials, configurations, arrangements on other levels or quantities of elements in integrated circuit 400C are within the scope of the present disclosure.

FIG. 5A is a diagram of an integrated circuit 500A, in accordance with some embodiments.

FIG. 5A is a top view of integrated circuit 500A, in accordance with some embodiments.

Integrated circuit 500A is an embodiment of integrated circuit 100A of FIG. 1A, and similar detailed description is therefore omitted.

Integrated circuit 500A is a variation of integrated circuit 300A of FIGS. 3A-3B, and similar detailed description is therefore omitted.

In comparison with integrated circuit 300A of FIGS. 3A-3B, a set of gates 504 replaces the set of gates 304 of FIGS. 3A-3B, and similar detailed description is therefore omitted. For example, in some embodiments, the set of gates 504 has gates with different lengths (e.g., L1 and L2) in the first direction X.

Integrated circuit 500A includes the substrate 390, the insulating region 303, the set of active regions 302, the set of gates 504 and the set of contacts 306.

The set of gates 504 includes at least one or more of gates 504a, 504b, 504c or 504d.

In some embodiments, at least one or more gates 504a, 504b, 504c or 504d is similar to at least one or more of gates 304a, 304b, 304c or 304d, and similar detailed description is therefore omitted.

Each of the gates of the set of gates 504 is separated from an adjacent gate of the set of gates 504 in the first direction X by a pitch CPP.

In some embodiments, at least one gate of the set of gates 504 is separated from an adjacent gate of the set of gates 504 in the first direction X by a pitch different from the pitch CPP. In some embodiments, pitch CPP is equal to at least one of pitch CPP1, CPP2 or CPP3.

In some embodiments, pitch CPP is different from at least one of pitch CPP1, CPP2 or CPP3.

In some embodiments, at least one of gate 504a or 504d of the set of gates 504 has a length L1 in the first direction X.

In some embodiments, at least one of gate 504b or 504c of the set of gates 504 has a length L2 in the first direction X.

In some embodiments, the length L1 is less than the length L2. In some embodiments, the length L2 is related to a range R1. In some embodiments, the range R1 ranges from about 1.3*L1 to about 1.4*L1. Other ranges or values for the range R1 are within the scope of the present disclosure.

In some embodiments, if the length L2 is less than the range R1, then the length L2 may be insufficient to change the electrical characteristics of at least one of gate 504b or 504c compared with at least one of gate 504a or 504d thereby decreasing the performance of integrated circuit 500A of at least one or more of the effective channel length, the gate control capability, the transconductance gm, the output conductance gds, the signal path or the parasitic capacitance effect compared to other approaches that are not less than the range R1.

In some embodiments, if the length L2 is equal to the range R1, then the length L2 is sufficient to improve the electrical characteristics of at least one of gate 504b or 504c thereby increasing the performance of integrated circuit 500A of at least one or more of the effective channel length, the gate control capability, the transconductance gm, the output conductance gds, the signal path or the parasitic capacitance effect compared to other approaches that are less than the range R1.

In some embodiments, if the length L2 is greater than the range R1, then the length L2 may be sufficient to improve the electrical characteristics of at least one of gate 504b or 504c compared with at least one of gate 504a or 504d thereby increasing the performance of integrated circuit 500A of at least one or more of the effective channel length, the gate control capability, the transconductance gm, the output conductance gds, the signal path or the parasitic capacitance effect compared to other approaches that are less than the range R1.

In some embodiments, the length L1 is equal to the length L2.

In some embodiments, at least one of gate 504a or 504d of the set of gates 504 has a length L2 in the first direction X.

In some embodiments, at least one of gate 504b or 504c of the set of gates 504 has a length L1 in the first direction X.

In some embodiments, each gate 504a, 504b, 504c or 504d of the set of gates 504 has a width W2a in the second direction Y. In some embodiments, the width W2a is the portion of gate 504a, 504b, 504c or 504d that is directly above the set of active regions 302. Stated differently, in some embodiments, the width W2a is the portion of gate 504a, 504b, 504c or 504d that covers the set of active regions 302, but does not extend beyond the set of active regions 302.

In some embodiments, one or more of gates 504a, 504b, 504c or 504d of the set of gates 504 has a width in the second direction Y different from the width W2a.

Other configurations, arrangements on other levels or quantities of gates in the set of gates 504 are within the scope of the present disclosure.

In some embodiments, by integrated circuit 500A including gates with different lengths, integrated circuit 500A has improved effective channel length, improved gate control capability, improved transconductance gm, improved output conductance gds, improved signal path, and improved parasitic capacitance effect than other approaches, resulting in a more flexible design than other approaches.

Other materials, configurations, arrangements on other levels or quantities of elements in integrated circuit 500A are within the scope of the present disclosure.

FIG. 5B is a diagram of an integrated circuit 500B, in accordance with some embodiments.

FIG. 5B is a top view of integrated circuit 500B, in accordance with some embodiments.

Integrated circuit 500B is an embodiment of integrated circuit 100B of FIG. 1B, and similar detailed description is therefore omitted.

Integrated circuit 500B is a variation of integrated circuit 300C of FIGS. 3C-3D, and similar detailed description is therefore omitted.

In comparison with integrated circuit 300C of FIGS. 3C-3D, a set of active regions 622 replaces the set of active regions 322 of FIGS. 3C-3D, a set of gates 524 replaces the set of gates 324 of FIGS. 3C-3D, and similar detailed description is therefore omitted. For example, in some embodiments, the set of gates 524 has gates with different lengths (e.g., L1 and L2) in the first direction X.

Integrated circuit 500B includes the substrate 390, the insulating region 303, the set of active regions 622, the set of gates 524 and the set of contacts 326.

The set of active regions 522 includes at least one or more of active regions 322a, 322b, 322c, 322d, 322e, 322f, 322g, 322h or 522i.

In some embodiments, active region 522i is similar to at least one or more of active regions 322a, 322b, 322c, 322d, 322e, 322f, 322g or 322h, and similar detailed description is therefore omitted.

In some embodiments, active region 522i of the set of active regions 522 is manufactured by corresponding active region layout patterns of the set of active region layout patterns.

In some embodiments, active region 522i of the set of active regions 622 is a source region and/or a drain region of one or more NMOS transistors, such as transistors 202 and 204. In some embodiments, active region 522i is a source region of transistor 204.

In some embodiments, active region 522i is an N-type doped S/D region embedded in a dielectric material of substrate 390.

In some embodiments, integrated circuit 600B is a multi-finger transistor device, and thus two or more of active regions 322a, 322e or 622i which are source regions of integrated circuit 500B are electrically coupled together.

In some embodiments, active region 522i of the set of active regions 522 has a width W1b in the second direction Y.

Other numbers of active regions in the set of active regions 522 are within the scope of the present disclosure.

Other configurations, arrangements on other levels or quantities of regions in the set of active regions 522 are within the scope of the present disclosure.

The set of gates 524 includes at least one or more of gates 524a, 524b, 524c, 524d, 524e, 524f, 524g or 524h.

In some embodiments, at least one or more gates 524a, 524b, 524c, 524d, 524e, 524f, 524g or 524h is similar to at least one or more of gates 324a, 324b, 324c, 324d, 324e, 324f or 324g, and similar detailed description is therefore omitted.

Each of the gates of the set of gates 524 is separated from an adjacent gate of the set of gates 524 in the first direction X by a pitch CPP.

In some embodiments, at least one gate of the set of gates 524 is separated from an adjacent gate of the set of gates 524 in the first direction X by a pitch different from the pitch CPP.

In some embodiments, pitch CPP is equal to at least one of pitch CPP1, CPP2 or CPP3.

In some embodiments, pitch CPP is different from at least one of pitch CPP1, CPP2 or CPP3.

In some embodiments, at least one of gate 524a, 524d, 524c or 524h of the set of gates 524 has a length L1 in the first direction X.

In some embodiments, at least one of gate 524b, 524c, 524f or 524g of the set of gates 524 has a length L2 in the first direction X.

In some embodiments, the length L1 is less than the length L2. In some embodiments, the length L2 is related to a range R2. In some embodiments, the range R2 ranges from about 1.1*L1 to about 1.2*L1. Other ranges or values for the range R2 are within the scope of the present disclosure.

In some embodiments, if the length L2 is less than the range R2, then the length L2 may be insufficient to change the electrical characteristics of at least one of gate 524b, 524c, 524f or 524g compared with at least one of gate 524a, 524d, 524e or 524h thereby decreasing the performance of integrated circuit 500B of at least one or more of the effective channel length, the gate control capability, the transconductance gm, the output conductance gds, the signal path or the parasitic capacitance effect compared to other approaches that are not less than the range R2.

In some embodiments, if the length L2 is equal to the range R2, then the length L2 is sufficient to improve the electrical characteristics of at least one of gate 524b, 524c, 524f or 524g compared with at least one of gate 524a, 524d, 524e or 524h thereby increasing the performance of integrated circuit 500B of at least one or more of the effective channel length, the gate control capability, the transconductance gm, the output conductance gds, the signal path or the parasitic capacitance effect compared to other approaches that are less than the range R2.

In some embodiments, if the length L2 is greater than the range R2, then the length L2 may be sufficient to improve the electrical characteristics of at least one of gate 524b, 524c, 524f or 524g compared with at least one of gate 524a, 524d, 524e or 524h thereby increasing the performance of integrated circuit 500B of at least one or more of the effective channel length, the gate control capability, the transconductance gm, the output conductance gds, the signal path or the parasitic capacitance effect compared to other approaches that are less than the range R2.

In some embodiments, the length L1 is equal to the length L2.

In some embodiments, at least one of gate 524a, 524d, 524e or 524h of the set of gates 524 has a length L2 in the first direction X.

In some embodiments, at least one of 524b, 524c, 524f or 524g of the set of gates 524 has a length L1 in the first direction X.

In some embodiments, each gate 524a, 524b, 524c, 524d, 524c, 524f, 524g or 524h of the set of gates 524 has a width W2b in the second direction Y. In some embodiments, the width W2b is the portion of gate 524a, 524b, 524c, 524d, 524c, 524f, 524g or 524h that is directly above the set of active regions 322. Stated differently, in some embodiments, the width W2b is the portion of gate 524a, 524b, 524c, 524d, 524c, 524f, 524g or 524h that covers the set of active regions 322, but does not extend beyond the set of active regions 322.

In some embodiments, one or more of gates 524a, 524b, 524c, 524d, 524c, 524f, 524g or 524h of the set of gates 524 has a width in the second direction Y different from the width W2b.

Other configurations, arrangements on other levels or quantities of gates in the set of gates 524 are within the scope of the present disclosure.

In some embodiments, integrated circuit 500B is a stacked MOSFET device of a single cascode device with a compact design or layout style. For example, in some embodiments, one or more drain and source regions of integrated circuit 500B are shared with each other thereby reducing an area of integrated circuit 500B compared to other approaches.

In some embodiments, by integrated circuit 500B including gates with different lengths, integrated circuit 500B has improved effective channel length, improved gate control capability, improved transconductance gm, improved output conductance gds, improved signal path, and improved parasitic capacitance effect than other approaches, resulting in a more flexible design than other approaches.

Other materials, configurations, arrangements on other levels or quantities of elements in integrated circuit 500B are within the scope of the present disclosure.

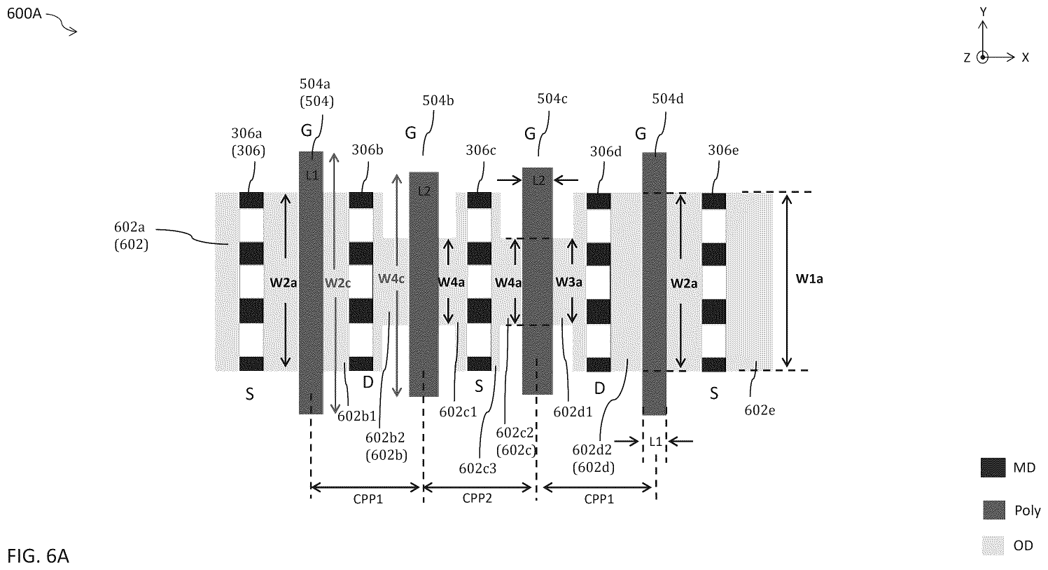

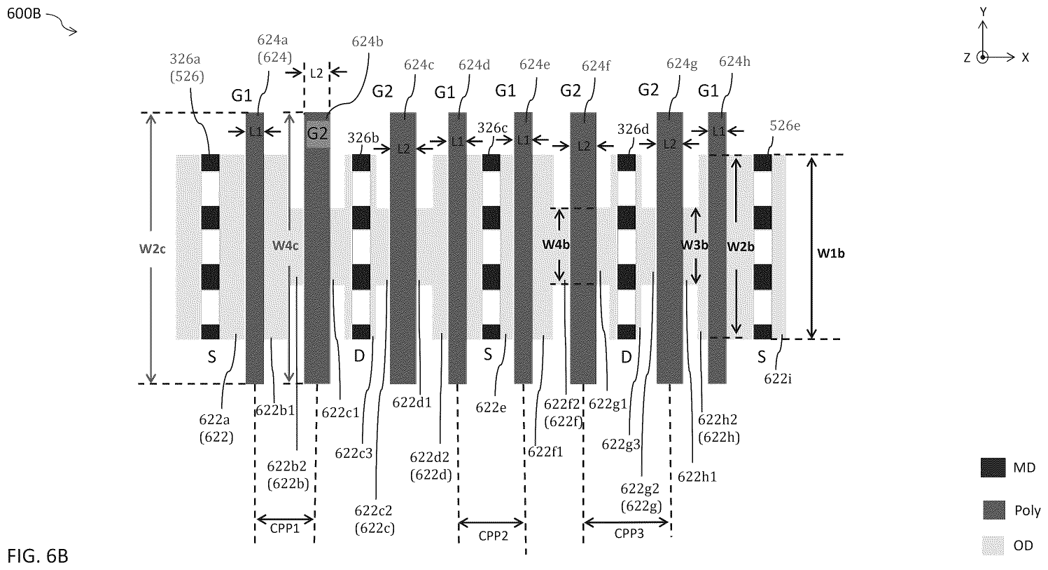

FIG. 6A is a diagram of an integrated circuit 600A, in accordance with some embodiments.

FIG. 6A is a top view of integrated circuit 600A, in accordance with some embodiments.

Integrated circuit 600A is an embodiment of integrated circuit 100A of FIG. 1A, and similar detailed description is therefore omitted. In some embodiments, integrated circuit 600A is an embodiment of integrated circuit 100B of FIG. 1B, and similar detailed description is therefore omitted.

Integrated circuit 600A is a variation of integrated circuit 500A of FIG. 5A, and similar detailed description is therefore omitted.

In comparison with integrated circuit 500A of FIG. 5A, a set of active regions 602 replaces the set of active regions 302 of FIG. 5A, and similar detailed description is therefore omitted. For example, in some embodiments, the set of active regions 502 has active regions with different widths (e.g., W1a and W3a) in the second direction Y, and the set of gates 504 has gates with different widths (e.g., W2a and W4a) in the second direction Y.

Integrated circuit 600A includes the substrate 390, the insulating region 303, the set of active regions 602, the set of gates 504 and the set of contacts 306.

The set of active regions 602 includes at least one or more of active regions 602a, 602b, 602c, 602d or 602c.

In some embodiments, at least one or more of active regions 602a, 602b, 602c, 602d or 602e is similar to at least one or more of active regions 302a, 302b, 302c, 302d or 302e, and similar detailed description is therefore omitted. In some embodiments, at least one or more of active regions 602a, 602b, 602c, 602d or 602e is similar to at least one or more of active regions 402a, 402b, 402c, 402d or 402c, and similar detailed description is therefore omitted.

The set of active regions 602 is manufactured by a corresponding set of active region layout patterns of a layout design similar to integrated circuit 600A.

In some embodiments, the set of active regions 602 are located on a front-side (not labelled) of at least integrated circuit 600A. In some embodiments, active regions 602a, 602b, 602c, 602d or 602e of the set of active regions 602 are manufactured by corresponding active region layout patterns of the set of active region layout patterns.

In some embodiments, each of active region 602a, 602b, 602c, 602d or 602e of the set of active regions 602 is a source region and/or a drain region of an NMOS transistor, such as transistor 102. In some embodiments, each of active region 602a, 602b, 602c, 602d or 602e of the set of active regions 602 is a source region and/or a drain region of a PMOS transistor, such as transistor 104.

In some embodiments, active region 602a is a source region of transistor 102.

In some embodiments, active region 602b is a drain region of transistor 102.

In some embodiments, active region 602c is a source region of transistor 102.

In some embodiments, active region 602d is a drain region of transistor 102.

In some embodiments, active region 602e is a source region of transistor 102.

In some embodiments, active region 602a is a source region of transistor 104.

In some embodiments, active region 602b is a drain region of transistor 104.

In some embodiments, active region 602c is a source region of transistor 104.

In some embodiments, active region 602d is a drain region of transistor 104.

In some embodiments, active region 602e is a source region of transistor 104.

In some embodiments, at least one or more of active regions 602a, 602b, 602c, 602d or 602e is an N-type doped S/D region embedded in a dielectric material of substrate 390. In some embodiments, at least one or more of active regions 602a, 602b, 602c, 602d or 602e is a P-type doped S/D region embedded in a dielectric material of substrate 490.

In some embodiments, integrated circuit 600A is a multi-finger transistor device, and thus two or more of active regions 602a, 602c or 602e which are source regions of integrated circuit 600A are electrically coupled together.

In some embodiments, integrated circuit 600A is a multi-finger transistor device, and thus two or more of active regions 602b or 602d which are drain regions of integrated circuit 600A are electrically coupled together.

In some embodiments, one or more active regions 602a or 602e of the set of active regions 602 has a width W1a in the second direction Y.

In some embodiments, active region 602b includes at least one or more of active regions active regions 602b1 or 602b2.

In some embodiments, active region 602c includes at least one or more of active regions active regions 602c1, 602c2 or 602c3. Active region 602c3 is between active regions 602c1 and 602c2.

In some embodiments, active region 602d includes at least one or more of active regions active regions 602d1 or 602d2.

In some embodiments, one or more of active regions 602a, 602b1, 602c1, 602c3, 602d2 or 602e has a width W1a in the second direction Y.

In some embodiments, one or more of active regions 602b2, 602c1, 602c2 or 602d1 has a width W3a in the second direction Y.

In some embodiments, width W3a is less than width W1a.

In some embodiments, the width W1a is related to a range Rla. In some embodiments, the range R1a ranges from about 1.45*W3a to about 1.55*W3a. Other ranges or values for the range R1a are within the scope of the present disclosure.

In some embodiments, if the width W1a is less than the range R1a, then the width W1a may be insufficient to change the electrical characteristics of at least one of active regions 602a, 602b1, 602c1, 602c3, 602d2 or 602e compared with at least one of active regions 602b2, 602cl, 602c2 or 602d1 thereby decreasing the performance of integrated circuit 600A of at least one or more of the effective channel width, the gate control capability, the transconductance gm, the output conductance gds, the signal path or the parasitic capacitance effect compared to other approaches that are not less than the range R1a.

In some embodiments, if the width W1a is equal to the range R1a, then the width W1a is sufficient to improve the electrical characteristics of at least one of active regions 602a, 602b1, 602c1, 602c3, 602d2 or 602e compared with at least one of active regions 602b2, 602c1, 602c2 or 602d1 thereby increasing the performance of integrated circuit 600A of at least one or more of the effective channel width, the gate control capability, the transconductance gm, the output conductance gds, the signal path or the parasitic capacitance effect compared to other approaches that are less than the range R1a.

In some embodiments, if the width W1a is greater than the range R1a, then the width W1a is sufficient to improve the electrical characteristics of at least one of active regions 602a, 602b1, 602c1, 602c3, 602d2 or 602e compared with at least one of active regions 602b2, 602cl, 602c2 or 602d1 thereby increasing the performance of integrated circuit 600A of at least one or more of the effective channel width, the gate control capability, the transconductance gm, the output conductance gds, the signal path or the parasitic capacitance effect compared to other approaches that are less than the range R1a.

In some embodiments, the set of active regions 602 is located on the first level.

Other numbers of active regions in the set of active regions 602 are within the scope of the present disclosure.

Other configurations, arrangements on other levels or quantities of regions in the set of active regions 602 are within the scope of the present disclosure.

In at least FIG. 6A, gates 504a and 504b of the set of gates 504 are separated from each other in the first direction X by the pitch CPP1.

In at least FIG. 6A, gates 504b and 504c of the set of gates 504 are separated from each other in the first direction X by the pitch CPP2.

In at least FIG. 6A, gates 504c and 504d of the set of gates 504 are separated from each other in the first direction X by the pitch CPP1.

In some embodiments, pitch CPP1 is not equal to pitch CPP2. In some embodiments, pitch CPP1 is greater than pitch CPP2.

In some embodiments, pitch CPP1 is equal to pitch CPP2.

In some embodiments, the pitch CPP1 is related to a range R3a. In some embodiments, the range R3a ranges from about 1.2*CPP2 to about 1.3*CPP2. Other ranges or values for the range R3a are within the scope of the present disclosure.

Other ranges or values for the range R3a are within the scope of the present disclosure.

In some embodiments, if the pitch CPP1 is less than the range R3, then the pitch CPP1 may be insufficient to create enough separation between adjacent gates in the set of gates 504 thereby decreasing the manufacturing yield of integrated circuit 600A compared to other approaches.

In some embodiments, if the pitch CPP1 is less than the range R3, then the pitch CPP1 may be insufficient to create enough separation between adjacent gates in the set of gates 504 to improve the electrical characteristics of at least one of gate 504a or 504d compared with at least one of gate 504b or 504c thereby decreasing the performance of integrated circuit 600A of at least one or more of the effective channel length, the gate control capability, the transconductance gm, the output conductance gds, the signal path or the parasitic capacitance effect compared to other approaches that are not less than the range R3.

In some embodiments, if the pitch CPP1 is equal to the range R3, then the pitch CPP1 is sufficient to create enough separation between adjacent gates in the set of gates 504 thereby increasing the manufacturing yield of integrated circuit 600A compared to other approaches.

In some embodiments, if the pitch CPP1 is equal to the range R3, then the pitch CPP1 is sufficient to create enough separation between adjacent gates in the set of gates 504 to improve the electrical characteristics of at least one of gate 504a or 504d compared with at least one of gate 504b or 504c thereby increasing the performance of integrated circuit 600A of at least one or more of the effective channel length, the gate control capability, the transconductance gm, the output conductance gds, the signal path or the parasitic capacitance effect compared to other approaches that are less than the range R3.

In some embodiments, if the pitch CPP1 is greater than the range R3, then the pitch CPP1 is sufficient to create enough separation between adjacent gates in the set of gates 504 thereby increasing the manufacturing yield of integrated circuit 600A compared to other approaches.

In some embodiments, if the pitch CPP1 is greater than the range R3, then the pitch CPP1 may be sufficient to create enough separation between adjacent gates in the set of gates 504 to improve the electrical characteristics of at least one of gate 504a or 504d compared with at least one of gate 504b or 504c thereby increasing the performance of integrated circuit 600A of at least one or more of the effective channel length, the gate control capability, the transconductance gm, the output conductance gds, the signal path or the parasitic capacitance effect compared to other approaches that are less than the range R3.

In some embodiments, at least one of gates 504a, 504b, 504c, 504d or 504e of the set of gates 504 has a length L1 in the first direction X, and at least one of gates 504a, 504b, 504c, 504d or 504c of the set of gates 504 has a length L2 in the first direction X. In some embodiments, each of gates 504a, 504b, 504c, 504d or 504e of the set of gates 504 has a length L1 or L2 in the first direction X.

In some embodiments, the length L1 in the first direction X is not equal to the length L2 in the first direction X. In some embodiments, the length L1 in the first direction X is greater than the length L2 in the first direction X.

In some embodiments, the length L1 is less than the length L2. In some embodiments, the length L2 is related to a range R1. In some embodiments, the range R1 ranges from about 1.3*L1 to about 1.4*L1. Other ranges or values for the range R1 are within the scope of the present disclosure.

In some embodiments, if the length L2 is less than the range R1, then the length L2 may be insufficient to change the electrical characteristics of at least one of gate 504b or 504c compared with at least one of gate 504a or 504d thereby decreasing the performance of integrated circuit 600A of at least one or more of the effective channel length, the gate control capability, the transconductance gm, the output conductance gds, the signal path or the parasitic capacitance effect compared to other approaches that are not less than the range R1.

In some embodiments, if the length L2 is equal to the range R1, then the length L2 is sufficient to improve the electrical characteristics of at least one of gate 504b or 504c thereby increasing the performance of integrated circuit 600A of at least one or more of the effective channel length, the gate control capability, the transconductance gm, the output conductance gds, the signal path or the parasitic capacitance effect compared to other approaches that are less than the range R1.

In some embodiments, if the length L2 is greater than the range R1, then the length L2 may be sufficient to improve the electrical characteristics of at least one of gate 504b or 504c compared with at least one of gate 504a or 504d thereby increasing the performance of integrated circuit 600A of at least one or more of the effective channel length, the gate control capability, the transconductance gm, the output conductance gds, the signal path or the parasitic capacitance effect compared to other approaches that are less than the range R1.

In some embodiments, the length L1 in the first direction X is equal to the length L2 in the first direction X.

In some embodiments, at least one of gates 504a, 504b, 504c, 504d or 504e of the set of gates 504 has a length L1 in the first direction X, at least one of gates 504a, 504b, 504c, 504d or 504c of the set of gates 504 has a length L2 in the first direction X, at least two or more active regions in the set of active regions 602 have different widths (e.g., W1a and W3a) in the second direction Y, and at least one of gates 504a, 504b, 504c, 504d or 504e of the set of gates 504 has a width W2a in the second direction Y, and at least one of gates 504a, 504b, 504c, 504d or 504c of the set of gates 504 has a width W4a in the second direction Y.

In some embodiments, by the set of active regions 602 having different widths (e.g., W1a and W3a) in the second direction Y causes the set of gates 504 to have gates with different widths (e.g., W2a and W4a) in the second direction Y.

In some embodiments, at least one of gate 504a or 504d of the set of gates 504 has a width W2a in the second direction Y.

In some embodiments, at least one of gate 504b or 504c of the set of gates 504 has a width W4a in the second direction Y.

In some embodiments, the width W2a is the portion of gate 504a or 504d that is directly above the set of active regions 602. In some embodiments, the width W4a is the portion of gate 504b or 504c that is directly above the set of active regions 602. Stated differently, in some embodiments, the width W4a is the dimension of the portion of gate 504b or 504c that covers the set of active regions 602, but does not extend beyond the set of active regions 602.

In some embodiments, the width W4a is equal to the width W2a.

In some embodiments, the width W4a is less than the width W2a.

In some embodiments, if the width W1a is less than the width W3a, then the width W2a is less than W4a. In some embodiments, if the width W2a is less than the width W4a, then the width W4a may be insufficient to change the electrical characteristics of at least one of gate 504b or 504c compared with at least one of gate 504a or 504d thereby decreasing the performance of integrated circuit 600A of at least one or more of the transconductance gm, output conductance gds or parasitic capacitance effect compared to other approaches where the width W2a is not less than the width W4a.

In some embodiments, if the width W1a is equal to the width W3a, then the width W2a is equal to W4a. In some embodiments, if the width W2a is equal to the width W4a, then the width W4a may be insufficient to improve the electrical characteristics of at least one of gate 504b or 504c compared with at least one of gate 504a or 504d thereby maintaining the performance of integrated circuit 600A of at least one or more of the transconductance gm, output conductance gds or parasitic capacitance effect compared to other approaches where the width W2a is less than the width W4a.

In some embodiments, if the width W1a is greater than the width W3a, then the width W2a is greater than W4a. In some embodiments, if the width W2a is greater than the width W4a, then the width W4a may be sufficient to improve the electrical characteristics of at least one of gate 504b or 504c compared with at least one of gate 504a or 504d thereby increasing the performance of integrated circuit 600A of at least one or more of the transconductance gm, output conductance gds or parasitic capacitance effect compared to other approaches where the width W2a is less than the width W4a.

In some embodiments, the set of gates 504 have gates with different widths (e.g., W2c and W4c) in the second direction Y. In some embodiments, the width W4c or W2c is the dimension of the corresponding gate in the second direction Y.

In some embodiments, at least one of gate 504a or 504d of the set of gates 504 has a width W2c in the second direction Y.

In some embodiments, at least one of gate 504b or 504c of the set of gates 504 has a width W4c in the second direction Y.

In some embodiments, the width W4c is not equal to the width W2c. In some embodiments, the width W4c is less than the width W2c.

In some embodiments, the set of gates 504 have gates with the same widths (e.g., W2c or W4c) in the second direction Y. In some embodiments, the width W4c is equal to the width W2c.

In some embodiments, the length L1 in the first direction X is different from the length L2 in the first direction X, the width W1a in the second direction Y is different from the width W3a in the second direction Y, and the pitch CPP1 is different from the pitch CPP2.

In some embodiments, the length L1 in the first direction X is different from the length L2 in the first direction X, the width W2a in the second direction Y is different from the width W4a in the second direction Y, and the pitch CPP1 is different from the pitch CPP2.

In some embodiments, the length L1 in the first direction X is different from the length L2 in the first direction X, the width W2c in the second direction Y is different from the width W4c in the second direction Y, and the pitch CPP1 is different from the pitch CPP2.

Other configurations, arrangements on other levels or quantities of gates in the set of gates 504 are within the scope of the present disclosure.

In some embodiments, by integrated circuit 600A including gates with different widths, integrated circuit 600A has improved transconductance gm, improved output conductance gds and improved parasitic capacitance effect than other approaches, resulting in a more flexible design than other approaches.

Other materials, configurations, arrangements on other levels or quantities of elements in integrated circuit 600A are within the scope of the present disclosure.

FIG. 6B is a diagram of an integrated circuit 600B, in accordance with some embodiments.

FIG. 6B is a top view of integrated circuit 600B, in accordance with some embodiments.

Integrated circuit 600B is an embodiment of integrated circuit 200A of FIG. 2A, and similar detailed description is therefore omitted. In some embodiments, integrated circuit 600B is an embodiment of integrated circuit 200B of FIG. 2B, and similar detailed description is therefore omitted.

Integrated circuit 600B is a variation of integrated circuit 500B of FIG. 5B, and similar detailed description is therefore omitted.

In comparison with integrated circuit 500B of FIG. 5B, a set of active regions 622 replaces the set of active regions 302 of FIG. 5B, a set of gates 624 replaces the set of gates 524 of FIG. 5B, and similar detailed description is therefore omitted. For example, in some embodiments, the set of active regions 622 has active regions with different widths (e.g., W1b and W3b) in the second direction Y, and the set of gates 624 has gates with different widths (e.g., W2b and W4b) in the second direction Y.

Integrated circuit 600B includes the substrate 390, the insulating region 303, the set of active regions 622, the set of gates 624 and the set of contacts 326.

The set of active regions 622 includes at least one or more of active regions 622a, 622b, 622c, 622d, 622e, 622f, 622g, 622h or 622i.

In some embodiments, at least one or more of active regions 622a, 622b, 622c, 622d, 622c, 622f, 622g, 622h or 622i is similar to at least one or more of active regions 322a, 322b, 322c, 322d, 322e, 322f, 322g or 322h, and similar detailed description is therefore omitted. In some embodiments, at least one or more of active regions 622a, 622b, 622c, 622d, 622c, 622f, 622g, 622h or 622i is similar to at least one or more of active regions 422a, 422b, 422c, 422d, 422e, 422f, 422g or 422h, and similar detailed description is therefore omitted.

The set of active regions 622 is manufactured by a corresponding set of active region layout patterns of a layout design similar to integrated circuit 600B.

In some embodiments, the set of active regions 622 are located on a front-side (not labelled) of at least integrated circuit 600B. In some embodiments, active regions 622a, 622b, 622c, 622d, 622c, 622f, 622g, 622h or 622i of the set of active regions 622 are manufactured by corresponding active region layout patterns of the set of active region layout patterns.

In some embodiments, each of active region 622a, 622b, 622c, 622d, 622e, 622f, 622g, 622h or 622i of the set of active regions 622 is a source region and/or a drain region of one or more NMOS transistors, such as transistors 202 and 204. In some embodiments, each of active region 622a, 622b, 622c, 622d, 622e, 622f, 622g, 622h or 622i of the set of active regions 622 is a source region and/or a drain region of one or more PMOS transistors, such as transistors 210 and 212.

In some embodiments, active region 622a is a source region of transistor 204.

In some embodiments, active region 622b is a drain region of transistor 204 and a source region of transistor 202.

In some embodiments, active region 622c is a drain region of transistor 202.

In some embodiments, active region 622d is a source region of transistor 202 and a drain region of transistor 204.

In some embodiments, active region 622e is a source region of transistor 204.

In some embodiments, active region 622f is a drain region of transistor 204 and a source region of transistor 202.

In some embodiments, active region 622g is a drain region of transistor 202.

In some embodiments, active region 622h is a source region of transistor 202 and a drain region of transistor 204.

In some embodiments, active region 622i is a source region of transistor 204.

In some embodiments, active region 622a is a source region of transistor 210.

In some embodiments, active region 622b is a drain region of transistor 210 and a source region of transistor 212.

In some embodiments, active region 622c is a drain region of transistor 212.

In some embodiments, active region 622d is a source region of transistor 202 and a drain region of transistor 210.

In some embodiments, active region 622e is a source region of transistor 210.

In some embodiments, active region 622f is a drain region of transistor 210 and a source region of transistor 212.

In some embodiments, active region 622g is a drain region of transistor 212.

In some embodiments, active region 622h is a source region of transistor 212 and a drain region of transistor 210.

In some embodiments, active region 622i is a source region of transistor 210.

In some embodiments, at least one or more of active regions 622a, 622b, 622c, 622d, 622e, 622f, 622g, 622h or 622i is an N-type doped S/D region embedded in a dielectric material of substrate 390. In some embodiments, at least one or more of active regions 622a, 622b, 622c, 622d, 622e, 622f, 622g, 622h or 622i is a P-type doped S/D region embedded in a dielectric material of substrate 490.

In some embodiments, integrated circuit 600B is a multi-finger transistor device, and thus two or more of active regions 622a, 622e or 622i which are source regions of integrated circuit 600B are electrically coupled together.

In some embodiments, integrated circuit 600B is a multi-finger transistor device, and thus two or more of active regions 622c or 622g which are drain regions of integrated circuit 600B are electrically coupled together.

In some embodiments, integrated circuit 600B is a multi-finger transistor device, and thus two or more of active regions 622b, 622d, 622f or 622h are electrically coupled together.

In some embodiments, one or more active regions 622a, 622e or 622i of the set of active regions 622 has a width W1b in the second direction Y.

In some embodiments, active region 622b includes at least one or more of active regions active regions 622b1 or 622b2.

In some embodiments, active region 622c includes at least one or more of active regions active regions 622c1, 622c2 or 622c3. Active region 622c3 is between active regions 622c1 and 622c2.

In some embodiments, active region 622d includes at least one or more of active regions active regions 622d1 or 622d2.

In some embodiments, active region 622f includes at least one or more of active regions active regions 622f1 or 622f2.

In some embodiments, active region 622g includes at least one or more of active regions active regions 622g1, 622g2 or 622g3. Active region 622g3 is between active regions 622g1 and 622g2.

In some embodiments, active region 622h includes at least one or more of active regions active regions 622h1 or 622h2.

In some embodiments, one or more of active regions 622a, 622b1, 622c3, 622d2, 622c, 622f1, 622g3, 622h2 or 622i has a width W1b in the second direction Y.

In some embodiments, one or more of active regions 622b2, 622c1, 622c2, 622d1, 622f2, 622g1, 622g2 or 622h1 has a width W3b in the second direction Y.

In some embodiments, width W3b is less than width W1b.

In some embodiments, the width W1b is related to a range R1b. In some embodiments, the range Rib ranges from about 1.45*W3b to about 1.55*W3b. Other ranges or values for the range R1b are within the scope of the present disclosure.

In some embodiments, if the width W1b is less than the range R1b, then the width W1b may be insufficient to change the electrical characteristics of at least one of active regions 622a, 622b1, 622c3, 622d2, 622e, 622f1, 622g3, or 622h2 or 622i compared with at least one of active regions 622b2, 622c1, 622c2, 622d1, 622f2, 622g1, 622g2 or 622h1 thereby decreasing the performance of integrated circuit 600B of at least one or more of the effective channel width, the gate control capability, the transconductance gm, the output conductance gds, the signal path or the parasitic capacitance effect compared to other approaches that are not less than the range R1b.

In some embodiments, if the width Wlb is equal to the range R1b, then the width W1b is sufficient to improve the electrical characteristics of at least one of active regions 622a, 622b1, 622c3, 622d2, 622e, 622f1, 622g3, or 622h2 or 622i compared with at least one of active regions 622b2, 622c1, 622c2, 622d1, 622f2, 622g1, 622g2 or 622h1 thereby increasing the performance of integrated circuit 600B of at least one or more of the effective channel width, the gate control capability, the transconductance gm, the output conductance gds, the signal path or the parasitic capacitance effect compared to other approaches that are less than the range R1b.

In some embodiments, if the width W1b is greater than the range Rb, then the width W1b is sufficient to improve the electrical characteristics of at least one of active regions 622a, 622b1, 622c3, 622d2, 622e, 622f1, 622g3, or 622h2 or 622i compared with at least one of active regions 622b2, 622c1, 622c2, 622dl, 622f2, 622g1, 622g2 or 622h1 thereby increasing the performance of integrated circuit 600B of at least one or more of the effective channel width, the gate control capability, the transconductance gm, the output conductance gds, the signal path or the parasitic capacitance effect compared to other approaches that are less than the range R1b.

In some embodiments, the set of active regions 622 is located on the first level.

Other numbers of active regions in the set of active regions 622 are within the scope of the present disclosure.

Other configurations, arrangements on other levels or quantities of regions in the set of active regions 622 are within the scope of the present disclosure.

In some embodiments, by the set of active regions 622 having different widths (e.g., W1b and W3b) in the second direction Y causes the set of gates 624 to have gates with different widths (e.g., W2b and W4b) in the second direction Y.

The set of gates 624 includes at least one or more of gates 624a, 624b, 624c, 624d, 624e, 624f, 624g or 624h.

In FIG. 6B, gates 624a and 624b of the set of gates 624 are separated from each other in the first direction X by the pitch CPP1.

In FIG. 6B, gates 624b and 624c of the set of gates 624 are separated from each other in the first direction X by the pitch CPP3.

In FIG. 6B, gates 624c and 624d of the set of gates 624 are separated from each other in the first direction X by the pitch CPP1.

In FIG. 6B, gates 624d and 624e of the set of gates 624 are separated from each other in the first direction X by the pitch CPP2.

In FIG. 6B, gates 624e and 624f of the set of gates 624 are separated from each other in the first direction X by the pitch CPP1.

In FIG. 6B, gates 624f and 624g of the set of gates 624 are separated from each other in the first direction X by the pitch CPP3.

In FIG. 6B, gates 624g and 624h of the set of gates 624 are separated from each other in the first direction X by the pitch CPP1.

In some embodiments, at least one of pitch CPP1, CPP2 or CPP3 is not equal to at least another of pitch CPP1, CPP2 or CPP3.

In some embodiments, at least one of pitch CPP1, CPP2 or CPP3 is equal to at least another of pitch CPP1, CPP2 or CPP3.

In some embodiments, the pitch CPP1 is related to a range R4. In some embodiments, the range R4 ranges from about 1.3*CPP3 to about 1.4*CPP3.

In some embodiments, the pitch CPP2 is related to a range R5. In some embodiments, the range R5 ranges from about 1.2*CPP3 to about 1.3*CPP3.

Other ranges or values for at least one of the range R4 or R5 are within the scope of the present disclosure.

In some embodiments, if the pitch CPP1 is less than the range R4, then the pitch CPP1 may be insufficient to create enough separation between adjacent gates in the set of gates 624 thereby decreasing the manufacturing yield of integrated circuit 600B compared to other approaches.

In some embodiments, if the pitch CPP1 is less than the range R4, then the pitch CPP1 may be insufficient to create enough separation between adjacent gates in the set of gates 624 to improve the electrical characteristics of the set of gates 624 thereby decreasing the performance of integrated circuit 600B of at least one or more of the effective channel length, the gate control capability, the transconductance gm, the output conductance gds, the signal path or the parasitic capacitance effect compared to other approaches that are not less than the range R4.

In some embodiments, if the pitch CPP1 is equal to the range R4, then the pitch CPP1 is sufficient to create enough separation between adjacent gates in the set of gates 624 thereby increasing the manufacturing yield of integrated circuit 600B compared to other approaches.

In some embodiments, if the pitch CPP1 is equal to the range R4, then the pitch CPP1 is sufficient to create enough separation between adjacent gates in the set of gates 624 to improve circuit 600B of at least one or more of the effective channel length, the gate control capability, the transconductance gm, the output conductance gds, the signal path or the parasitic capacitance effect compared to other approaches that are less than the range R4.

In some embodiments, if the pitch CPP1 is greater than the range R4, then the pitch CPP1 is sufficient to create enough separation between adjacent gates in the set of gates 624 thereby increasing the manufacturing yield of integrated circuit 600B compared to other approaches.

In some embodiments, if the pitch CPP1 is greater than the range R4, then the pitch CPP1 may be sufficient to create enough separation between adjacent gates in the set of gates 624 to improve the electrical characteristics of the set of gates 624 compared with at least one of gate 624b or 624c thereby increasing the performance of integrated circuit 600B of at least one or more of the effective channel length, the gate control capability, the transconductance gm, the output conductance gds, the signal path or the parasitic capacitance effect compared to other approaches that are less than the range R4.

Other ranges or values for the range R5 are within the scope of the present disclosure.

In some embodiments, if the pitch CPP2 is less than the range R5, then the pitch CPP2 may be insufficient to create enough separation between adjacent gates in the set of gates 624 thereby decreasing the manufacturing yield of integrated circuit 600B compared to other approaches.

In some embodiments, if the pitch CPP2 is less than the range R5, then the pitch CPP2 may be insufficient to create enough separation between adjacent gates in the set of gates 624 to improve the electrical characteristics of the set of gates 624 thereby decreasing the performance of integrated circuit 600B of at least one or more of the effective channel length, the gate control capability, the transconductance gm, the output conductance gds, the signal path or the parasitic capacitance effect compared to other approaches that are not less than the range R5.

In some embodiments, if the pitch CPP2 is equal to the range R5, then the pitch CPP2 is sufficient to create enough separation between adjacent gates in the set of gates 624 thereby increasing the manufacturing yield of integrated circuit 600B compared to other approaches.

In some embodiments, if the pitch CPP2 is equal to the range R5, then the pitch CPP2 is sufficient to create enough separation between adjacent gates in the set of gates 624 to improve circuit 600B of at least one or more of the effective channel length, the gate control capability, the transconductance gm, the output conductance gds, the signal path or the parasitic capacitance effect compared to other approaches that are less than the range R5.

In some embodiments, if the pitch CPP2 is greater than the range R5, then the pitch CPP2 is sufficient to create enough separation between adjacent gates in the set of gates 624 thereby increasing the manufacturing yield of integrated circuit 600B compared to other approaches.

In some embodiments, if the pitch CPP2 is greater than the range R5, then the pitch CPP2 may be sufficient to create enough separation between adjacent gates in the set of gates 624 to improve the electrical characteristics of the set of gates 624 thereby increasing the performance of integrated circuit 600B of at least one or more of the effective channel length, the gate control capability, the transconductance gm, the output conductance gds, the signal path or the parasitic capacitance effect compared to other approaches that are less than the range R5.

In some embodiments, the discussion of at least one or more of ranges R1, R2, R3, R4 or R5 apply to one or more of the set of gates 304, 324, 504, 624 or 824.

Other configurations, arrangements on other levels or quantities of gates in the set of gates 624 are within the scope of the present disclosure.

In some embodiments, at least one or more gates 624a, 624b, 624c, 624d, 624c, 624f, 624g or 624h is similar to at least one or more of gates 524a, 524b, 524c, 524d, 524c, 524f, 524g or 524h, and similar detailed description is therefore omitted.

In some embodiments, at least one of gates 624a, 624d, 624e or 624h of the set of gates 624 has a length L1 in the first direction X, and at least one of gates 624b, 624c, 624f or 624g of the set of gates 624 has a length L2 in the first direction X.

In some embodiments, at least one of gates 624a, 624b, 624c, 624d, 624c, 624f, 624g or 624h of the set of gates 624 has a length L1 in the first direction X, and at least one of gates 624a, 624b, 624c, 624d, 624c, 624f, 624g or 624h of the set of gates 624 has a length L2 in the first direction X.

In some embodiments, each of gates 624a, 624b, 624c, 624d, 624c, 624f, 624g or 624h of the set of gates 624 has a length L1 or L2 in the first direction X.

In some embodiments, the length L1 in the first direction X is not equal to the length L2 in the first direction X. In some embodiments, the length L2 in the first direction X is greater than the length L1 in the first direction X.

In some embodiments, the length L2 is related to a range R2. In some embodiments, the range R2 ranges from about 1.1*L1 to about 1.2*L1. Other ranges or values for the range R2 are within the scope of the present disclosure.

In some embodiments, if the length L2 is less than the range R2, then the length L2 may be insufficient to change the electrical characteristics of at least one of gate 624b, 624c, 624f or 624g compared with at least one of gate 624a, 624d, 624c or 624h thereby decreasing the performance of integrated circuit 600B of at least one or more of the effective channel length, the gate control capability, the transconductance gm, the output conductance gds, the signal path or the parasitic capacitance effect compared to other approaches that are not less than the range R2.

In some embodiments, if the length L2 is equal to the range R2, then the length L2 is sufficient to improve the electrical characteristics of at least one of gate 624b, 624c, 624f or 624g thereby increasing the performance of integrated circuit 600B of at least one or more of the effective channel length, the gate control capability, the transconductance gm, the output conductance gds, the signal path or the parasitic capacitance effect compared to other approaches that are less than the range R2.

In some embodiments, if the length L2 is greater than the range R2, then the length L2 may be sufficient to improve the electrical characteristics of at least one of gate 624b, 624c, 624f or 624g compared with at least one of gate 624a, 624d, 624e or 624h thereby increasing the performance of integrated circuit 600B of at least one or more of the effective channel length, the gate control capability, the transconductance gm, the output conductance gds, the signal path or the parasitic capacitance effect compared to other approaches that are less than the range R2.

In some embodiments, the length L1 in the first direction X is equal to the length L2 in the first direction X.

In comparison with the set of gates 524 of FIG. 5B, the set of gates 624 has gates with different lengths (e.g., L1) in the first direction, and different widths (e.g., W2b and W4b) in the second direction Y, and similar detailed description is therefore omitted. In comparison with the set of gates 524 of FIG. 5B, the set of gates 624 have gates with a same length (e.g., L1 or L2) in the first direction, but different widths (e.g., W2b and W4b) in the second direction Y, and similar detailed description is therefore omitted.

In some embodiments, by the set of active regions 622 having different widths (e.g., W1b and W3b) in the second direction Y causes the set of gates 624 to have gates with different widths (e.g., W2b and W4b) in the second direction Y.

In some embodiments, at least one of gate 624a, 624d, 624c or 624h of the set of gates 624 has a width W2b in the second direction Y.

In some embodiments, at least one of gate 624b, 624c, 624f or 624g of the set of gates 624 has a width W4b in the second direction Y.

In some embodiments, the width W2b is the portion of gate 624a, 624d, 624c or 624h that is directly above the set of active regions 622. In some embodiments, the width W4b is the portion of gate 624b, 624c, 624f or 624g that is directly above the set of active regions 622. Stated differently, in some embodiments, the width W4b is the dimension of the portion of gate 624b, 624c, 624f or 624g that covers the set of active regions 622, but does not extend beyond the set of active regions 622.

In some embodiments, the width W4b is equal to the width W2b.

In some embodiments, the width W4b is less than the width W2b.

In some embodiments, if the width W1b is less than the width W3b, then the width W2b is less than W4b. In some embodiments, if the width W2b is less than the width W4b, then the width W4b may be insufficient to change the electrical characteristics of at least one of gate 624b, 624c, 624f or 624g compared with at least one of gate 624a, 624d, 624c or 624h thereby decreasing the performance of integrated circuit 600B of at least one or more of the transconductance gm, output conductance gds or parasitic capacitance effect compared to other approaches where the width W2b is not less than the width W4b.

In some embodiments, if the width W1b is equal to the width W3b, then the width W2b is equal to W4b. In some embodiments, if the width W2b is equal to the width W4b, then the width W4b may be insufficient to improve the electrical characteristics of at least one of gate 624b, 624c, 624f or 624g compared with at least one of gate 624a, 624d, 624c or 624h thereby maintaining the performance of integrated circuit 600B of at least one or more of the transconductance gm, output conductance gds or parasitic capacitance effect compared to other approaches where the width W2b is less than the width W4b.

In some embodiments, if the width W1b is greater than the width W3b, then the width W2b is greater than W4b. In some embodiments, if the width W2b is greater than the width W4b, then the width W4b may be sufficient to improve the electrical characteristics of at least one of gate 624b, 624c, 624f or 624g compared with at least one of gate 624a, 624d, 624c or 624h thereby increasing the performance of integrated circuit 600B of at least one or more of the transconductance gm, output conductance gds or parasitic capacitance effect compared to other approaches where the width W2b is less than the width W4b.

In some embodiments, the set of gates 604 have gates with different widths (e.g., W2c and W4c) in the second direction Y. In some embodiments, the width W4c or W2c is the dimension of the corresponding gate in the second direction Y.

In some embodiments, at least one of gate 624a, 624d, 624e or 624h of the set of gates 604 has a width W2c in the second direction Y.

In some embodiments, at least one of gate 624b, 624c, 624f or 624g of the set of gates 604 has a width W4c in the second direction Y.

In some embodiments, the width W4c is not equal to the width W2c. In some embodiments, the width W4c is less than the width W2c.

In some embodiments, the set of gates 604 have gates with the same widths (e.g., W2c or W4c) in the second direction Y. In some embodiments, the width W4c is equal to the width W2c.

In some embodiments, the length L1 in the first direction X is different from the length L2 in the first direction X, the width W1a in the second direction Y is different from the width W3a in the second direction Y, and at least one of pitch CPP1, CPP2 or CPP3 is different from at least another of pitch CPP1, CPP2 or CPP3.

In some embodiments, the length L1 in the first direction X is different from the length L2 in the first direction X, the width W2a in the second direction Y is different from the width W4a in the second direction Y, and at least one of pitch CPP1, CPP2 or CPP3 is different from at least another of pitch CPP1, CPP2 or CPP3.

In some embodiments, the length L1 in the first direction X is different from the length L2 in the first direction X, the width W2c in the second direction Y is different from the width W4c in the second direction Y, and at least one of pitch CPP1, CPP2 or CPP3 is different from at least another of pitch CPP1, CPP2 or CPP3.

Other configurations, arrangements on other levels or quantities of gates in the set of gates 624 are within the scope of the present disclosure.

In some embodiments, integrated circuit 600B is a stacked MOSFET device of a single cascode device with a compact design or layout style. For example, in some embodiments, one or more drain and source regions of integrated circuit 600B are shared with each other thereby reducing an area of integrated circuit 600B compared to other approaches.

In some embodiments, by integrated circuit 600B including gates with different widths, integrated circuit 600B has improved transconductance gm, improved output conductance gds and improved parasitic capacitance effect than other approaches, resulting in a more flexible design than other approaches.

Other materials, configurations, arrangements on other levels or quantities of elements in integrated circuit 600B are within the scope of the present disclosure.

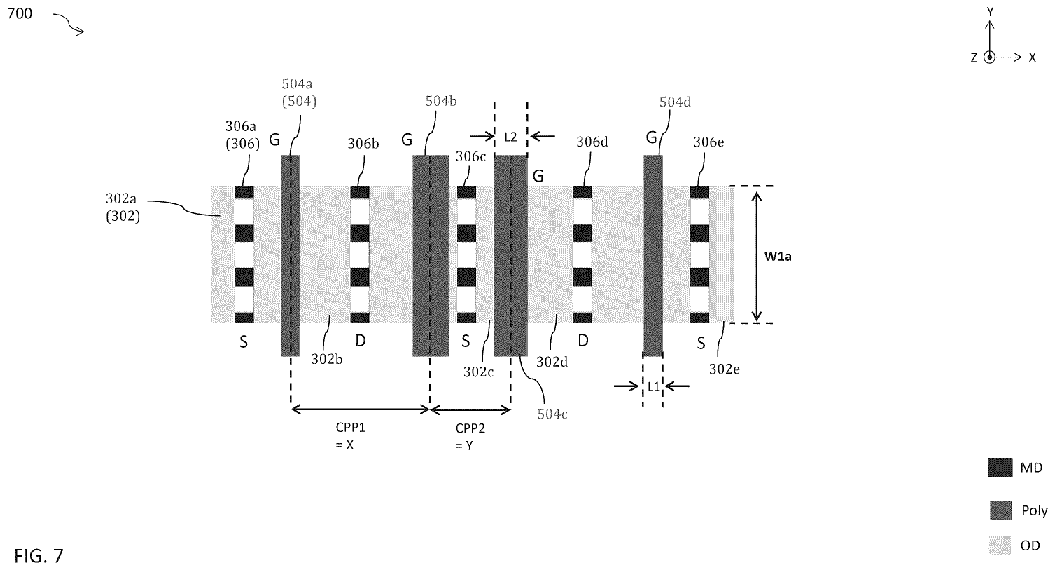

FIG. 7 is a diagram of an integrated circuit 700, in accordance with some embodiments.

FIG. 7 is a top view of integrated circuit 700, in accordance with some embodiments.

Integrated circuit 700 is an embodiment of integrated circuit 100A of FIG. 1A, and similar detailed description is therefore omitted.

Integrated circuit 700 is a variation of integrated circuit 300A of FIGS. 3A-3B and integrated circuit 500A of FIG. 5A, and similar detailed description is therefore omitted. For example, in some embodiments, integrated circuit 700 combines the different poly pitch features of the set of gates 304 of FIGS. 3A-3B into the set of gates 504, which have different length features, and similar detailed description is therefore omitted. In some embodiments, integrated circuit 700 combines the different poly pitch features of the set of gates 304 of FIGS. 3A-3B into the set of gates 504, and further combines the different active region features of FIG. 6A of the set of active regions 602 into the set of active regions 302 of FIG. 7, and similar detailed description is therefore omitted. In some embodiments, the set of active regions 302 of FIG. 7 is replaced by the set of active regions 602 of FIG. 6A, and similar detailed description is therefore omitted.

In comparison with integrated circuit 300A of FIGS. 3A-3B, the set of gates 504 replaces the set of gates 304 of FIGS. 3A-3B, and similar detailed description is therefore omitted.

Integrated circuit 700 includes the substrate 390, the insulating region 303, the set of active regions 302, the set of gates 504 and the set of contacts 306.

In FIG. 7, gates 504a and 504b of the set of gates 504 are separated from each other in the first direction X by the pitch CPP1.

In FIG. 7, gates 504b and 504c of the set of gates 504 are separated from each other in the first direction X by the pitch CPP2.

In FIG. 7, gates 504c and 504d of the set of gates 504 are separated from each other in the first direction X by the pitch CPP1.

In some embodiments, pitch CPP1 is not equal to pitch CPP2. In some embodiments, pitch CPP1 is greater than pitch CPP2.

In some embodiments, pitch CPP1 is equal to pitch CPP2.

In some embodiments, the pitch CPP1 is related to a range R3. In some embodiments, the range R3 ranges from about 1.2*CPP2 to about 1.3*CPP2. Other ranges or values for the range R3 are within the scope of the present disclosure.

Other ranges or values for the range R3 are within the scope of the present disclosure.

In some embodiments, if the pitch CPP1 is less than the range R3, then the pitch CPP1 may be insufficient to create enough separation between adjacent gates in the set of gates 504 thereby decreasing the manufacturing yield of integrated circuit 600A or 700 compared to other approaches.

In some embodiments, if the pitch CPP1 is less than the range R3, then the pitch CPP1 may be insufficient to create enough separation between adjacent gates in the set of gates 504 to improve the electrical characteristics of at least one of gate 504a or 504d compared with at least one of gate 504b or 504c thereby decreasing the performance of integrated circuit 600A or 700 of at least one or more of the effective channel length, the gate control capability, the transconductance gm, the output conductance gds, the signal path or the parasitic capacitance effect compared to other approaches that are not less than the range R3.

In some embodiments, if the pitch CPP1 is equal to the range R3, then the pitch CPP1 is sufficient to create enough separation between adjacent gates in the set of gates 504 thereby increasing the manufacturing yield of integrated circuit 600A or 700 compared to other approaches.

In some embodiments, if the pitch CPP1 is equal to the range R3, then the pitch CPP1 is sufficient to create enough separation between adjacent gates in the set of gates 504 to improve the electrical characteristics of at least one of gate 504a or 504d compared with at least one of gate 504b or 504c thereby increasing the performance of integrated circuit 600A or 700 of at least one or more of the effective channel length, the gate control capability, the transconductance gm, the output conductance gds, the signal path or the parasitic capacitance effect compared to other approaches that are less than the range R3.

In some embodiments, if the pitch CPP1 is greater than the range R3, then the pitch CPP1 is sufficient to create enough separation between adjacent gates in the set of gates 504 thereby increasing the manufacturing yield of integrated circuit 600A or 700 compared to other approaches.

In some embodiments, if the pitch CPP1 is greater than the range R3, then the pitch CPP1 may be sufficient to create enough separation between adjacent gates in the set of gates 504 to improve the electrical characteristics of at least one of gate 504a or 504d compared with at least one of gate 504b or 504c thereby increasing the performance of integrated circuit 600A or 700 of at least one or more of the effective channel length, the gate control capability, the transconductance gm, the output conductance gds, the signal path or the parasitic capacitance effect compared to other approaches that are less than the range R3.

Other configurations, arrangements on other levels or quantities of gates in the set of gates 504 are within the scope of the present disclosure.

Integrated circuit 700 achieves one or more of the benefits discussed herein.

Other materials, configurations, arrangements on other levels or quantities of elements in integrated circuit 700 are within the scope of the present disclosure.

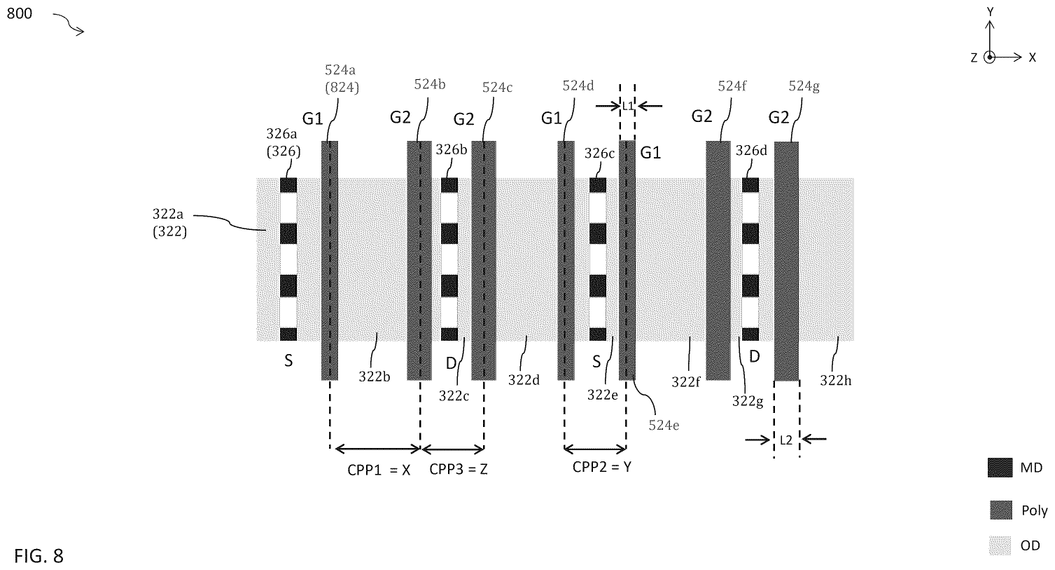

FIG. 8 is a diagram of an integrated circuit 800, in accordance with some embodiments. FIG. 8 is a top view of integrated circuit 800, in accordance with some embodiments.

Integrated circuit 800 is an embodiment of integrated circuit 200A of FIG. 2A, and similar detailed description is therefore omitted.

Integrated circuit 800 is a variation of integrated circuit 300C of FIGS. 3C-3D and integrated circuit 500B of FIG. 5B, and similar detailed description is therefore omitted. For example, in some embodiments, integrated circuit 800 combines the different poly pitch features of the set of gates 324 of FIGS. 3C-3D into a set of gates 824, which have different length features similar to the set of gates 524 of FIG. 5B, and similar detailed description is therefore omitted. In some embodiments, integrated circuit 800 combines the different poly pitch features of the set of gates 324 of FIGS. 3C-3D into the set of gates 824, and further combines the different active region features of FIG. 6B of the set of active regions 622 into the set of active regions 322 of FIG. 8, and similar detailed description is therefore omitted. In some embodiments, the set of active regions 322 of FIG. 8 is replaced by the set of active regions 622 of FIG. 6B, and similar detailed description is therefore omitted.

In comparison with integrated circuit 300C of FIGS. 3C-3D, the set of gates 824 replaces the set of gates 324 of FIGS. 3C-3D, and similar detailed description is therefore omitted.

In comparison with integrated circuit 500B of FIG. 5B, the set of gates 824 replaces the set of gates 524 of FIG. 5B, and similar detailed description is therefore omitted.

The set of gates 824 includes at least one or more of gates 524a, 524b, 524c, 524d, 524c or 524f or 524g.

Integrated circuit 800 includes the substrate 390, the insulating region 303, the set of active regions 322, the set of gates 824 and the set of contacts 326.

In FIG. 8, gates 524a and 524b of the set of gates 524 are separated from each other in the first direction X by the pitch CPP1.

In FIG. 8, gates 524b and 524c of the set of gates 524 are separated from each other in the first direction X by the pitch CPP3.

In FIG. 8, gates 524c and 524d of the set of gates 524 are separated from each other in the first direction X by the pitch CPP1.

In FIG. 8, gates 524d and 524e of the set of gates 524 are separated from each other in the first direction X by the pitch CPP2.

In FIG. 8, gates 524e and 524f of the set of gates 524 are separated from each other in the first direction X by the pitch CPP1.

In FIG. 8, gates 524f and 524g of the set of gates 524 are separated from each other in the first direction X by the pitch CPP3.

In some embodiments, at least one of pitch CPP1, CPP2 or CPP3 is not equal to at least another of pitch CPP1, CPP2 or CPP3.

In some embodiments, at least one of pitch CPP1, CPP2 or CPP3 is equal to at least another of pitch CPP1, CPP2 or CPP3.

In some embodiments, the pitch CPP1 is related to a range R4. In some embodiments, the range R4 ranges from about 1.3*CPP3 to about 1.4*CPP3.

In some embodiments, the pitch CPP2 is related to a range R5. In some embodiments, the range R5 ranges from about 1.2*CPP3 to about 1.3*CPP3.

Other ranges or values for the range R4 are within the scope of the present disclosure.

In some embodiments, if the pitch CPP1 is less than the range R4, then the pitch CPP1 may be insufficient to create enough separation between adjacent gates in the set of gates 824 thereby decreasing the manufacturing yield of integrated circuit 800 compared to other approaches.

In some embodiments, if the pitch CPP1 is less than the range R4, then the pitch CPP1 may be insufficient to create enough separation between adjacent gates in the set of gates 824 to improve the electrical characteristics of the set of gates 824 thereby decreasing the performance of integrated circuit 800 of at least one or more of the effective channel length, the gate control capability, the transconductance gm, the output conductance gds, the signal path or the parasitic capacitance effect compared to other approaches that are not less than the range R4.

In some embodiments, if the pitch CPP1 is equal to the range R4, then the pitch CPP1 is sufficient to create enough separation between adjacent gates in the set of gates 824 thereby increasing the manufacturing yield of integrated circuit 800 compared to other approaches.

In some embodiments, if the pitch CPP1 is equal to the range R4, then the pitch CPP1 is sufficient to create enough separation between adjacent gates in the set of gates 824 to improve the electrical characteristics of the set of gates 824 thereby increasing the performance of integrated circuit 800 of at least one or more of the effective channel length, the gate control capability, the transconductance gm, the output conductance gds, the signal path or the parasitic capacitance effect compared to other approaches that are less than the range R4.

In some embodiments, if the pitch CPP1 is greater than the range R4, then the pitch CPP1 is sufficient to create enough separation between adjacent gates in the set of gates 824 thereby increasing the manufacturing yield of integrated circuit 800 compared to other approaches.

In some embodiments, if the pitch CPP1 is greater than the range R4, then the pitch CPP1 may be sufficient to create enough separation between adjacent gates in the set of gates 824 to improve the electrical characteristics of the set of gates 824 compared with at least one of gate 524b or 524c thereby increasing the performance of integrated circuit 800 of at least one or more of the effective channel length, the gate control capability, the transconductance gm, the output conductance gds, the signal path or the parasitic capacitance effect compared to other approaches that are less than the range R4.

Other ranges or values for the range R5 are within the scope of the present disclosure.

In some embodiments, if the pitch CPP2 is less than the range R5, then the pitch CPP2 may be insufficient to create enough separation between adjacent gates in the set of gates 824 thereby decreasing the manufacturing yield of integrated circuit 800 compared to other approaches.

In some embodiments, if the pitch CPP2 is less than the range R5, then the pitch CPP2 may be insufficient to create enough separation between adjacent gates in the set of gates 824 to improve the electrical characteristics of the set of gates 824 thereby decreasing the performance of integrated circuit 800 of at least one or more of the effective channel length, the gate control capability, the transconductance gm, the output conductance gds, the signal path or the parasitic capacitance effect compared to other approaches that are not less than the range R5.

In some embodiments, if the pitch CPP2 is equal to the range R5, then the pitch CPP2 is sufficient to create enough separation between adjacent gates in the set of gates 824 thereby increasing the manufacturing yield of integrated circuit 800 compared to other approaches.

In some embodiments, if the pitch CPP2 is equal to the range R5, then the pitch CPP2 is sufficient to create enough separation between adjacent gates in the set of gates 824 to improve the electrical characteristics of the set of gates 824 thereby increasing the performance of integrated circuit 800 of at least one or more of the effective channel length, the gate control capability, the transconductance gm, the output conductance gds, the signal path or the parasitic capacitance effect compared to other approaches that are less than the range R5.

In some embodiments, if the pitch CPP2 is greater than the range R5, then the pitch CPP2 is sufficient to create enough separation between adjacent gates in the set of gates 824 thereby increasing the manufacturing yield of integrated circuit 800 compared to other approaches.

In some embodiments, if the pitch CPP2 is greater than the range R5, then the pitch CPP2 may be sufficient to create enough separation between adjacent gates in the set of gates 824 to improve the electrical characteristics of the set of gates 824 thereby increasing the performance of integrated circuit 800 of at least one or more of the effective channel length, the gate control capability, the transconductance gm, the output conductance gds, the signal path or the parasitic capacitance effect compared to other approaches that are less than the range R5.

In some embodiments, the discussion of at least one or more of ranges R1, R2, R3, R4 or R5 apply to one or more of the set of gates 304, 324, 504, 524, 624 or 824.

Other configurations, arrangements on other levels or quantities of gates in the set of gates 824 are within the scope of the present disclosure.

In some embodiments, integrated circuit 800 is a stacked MOSFET device of a single cascode device with a compact design or layout style. For example, in some embodiments, one or more drain and source regions of integrated circuit 800 are shared with each other thereby reducing an area of integrated circuit 800 compared to other approaches.

Integrated circuit 800 achieves one or more of the benefits discussed herein.

Other materials, configurations, arrangements on other levels or quantities of elements in integrated circuit 800 are within the scope of the present disclosure.

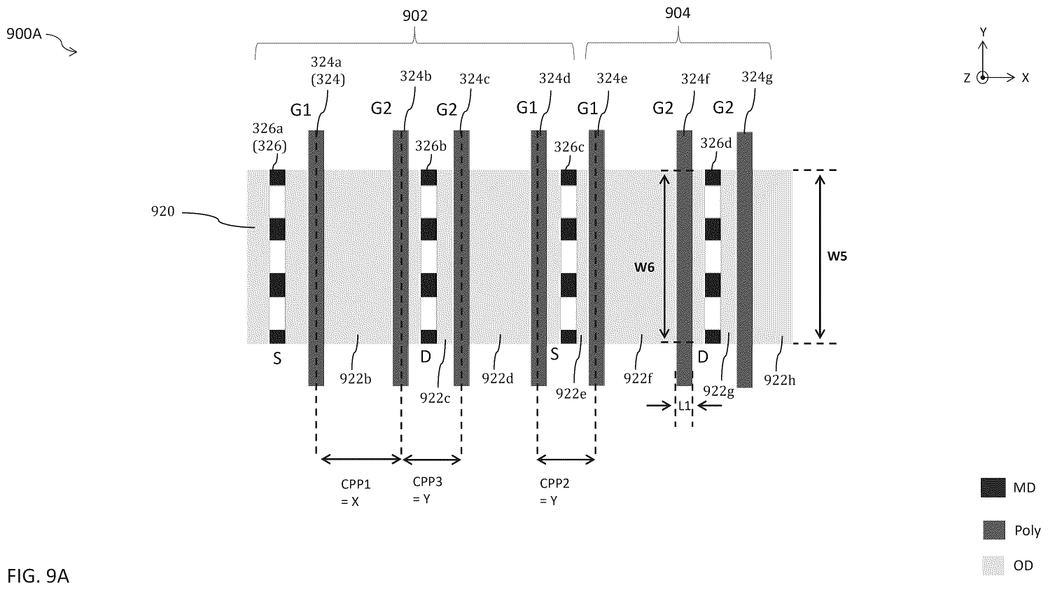

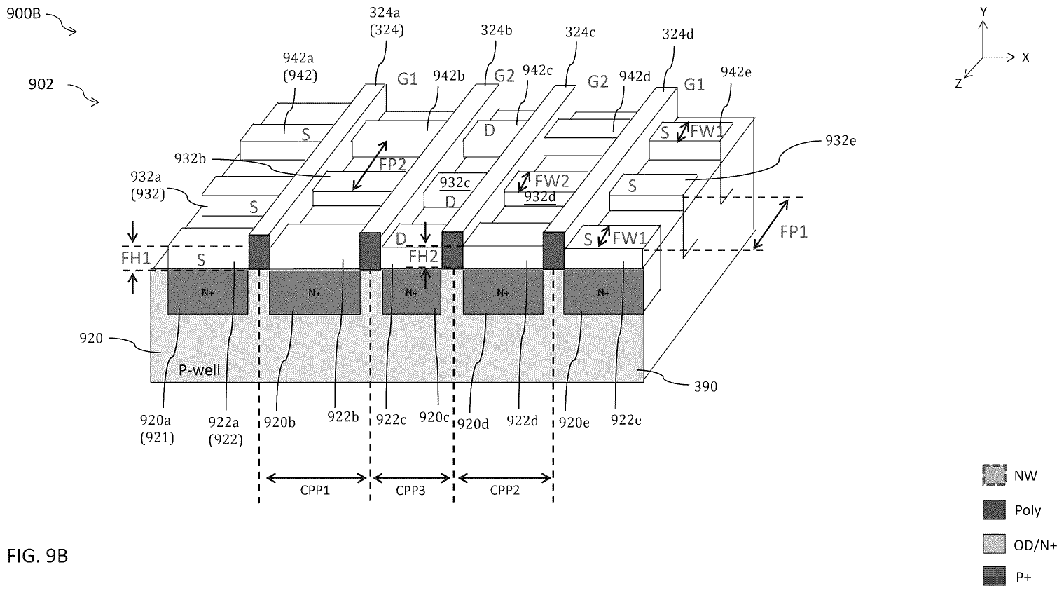

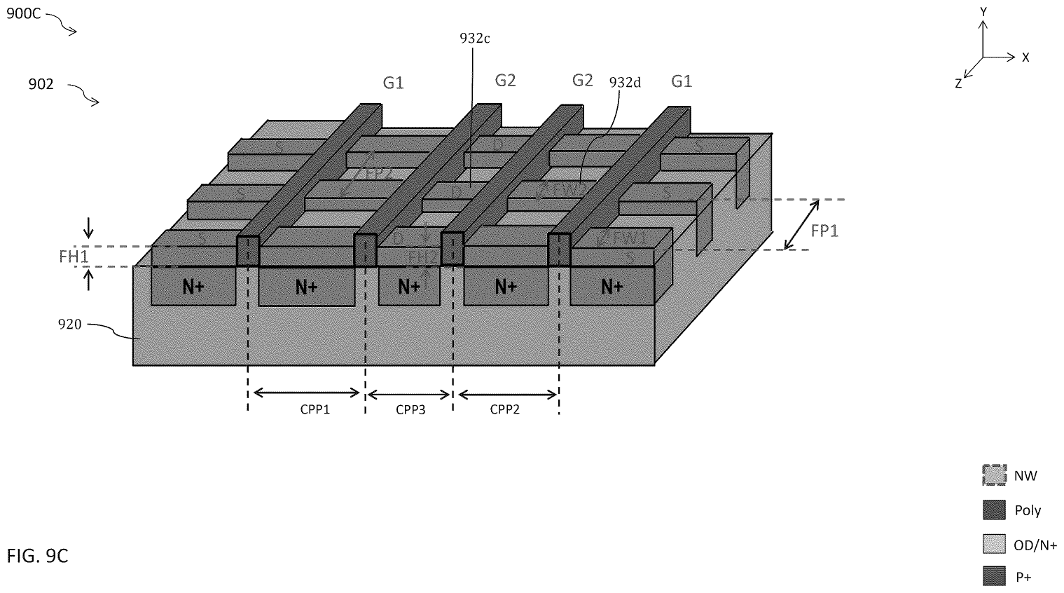

FIGS. 9A-9C are diagrams of an integrated circuit 900, in accordance with some embodiments.

FIG. 9A is a top view of integrated circuit 900, in accordance with some embodiments.

FIG. 9B is a perspective view of region 902 of integrated circuit 900, in accordance with some embodiments.

FIG. 9C is a perspective view of region 902 of integrated circuit 900, in accordance with some embodiments.

Integrated circuit 900 is an embodiment of integrated circuit 100B of FIG. 1B, and similar detailed description is therefore omitted. For example, in some embodiments, integrated circuit 900 is a finFET embodiment of integrated circuit 100B of FIG. 1B, and similar detailed description is therefore omitted.

Integrated circuit 900 is a variation of integrated circuit 300C of FIGS. 3C-3D, and similar detailed description is therefore omitted. In some embodiments, integrated circuit 900 is a finFET version of integrated circuit 300C of FIGS. 3C-3D, and similar detailed description is therefore omitted.

In comparison with integrated circuit 300C of FIGS. 3C-3D, a set of active regions 920 and a set of fins 922, 932 and 942 replace the set of active regions 322 of FIGS. 3C-3D, and similar detailed description is therefore omitted.

Integrated circuit 900 includes a region 902 and a region 904. Region 902 includes the substrate 390, the insulating region 303, the set of active regions 920, the set of fins 922, the set of fins 932, the set of fins 942, the set of gates 324 and the set of contacts 326.

Region 904 includes the substrate 390, the insulating region 303, the set of active regions 920, a set of fins (not shown) similar to the set of fins 922, a set of fins (not shown) similar to the set of fins 932, a set of fins (not shown) similar to the set of fins 942, the set of gates 324 and the set of contacts 326. For ease of illustration and brevity, the set of fins (not shown) similar to the set of fins 922, the set of fins (not shown) similar to the set of fins 932, and the set of fins (not shown) similar to the set of fins 942 are not described herein, but the description is similar to the description of the set of fins 922, the set of fins 932, the set of fins 942 of region 902.

The set of active regions 920 includes at least one or more of active regions 920a, 920b, . . . , 920o ((collectively referred to as a “set of active regions 921”), the set of fins 922, the set of fins 932 or the set of fins 942.

The set of active regions 921 is embedded in substrate 390. In some embodiments, the set of active regions 921 is similar to the set of active regions 322 of FIGS. 3C-3D, and similar detailed description is therefore omitted.

In some embodiments, at least one of the set of active regions 921, the set of fins 922, the set of fins 932 or the set of fins 942 have the same material and/or same dopant types as each other.

In some embodiments, at least one or more active regions 920a, 920b, . . . , 9200 is similar to at least one or more of active regions 322a, 322b, 322c, 322d, 322e, 322f, 322g or 322h, and similar detailed description is therefore omitted.

In some embodiments, the set of active regions 921 are active regions below the set of fins 922, the set of fins 932 or the set of fins 942. For example, 920a, 920b, . . . , 920e is the corresponding active region covered or below corresponding fin 922a, 922b, . . . , 922e of the set of fins 922, in accordance with some embodiments.

Similarly, 920f, 920g, . . . , 920j is the corresponding active region covered or below corresponding fin 932a, 932b, . . . , 932e of the set of fins 932, in accordance with some embodiments.

Similarly, 920k, 920l, . . . , 920o is the corresponding active region covered or below corresponding fin 942a, 942b, . . . , 942e of the set of fins 942, in accordance with some embodiments.

In some embodiments, at least one of the set of fins 922, 932 or 942 are located on the front-side (not labelled) of at least integrated circuit 900A.

The set of fins 922 includes at least one or more of fins 922a, 922b, 922c, 922d or 922e.

In some embodiments, the set of fins 922 are manufactured by a corresponding set of fin layout patterns of the set of fin layout patterns. In some embodiments, fins 922a, 922b, 922c, 922d or 922e of the set of fins 922 are manufactured by corresponding fin layout patterns of the set of fin layout patterns.

Each of fins 922a, 922b, 922c, 922d or 922e of the set of fins 922 extends in the second direction Y away from the substrate 390.

Gate 324a is between fins 922a and 922b.

Gate 324b is between fins 922b and 922c.

Gate 324c is between fins 922c and 922d.

Gate 324d is between fins 922d and 922e.

In some embodiments, each of fin 922a, 922b, 922c, 922d or 922e of the set of fins 922 is a source region and/or a drain region of one or more NMOS transistors, such as transistors 202 and 204.

In some embodiments, fin 922a is a source region of transistor 204.

In some embodiments, fin 922b is a drain region of transistor 204 and a source region of transistor 202.

In some embodiments, fin 922c is a drain region of transistor 202.

In some embodiments, fin 922d is a source region of transistor 202 and a drain region of transistor 204.

In some embodiments, fin 922e is a source region of transistor 204.

The set of fins 932 includes at least one or more of fins 932a, 932b, 932c, 932d or 932e.

In some embodiments, the set of fins 932 are manufactured by a corresponding set of fin layout patterns of the set of fin layout patterns. In some embodiments, fins 932a, 932b, 932c, 932d or 932e of the set of fins 932 are manufactured by corresponding fin layout patterns of the set of fin layout patterns.

Each of fin 932a, 932b, 932c, 932d or 932e of the set of fins 932 extends in the second direction Y away from the substrate 390.

Gate 324a is between fins 932a and 932b.

Gate 324b is between fins 932b and 932c.

Gate 324c is between fins 932c and 932d.

Gate 324d is between fins 932d and 932e.

In some embodiments, each of fins 932a, 932b, 932c, 932d or 932e of the set of fins 932 is a source region and/or a drain region of one or more NMOS transistors, such as transistors 202 and 204.

In some embodiments, fin 932a is a source region of transistor 204.

In some embodiments, fin 932b is a drain region of transistor 204 and a source region of transistor 202.

In some embodiments, fin 932c is a drain region of transistor 202.

In some embodiments, fin 932d is a source region of transistor 202 and a drain region of transistor 204.

In some embodiments, fin 932e is a source region of transistor 204.

The set of fins 942 includes at least one or more of fins 942a, 942b, 942c, 942d or 942e.

In some embodiments, the set of fins 942 are manufactured by a corresponding set of fin layout patterns of the set of fin layout patterns. In some embodiments, fins 942a, 942b, 942c, 942d or 942e of the set of fins 942 are manufactured by corresponding fin layout patterns of the set of fin layout patterns.

Each of fin 942a, 942b, 942c, 942d or 942e of the set of fins 942 extends in the second direction Y away from the substrate 390.

Gate 324a is between fins 942a and 942b.

Gate 324b is between fins 942b and 942c.

Gate 324c is between fins 942c and 942d.

Gate 324d is between fins 942d and 942e.

In some embodiments, each of fin 942a, 942b, 942c, 942d or 942e of the set of fins 942 is a source region and/or a drain region of one or more NMOS transistors, such as transistors 202 and 204.

In some embodiments, fin 942a is a source region of transistor 204.

In some embodiments, fin 942b is a drain region of transistor 204 and a source region of transistor 202.

In some embodiments, fin 942c is a drain region of transistor 202.

In some embodiments, fin 942d is a source region of transistor 202 and a drain region of transistor 204.

In some embodiments, fin 942e is a source region of transistor 204.

In some embodiments, at least one or more of fins 922a, 922b, . . . , 922e of the set of fins 922 is an N-type doped S/D region raised above the substrate 390.

In some embodiments, at least one or more of fins 932a, 932b, . . . , 932e of the set of fins 932 is an N-type doped S/D region raised above the substrate 390.

In some embodiments, at least one or more of fins 942a, 942b, . . . , 942e of the set of fins 942 is an N-type doped S/D region raised above the substrate 390.

In some embodiments, integrated circuit 900 is a multi-finger transistor device, and thus two or more of fins 922a, 922e, 932a, 932e, 942a or 942e which are source regions of integrated circuit 900 are electrically coupled together.

In some embodiments, integrated circuit 900 is a multi-finger transistor device, and thus two or more of fins 922c, 932c or 942c which are drain regions of integrated circuit 900 are electrically coupled together.

In some embodiments, integrated circuit 900 is a multi-finger transistor device, and thus two or more of fins 922b, 922d, 932b, 932d, 942b or 942d are electrically coupled together.

In some embodiments, one or more fins 922a, 922b, 922c, 922d or 922e of the set of fins 922 has a width FW1 in a fourth direction Z. In some embodiments, the fourth direction is opposite from the third direction Z. In some embodiments, the fourth direction is in a negative direction from the third direction Z.

In some embodiments, one or more fins 932a, 932b, 932c, 932d or 932e of the set of fins 932 has a width FW2 in the fourth direction Z.

In some embodiments, one or more fins 942a, 942b, 942c, 942d or 942e of the set of fins 942 has a width FW1 in the fourth direction Z.

In some embodiments, the width FW1 is different from the width FW2.

In some embodiments, the width FW1 is greater than the width FW2. In some embodiments, the width FW1 is related to a range R6. In some embodiments, the range R6 ranges from about 1.05*FW2 to about 1.15*FW2.

In some embodiments, width FW1 is the same as width FW2.

In some embodiments, the width FW1 and the width FW2 are swapped with each other such that one or more fins that previously had width FW1 are changed to width FW2 and/or one or more fins that previously had width FW2 are changed to width FW1.

In some embodiments, if the width FW1 is less than the range R6, then the width FW1 may be insufficient in the set of fins 924, 934 or 944 thereby decreasing the manufacturing yield of integrated circuit 900 compared to other approaches.

In some embodiments, if the width FW1 is less than the range R6, then the width FW1 may be insufficient in the set of fins 924, 934 or 944 to improve the electrical characteristics of the set of fins 924, 934 or 944 thereby decreasing the performance of integrated circuit 900 of at least one or more of the effective channel length, the gate control capability, the transconductance gm, the output conductance gds, the signal path or the parasitic capacitance effect compared to other approaches that are not less than the range R6.

In some embodiments, if the width FW1 is equal to the range R6, then the width FW1 is sufficient in the set of fins 924, 934 or 944 thereby increasing the manufacturing yield of integrated circuit 900 compared to other approaches.

In some embodiments, if the width FW1 is equal to the range R6, then the width FW1 is sufficient in the set of fins 924, 934 or 944 to improve the electrical characteristics of the set of fins 924, 934 or 944 thereby increasing the performance of integrated circuit 900 of at least one or more of the effective channel length, the gate control capability, the transconductance gm, the output conductance gds, the signal path or the parasitic capacitance effect compared to other approaches that are less than the range R6.

In some embodiments, if the width FW1 is greater than the range R6, then the width FW1 is sufficient in the set of fins 924, 934 or 944 thereby increasing the manufacturing yield of integrated circuit 900 compared to other approaches.

In some embodiments, if the width FW1 is greater than the range R6, then the width FW1 may be sufficient in the set of fins 924, 934 or 944 to improve the electrical characteristics of the set of fins 924, 934 or 944 thereby increasing the performance of integrated circuit 900 of at least one or more of the effective channel length, the gate control capability, the transconductance gm, the output conductance gds, the signal path or the parasitic capacitance effect compared to other approaches that are less than the range R6.

In some embodiments, one or more fins 922a, 932a, 942a, 922e, 932e or 942e has a height FH1 in the second direction Y.

In some embodiments, one or more fins 922c, 932c, 942c has a height FH2 in the second direction Y.

In some embodiments, one or more fins 922b, 932b, 942b, 922c, 932c or 942c has the height FH1 or FH2 in the second direction Y.

In some embodiments, the height FH1 is greater than the height FH2. In some embodiments, the height FH1 is related to a range R7. In some embodiments, the range R7 ranges from about 1.1*FH2 to about 1.2*FH2.

In some embodiments, the height FH1 is equal to the height FH2.

In some embodiments, the height FH1 and the height FH2 are swapped with each other such that one or more fins that previously had height FH1 are changed to height FH2 and/or one or more fins that previously had height FH2 are changed to height FH1.

In some embodiments, if the height FH1 is less than the range R7, then the height FH1 may be insufficient in the set of fins 924, 934 or 944 thereby decreasing the manufacturing yield of integrated circuit 900 compared to other approaches.

In some embodiments, if the height FH1 is less than the range R7, then the height FH1 may be insufficient in the set of fins 924, 934 or 944 to improve the electrical characteristics of the set of fins 924, 934 or 944 thereby decreasing the performance of integrated circuit 900 of at least one or more of the effective channel length, the gate control capability, the transconductance gm, the output conductance gds, the signal path or the parasitic capacitance effect compared to other approaches that are not less than the range R7.

In some embodiments, if the height FH1 is equal to the range R7, then the height FH1 is sufficient in the set of fins 924, 934 or 944 thereby increasing the manufacturing yield of integrated circuit 900 compared to other approaches.

In some embodiments, if the height FH1 is equal to the range R7, then the height FH1 is sufficient in the set of fins 924, 934 or 944 to improve the electrical characteristics of the set of fins 924, 934 or 944 thereby increasing the performance of integrated circuit 900 of at least one or more of the effective channel length, the gate control capability, the transconductance gm, the output conductance gds, the signal path or the parasitic capacitance effect compared to other approaches that are less than the range R7.

In some embodiments, if the height FH1 is greater than the range R7, then the height FH1 is sufficient in the set of fins 924, 934 or 944 thereby increasing the manufacturing yield of integrated circuit 900 compared to other approaches.

In some embodiments, if the height FH1 is greater than the range R7, then the height FH1 may be sufficient in the set of fins 924, 934 or 944 to improve the electrical characteristics of the set of fins 924, 934 or 944 thereby increasing the performance of integrated circuit 900 of at least one or more of the effective channel length, the gate control capability, the transconductance gm, the output conductance gds, the signal path or the parasitic capacitance effect compared to other approaches that are less than the range R7.

Fins 922a and 932a are separated from each other in the fourth direction by a pitch FP1.

Fins 932a and 942a are separated from each other in the fourth direction by the pitch FP1.

Fins 922b and 932b are separated from each other in the fourth direction by the pitch FP1 or a pitch FP2.

Fins 932b and 942b are separated from each other in the fourth direction by the pitch FP1 or the pitch FP2.

Fins 922c and 932c are separated from each other in the fourth direction by a pitch FP2.

Fins 932c and 942c are separated from each other in the fourth direction by the pitch FP2.

Fins 922d and 932d are separated from each other in the fourth direction by the pitch FP1 or the pitch FP2.

Fins 932d and 942d are separated from each other in the fourth direction by the pitch FP1 the pitch FP2.

Fins 922e and 932e are separated from each other in the fourth direction by the pitch FP1.

Fins 932e and 942e are separated from each other in the fourth direction by the pitch FP1.

In some embodiments, pitch FP1 is not equal to pitch FP2.

In some embodiments, the pitch FP1 is greater than the pitch FP2. In some embodiments, the pitch FP1 is related to a range R8. In some embodiments, the range R8 ranges from about 1.1*FP2 to about 1.3*FP2.

In some embodiments, pitch FP1 is equal to pitch FP2.

In some embodiments, the pitch FP1 and the pitch FP2 are swapped with each other such that one or more fins that previously had pitch FP1 are changed to pitch FP2 and/or one or more fins that previously had pitch FP2 are changed to pitch FP1.

Other ranges or values for at least one of range R6, R7 or R8 are within the scope of the present disclosure.

In some embodiments, if the pitch FP1 is less than the range R8, then the pitch FP1 may be insufficient to create enough separation between adjacent fins in the set of fins 924, 934 or 944 thereby decreasing the manufacturing yield of integrated circuit 900 compared to other approaches.

In some embodiments, if the pitch FP1 is less than the range R8, then the pitch FP1 may be insufficient to create enough separation between adjacent fins in the set of fins 924, 934 or 944 to improve the electrical characteristics of the set of fins 924, 934 or 944 thereby decreasing the performance of integrated circuit 900 of at least one or more of the effective channel length, the gate control capability, the transconductance gm, the output conductance gds, the signal path or the parasitic capacitance effect compared to other approaches that are not less than the range R8.

In some embodiments, if the pitch FP1 is equal to the range R8, then the pitch FP1 is sufficient to create enough separation between adjacent fins in the set of fins 924, 934 or 944 thereby increasing the manufacturing yield of integrated circuit 900 compared to other approaches.

In some embodiments, if the pitch FP1 is equal to the range R8, then the pitch FP1 is sufficient to create enough separation between adjacent fins in the set of fins 924, 934 or 944 to improve the electrical characteristics of the set of fins 924, 934 or 944 thereby increasing the performance of integrated circuit 900 of at least one or more of the effective channel length, the gate control capability, the transconductance gm, the output conductance gds, the signal path or the parasitic capacitance effect compared to other approaches that are less than the range R8.

In some embodiments, if the pitch FP1 is greater than the range R8, then the pitch FP1 is sufficient to create enough separation between adjacent fins in the set of fins 924, 934 or 944 thereby increasing the manufacturing yield of integrated circuit 900 compared to other approaches.

In some embodiments, if the pitch FP1 is greater than the range R8, then the pitch FP1 may be sufficient to create enough separation between adjacent fins in the set of fins 924, 934 or 944 to improve the electrical characteristics of the set of fins 924, 934 or 944 thereby increasing the performance of integrated circuit 900 of at least one or more of the effective channel length, the gate control capability, the transconductance gm, the output conductance gds, the signal path or the parasitic capacitance effect compared to other approaches that are less than the range R8.

Other configurations, arrangements on other levels or quantities of fins in the set of fins 922, 932 or 942 are within the scope of the present disclosure.

In some embodiments, by integrated circuit 900 including at least one of different fin pitches, different fin heights or different fin widths, integrated circuit 900 has improved effective channel length, improved gate control capability, improved transconductance gm, improved output conductance gds, improved signal path, and improved parasitic capacitance effect than other approaches, resulting in a more flexible design than other approaches.

Other materials, configurations, arrangements on other levels or quantities of elements in integrated circuit 900 are within the scope of the present disclosure.

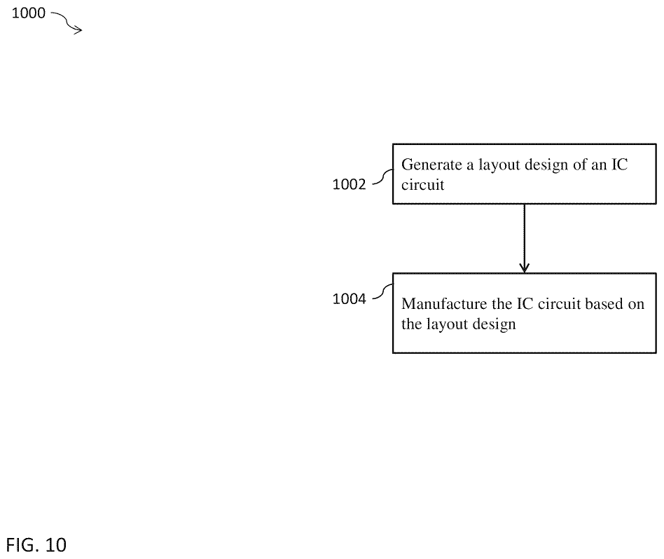

FIG. 10 is a flowchart of a method 1000 of forming or manufacturing an integrated circuit in accordance with some embodiments. It is understood that additional operations may be performed before, during, and/or after the method 1000 depicted in FIG. 10, and that some other operations may only be briefly described herein. In some embodiments, the method 1000 is usable to form integrated circuits, such as at least integrated circuit integrated circuit 100A, 100B, 200A, 200B, 300A, 300C, 400A, 400C, 500A, 500B, 600A, 600B, 700, 800 or 900.

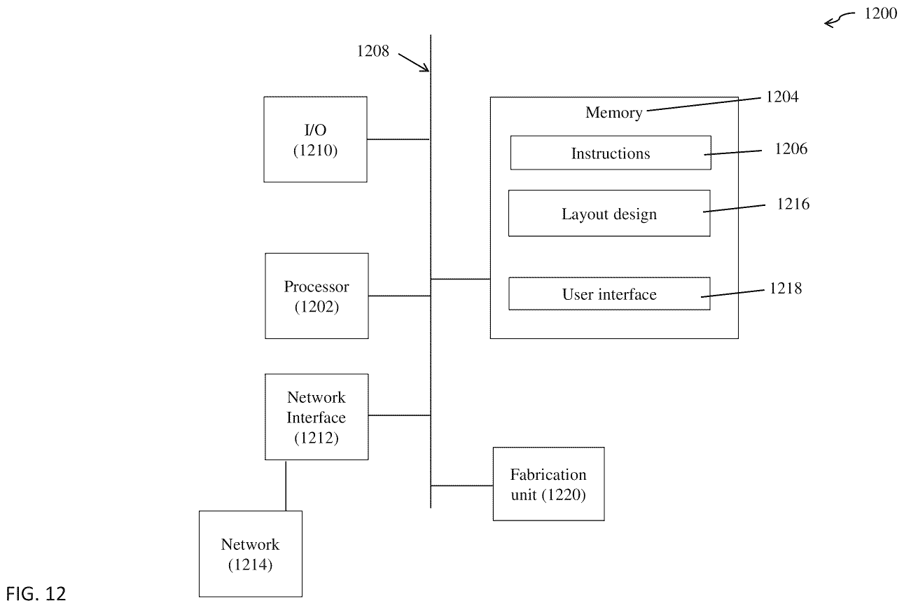

In operation 1002 of method 1000, a layout design of an integrated circuit is generated. Operation 1002 is performed by a processing device (e.g., processor 1202 (FIG. 12)) configured to execute instructions for generating a layout design. In some embodiments, the layout design of method 1000 includes one or more patterns similar to one or more features of at least integrated circuit 100A, 100B, 200A, 200B, 300A, 300C, 400A, 400C, 500A, 500B, 600A, 600B, 700, 800 or 900. In some embodiments, the layout design of the present application is in a graphic database system (GDSII) file format.

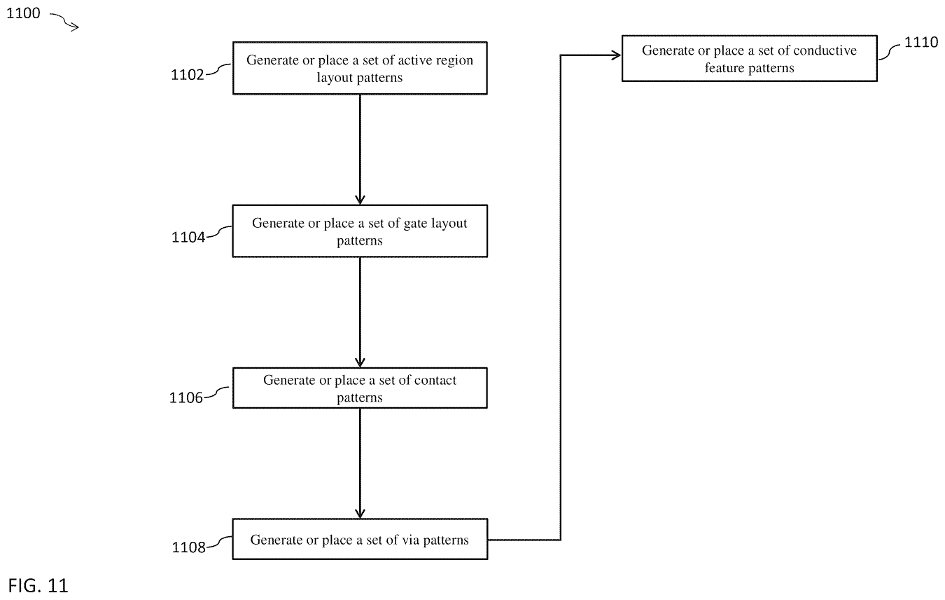

In operation 1004 of method 1000, the integrated circuit is manufactured based on the layout design. In some embodiments, operation 1004 of method 1000 comprises manufacturing at least one mask based on the layout design, and manufacturing the integrated circuit based on the at least one mask. In some embodiments, operation 1004 is an embodiment of method 1100 in FIG. 11.

FIG. 11 is a flowchart of a method 1100 of generating a layout design of an integrated circuit, in accordance with some embodiments. It is understood that additional operations may be performed before, during, and/or after the method 1100 depicted in FIG. 11, and that some other processes may only be briefly described herein. In some embodiments, method 1100 is an embodiment of operation 1102 of method 1100. In some embodiments, method 1100 is usable to generate one or more layout patterns similar to one or more features of at least integrated circuit 100A, 100B, 200A, 200B, 300A, 300C, 400A, 400C, 500A, 500B, 600A, 600B, 700, 800 or 900.

In some embodiments, method 1100 is usable to generate one or more layout patterns having structural relationships including alignment, pitches, lengths and widths, as well as configurations and layers similar to one or more features of at least integrated circuit 100A, 100B, 200A, 200B, 300A, 300C, 400A, 400C, 500A, 500B, 600A, 600B, 700, 800 or 900, and similar detailed description will not be described in FIG. 11, for brevity.

In operation 1102 of method 1100, a set of active region patterns is generated or placed on the layout design. In some embodiments, the set of active region patterns of method 1100 includes one or more regions similar to the set of active regions 302, 322, 402, 422, 522, 602, 622 or 920. In some embodiments, the set of active region patterns of method 1100 includes one or more regions similar to the set of fins 922, 932 or 942.

In operation 1104 of method 1100, a set of gate patterns is generated or placed on the layout design. In some embodiments, the set of gate patterns of method 1100 includes one or more gate patterns similar to at least the set of gates 304, 324, 504, 524, 624 or 824.

In operation 1106 of method 1100, a set of contact patterns is generated or placed on the layout design. In some embodiments, the set of contact patterns of method 1100 includes one or more contact patterns similar to at least the set of contacts 306, 326, 406, 426 or 526.

In operation 1110 of method 1100, a set of via patterns is generated or placed on the layout design. In some embodiments, the set of via patterns of method 1100 includes one or more vias similar to at least the set of vias 1510, 1512 or 1514. In some embodiments, the set of via patterns of method 1100 includes one or more vias similar to at least vias in the VG layer.

In operation 1112 of method 1100, a set of conductive feature patterns is generated or placed on the layout design. In some embodiments, the set of feature conductive patterns of method 1100 includes one or more conductive feature patterns similar to at least the set of conductors 1520, 1522 or 1532. In some embodiments, the first set of conductive patterns of method 1100 includes one or more conductors similar to at least conductors in the M0 layer.

In some embodiments, the first set of conductive patterns of method 1100 includes one or more conductors similar to at least conductors in the M1, M2, M3 or other upper metal layers.

One or more of the operations of methods 1000-1100 is performed by a processing device configured to execute instructions for manufacturing an integrated circuit, such as at least integrated circuit 100A, 100B, 200A, 200B, 300A, 300C, 400A, 400C, 500A, 500B, 600A, 600B, 700, 800 or 900. In some embodiments, one or more operations of methods 1000-1100 is performed using a same processing device as that used in a different one or more operations of methods 1000-1100. In some embodiments, a different processing device is used to perform one or more operations of methods 1000-1100 from that used to perform a different one or more operations of methods 1000-1100. In some embodiments, other order of operations of method 1000, 1100 or 1400 is within the scope of the present disclosure. Method 1000, 1100 or 1400 includes exemplary operations, but the operations are not necessarily performed in the order shown. Operations in method 1000, 1100 or 1400 may be added, replaced, changed order, and/or eliminated as appropriate, in accordance with the spirit and scope of disclosed embodiments.

FIG. 12 is a schematic view of a system 1200 for designing an IC layout design and manufacturing an IC circuit in accordance with some embodiments.

In some embodiments, system 1200 generates or places one or more IC layout designs described herein. System 1200 includes a hardware processor 1202 and a non-transitory, computer readable storage medium 1204 (e.g., memory 1204) encoded with, i.e., storing, the computer program code 1206, i.e., a set of executable instructions 1206. Computer readable storage medium 1204 is configured for interfacing with manufacturing machines for producing the integrated circuit. The processor 1202 is electrically coupled to the computer readable storage medium 1204 via a bus 1208. The processor 1202 is also electrically coupled to an I/O interface 1210 by bus 1208. A network interface 1212 is also electrically connected to the processor 1202 via bus 1208. Network interface 1212 is connected to a network 1214, so that processor 1202 and computer readable storage medium 1204 are capable of connecting to external elements via network 1214. The processor 1202 is configured to execute the computer program code 1206 (also referred to as “instructions” or “non-transitory instructions”) encoded in the computer readable storage medium 1204 in order to cause system 1200 to be usable for performing a portion or all of the operations as described in method 1000-1100.

In some embodiments, the processor 1202 is a central processing unit (CPU), a multi-processor, a distributed processing system, an application specific integrated circuit (ASIC), and/or a suitable processing unit.

In some embodiments, the computer readable storage medium 1204 is an electronic, magnetic, optical, electromagnetic, infrared, and/or a semiconductor system (or apparatus or device). For example, the computer readable storage medium 1204 includes a semiconductor or solid-state memory, a magnetic tape, a removable computer diskette, a random access memory (RAM), a read-only memory (ROM), a rigid magnetic disk, and/or an optical disk. In some embodiments using optical disks, the computer readable storage medium 1204 includes a compact disk-read only memory (CD-ROM), a compact disk-read/write (CD-R/W), and/or a digital video disc (DVD).

In some embodiments, the computer readable storage medium 1204 stores the computer program code 1206 configured to cause system 1200 to perform method 1000-1100. In some embodiments, the computer readable storage medium 1204 also stores information needed for performing method 1000-1100 as well as information generated during performing method 1000-1100, such as layout design 1216, user interface 1218 and fabrication unit 1220, and/or a set of executable instructions to perform the operation of method 1000-1100. In some embodiments, layout design 1216 comprises one or more layout patterns similar to one or more features of at least integrated circuit 100A, 100B, 200A, 200B, 300A, 300C, 400A, 400C, 500A, 500B, 600A, 600B, 700, 800 or 900.

In some embodiments, the computer readable storage medium 1204 stores instructions (e.g., computer program code 1206) for interfacing with manufacturing machines. The instructions (e.g., computer program code 1206) enable processor 1202 to generate manufacturing instructions readable by the manufacturing machines to effectively implement method 1000-1100 during a manufacturing process.

System 1200 includes I/O interface 1210. I/O interface 1210 is coupled to external circuitry. In some embodiments, I/O interface 1210 includes a keyboard, keypad, mouse, trackball, trackpad, and/or cursor direction keys for communicating information and commands to processor 1202.

System 1200 also includes network interface 1212 coupled to the processor 1202. Network interface 1212 allows system 1200 to communicate with network 1214, to which one or more other computer systems are connected. Network interface 1212 includes wireless network interfaces such as BLUETOOTH, WIFI, WIMAX, GPRS, or WCDMA; or wired network interface such as ETHERNET, USB, or IEEE-2094. In some embodiments, method 1000-1100 is implemented in two or more systems 1200, and information such as layout design, and user interface are exchanged between different systems 1200 by network 1214.

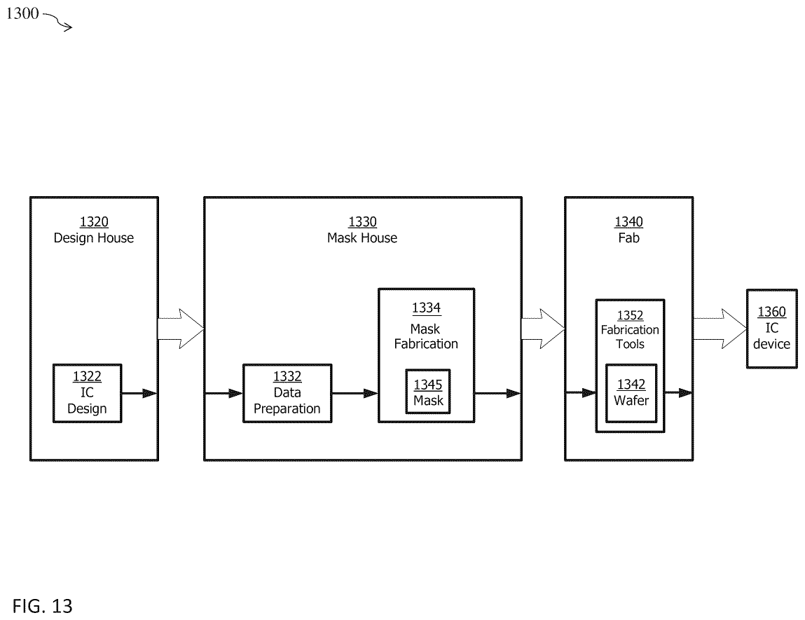

System 1200 is configured to receive information related to a layout design through I/O interface 1210 or network interface 1212. The information is transferred to processor 1202 by bus 1208 to determine a layout design for producing at least integrated circuit 100A, 100B, 200A, 200B, 300A, 300C, 400A, 400C, 500A, 500B, 600A, 600B, 700, 800 or 900. The layout design is then stored in computer readable storage medium 1204 as layout design 1216. System 1200 is configured to receive information related to a user interface through I/O interface 1210 or network interface 1212. The information is stored in computer readable storage medium 1204 as user interface 1218. System 1200 is configured to receive information related to a fabrication unit 1220 through I/O interface 1210 or network interface 1212. The information is stored in computer readable storage medium 1204 as fabrication unit 1220. In some embodiments, the fabrication unit 1220 includes fabrication information utilized by system 1200. In some embodiments, the fabrication unit 1220 corresponds to mask fabrication 1334 of FIG. 13.

In some embodiments, method 1000-1100 is implemented as a standalone software application for execution by a processor. In some embodiments, method 1000-1100 is implemented as a software application that is a part of an additional software application. In some embodiments, method 1000-1100 is implemented as a plug-in to a software application. In some embodiments, method 1000-1100 is implemented as a software application that is a portion of an EDA tool. In some embodiments, method 1000-1100 is implemented as a software application that is used by an EDA tool. In some embodiments, the EDA tool is used to generate a layout of the integrated circuit device. In some embodiments, the layout is stored on a non-transitory computer readable medium. In some embodiments, the layout is generated using a tool such as VIRTUOSO® available from CADENCE DESIGN SYSTEMS, Inc., or another suitable layout generating tool. In some embodiments, the layout is generated based on a netlist which is created based on the schematic design. In some embodiments, method 1000-1100 is implemented by a manufacturing device to manufacture an integrated circuit using a set of masks manufactured based on one or more layout designs generated by system 1200. In some embodiments, system 1200 is a manufacturing device configured to manufacture an integrated circuit using a set of masks manufactured based on one or more layout designs of the present disclosure. In some embodiments, system 1200 of FIG. 12 generates layout designs of an integrated circuit that are smaller than other approaches. In some embodiments, system 1200 of FIG. 12 generates layout designs of integrated circuit structure that occupy less area and provide better routing resources than other approaches.

FIG. 13 is a block diagram of an integrated circuit (IC) manufacturing system 1300, and an IC manufacturing flow associated therewith, in accordance with at least one embodiment of the present disclosure. In some embodiments, based on a layout diagram, at least one of (A) one or more semiconductor masks or (B) at least one component in a layer of a semiconductor integrated circuit is fabricated using manufacturing system 1300.

In FIG. 13, IC manufacturing system 1300 (hereinafter “system 1300”) includes entities, such as a design house 1320, a mask house 1330, and an IC manufacturer/fabricator (“fab”) 1340, that interact with one another in the design, development, and manufacturing cycles and/or services related to manufacturing an IC device 1360. The entities in system 1300 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, one or more of design house 1320, mask house 1330, and IC fab 1340 is owned by a single larger company. In some embodiments, one or more of design house 1320, mask house 1330, and IC fab 1340 coexist in a common facility and use common resources.

Design house (or design team) 1320 generates an IC design layout (“IC design”) 1322. IC design layout 1322 includes various geometrical patterns designed for an IC device 1360. The geometrical patterns correspond to patterns of metal, oxide, or semiconductor layers that make up the various components of IC device 1360 to be fabricated. The various layers combine to form various IC features. For example, a portion of IC design layout 1322 includes various IC features, such as an active region, gate electrode, source electrode and drain electrode, metal lines or vias of an interlayer interconnection, and openings for bonding pads, to be formed in a semiconductor substrate (such as a silicon wafer) and various material layers disposed on the semiconductor substrate. Design house 1320 implements a proper design procedure to form IC design layout 1322. The design procedure includes one or more of logic design, physical design or place and route. IC design layout 1322 is presented in one or more data files having information of the geometrical patterns. For example, IC design layout 1322 can be expressed in a GDSII file format or DFII file format.

Mask house 1330 includes data preparation 1332 and mask fabrication 1334. Mask house 1330 uses IC design layout 1322 to manufacture one or more masks 1345 to be used for fabricating the various layers of IC device 1360 according to IC design layout 1322. Mask house 1330 performs mask data preparation (“data preparation”) 1332, where IC design layout 1322 is translated into a representative data file (RDF). Mask data preparation 1332 provides the RDF to mask fabrication 1334. Mask fabrication 1334 includes a mask writer. A mask writer converts the RDF to an image on a substrate, such as a mask (reticle) 1345 or a semiconductor wafer 1342 (also referred to as “wafer 1342”). The IC design layout 1322 is manipulated by mask data preparation 1332 (also referred to as “data preparation 1332”) to comply with particular characteristics of the mask writer and/or requirements of IC fab 1340. In FIG. 13, mask data preparation 1332 and mask fabrication 1334 are illustrated as separate elements. In some embodiments, mask data preparation 1332 and mask fabrication 1334 can be collectively referred to as mask data preparation.

In some embodiments, mask data preparation 1332 includes optical proximity correction (OPC) which uses lithography enhancement techniques to compensate for image errors, such as those that can arise from diffraction, interference, other process effects and the like. OPC adjusts IC design layout 1322. In some embodiments, mask data preparation 1332 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, mask data preparation 1332 includes a mask rule checker (MRC) that checks the IC design layout that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout to compensate for limitations during mask fabrication 1334, which may undo part of the modifications performed by OPC in order to meet mask creation rules.

In some embodiments, mask data preparation 1332 includes lithography process checking (LPC) that simulates processing that will be implemented by IC fab 1340 to fabricate IC device 1360. LPC simulates this processing based on IC design layout 1322 to create a simulated manufactured device, such as IC device 1360. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (DOF), mask error enhancement factor (MEEF), other suitable factors, and the like or combinations thereof. In some embodiments, after a simulated manufactured device has been created by LPC, if the simulated device is not close enough in shape to satisfy design rules, OPC and/or MRC are be repeated to further refine IC design layout 1322.

It should be understood that the above description of mask data preparation 1332 has been simplified for the purposes of clarity. In some embodiments, data preparation 1332 includes additional features such as a logic operation (LOP) to modify the IC design layout according to manufacturing rules. Additionally, the processes applied to IC design layout 1322 during data preparation 1332 may be executed in a variety of different orders.

After mask data preparation 1332 and during mask fabrication 1334, a mask 1345 or a group of masks 1345 are fabricated based on the modified IC design layout 1322. In some embodiments, mask fabrication 1334 includes performing one or more lithographic exposures based on IC design layout 1322. In some embodiments, an electron-beam (e-beam) or a mechanism of multiple e-beams is used to form a pattern on a mask (photomask or reticle) 1345 based on the modified IC design layout 1322. The mask 1345 can be formed in various technologies. In some embodiments, the mask 1345 is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary version of mask 1345 includes a transparent substrate (e.g., fused quartz) and an opaque material (e.g., chromium) coated in the opaque regions of the binary mask. In another example, the mask 1345 is formed using a phase shift technology. In the phase shift mask (PSM) version of mask 1345, various features in the pattern formed on the mask are configured to have proper phase difference to enhance the resolution and imaging quality. In various examples, the phase shift mask can be attenuated PSM or alternating PSM. The mask(s) generated by mask fabrication 1334 is used in a variety of processes. For example, such a mask(s) is used in an ion implantation process to form various doped regions in the semiconductor wafer, in an etching process to form various etching regions in the semiconductor wafer, and/or in other suitable processes.

IC fab 1340 is an IC fabrication entity that includes one or more manufacturing facilities for the fabrication of a variety of different IC products. In some embodiments, IC Fab 1340 is a semiconductor foundry. For example, there may be a manufacturing facility for the front end fabrication of a plurality of IC products (front-end-of-line (FEOL) fabrication), while a second manufacturing facility may provide the back end fabrication for the interconnection and packaging of the IC products (back-end-of-line (BEOL) fabrication), and a third manufacturing facility may provide other services for the foundry entity.

IC fab 1340 includes wafer fabrication tools 1352 (hereinafter “fabrication tools 1352”) configured to execute various manufacturing operations on semiconductor wafer 1342 such that IC device 1360 is fabricated in accordance with the mask(s), e.g., mask 1345. In various embodiments, fabrication tools 1352 include one or more of a wafer stepper, an ion implanter, a photoresist coater, a process chamber, e.g., a CVD chamber or LPCVD furnace, a CMP system, a plasma etch system, a wafer cleaning system, or other manufacturing equipment capable of performing one or more suitable manufacturing processes as discussed herein.

IC fab 1340 uses mask(s) 1345 fabricated by mask house 1330 to fabricate IC device 1360. Thus, IC fab 1340 at least indirectly uses IC design layout 1322 to fabricate IC device 1360. In some embodiments, a semiconductor wafer 1342 is fabricated by IC fab 1340 using mask(s) 1345 to form IC device 1360. In some embodiments, the IC fabrication includes performing one or more lithographic exposures based at least indirectly on IC design layout 1322. Semiconductor wafer 1342 (also referred to as “wafer 1342”) includes a silicon substrate or other proper substrate having material layers formed thereon. Semiconductor wafer 1342 further includes one or more of various doped regions, dielectric features, multilevel interconnects, and the like (formed at subsequent manufacturing steps).

System 1300 is shown as having design house 1320, mask house 1330 or IC fab 1340 as separate components or entities. However, it is understood that one or more of design house 1320, mask house 1330 or IC fab 1340 are part of the same component or entity.

FIG. 14 is a functional flow chart of a method of manufacturing an integrated circuit (IC) device, in accordance with some embodiments. It is understood that additional operations may be performed before, during, and/or after the method 1400 depicted in FIG. 14, and that some other processes may only be briefly described herein. In some embodiments, other order of operations of method 1400 is within the scope of the present disclosure. Method 1400 includes exemplary operations, but the operations are not necessarily performed in the order shown. Operations may be added, replaced, changed order, and/or eliminated as appropriate, in accordance with the spirit and scope of disclosed embodiments.

In some embodiments, method 1400 is an embodiment of operation 1004 of method 1000. In some embodiments, the method 1400 is usable to manufacture or fabricate at least integrated circuit 100A, 100B, 200A, 200B, 300A, 300C, 400A, 400C, 500A, 500B, 600A, 600B, 700, 800 or 900.

In operation 1402 of method 1400, a first set of active regions of a first set of transistors is fabricated.

In some embodiments, the first set of active regions of method 1400 includes at least one of the set of active regions 302, 322, 402, 422, 522, 602, 622 or 920.

In some embodiments, the first set of active regions of method 1400 includes at least one of the set of active regions 302, 322, 402, 422, 522, 602, 622 or 920. In some embodiments, the first set of active regions of method 1400 includes at least one or more of the set of fins 922, 932 or 942.

In some embodiments, the first set of transistors of method 1400 includes at least one of transistor 102, 104, 202, 204, 210 or 212.

In some embodiments, the first set of active regions is on a first level (OD) of a substrate (390), and extends in the first direction X.

In some embodiments, the substrate of method 1400 includes at least one of substrate 390 or 490.

In some embodiments, the first set of active regions corresponds to a first transistor of the first set of transistors.

In some embodiments, the first transistor of method 1400 includes at least one of transistor 102, 104, 202, 204, 210 or 212.

In some embodiments, the first set of transistors of method 1400 includes one or more transistors described herein.

In some embodiments, operation 1402 further includes at least operation 1402a. In some embodiments, operation 1402a (not shown) includes fabricating source and drain regions of the set of transistors in a first well. In some embodiments, the first well includes at least one of substrate 390 or 490.

In some embodiments, the first well comprises p-type dopants. In some embodiments, the p-dopants include boron, aluminum or other suitable p-type dopants. In some embodiments, the first well comprises an epi-layer grown over a substrate. In some embodiments, the epi-layer is doped by adding dopants during the epitaxial process. In some embodiments, the epi-layer is doped by ion implantation after the epi-layer is formed. In some embodiments, the first well is formed by doping the substrate. In some embodiments, the doping is performed by ion implantation. In some embodiments, the first well has a dopant concentration ranging from 1×10¹² atoms/cm³ to 1×10¹⁴ atoms/cm³. Other dopant concentrations are in the scope of the present disclosure.

In some embodiments, the first well comprises n-type dopants. In some embodiments, the n-type dopants include phosphorus, arsenic or other suitable n-type dopants. In some embodiments, the n-type dopant concentration ranges from about 1×10¹² atoms/cm³ to about 1×10¹⁴ atoms/cm³. Other dopant concentrations are in the scope of the present disclosure.

In some embodiments, the formation of the source/drain features includes, a portion of the substrate is removed to form recesses at an edge of spacers, and a filling process is then performed by filling the recesses in the substrate. In some embodiments, the recesses are etched, for example, a wet etching or a dry etching, after removal of a pad oxide layer or a sacrificial oxide layer. In some embodiments, the etch process is performed to remove a top surface portion of the active region adjacent to an isolation region, such as an STI region. In some embodiments, the filling process is performed by an epitaxy or epitaxial (cpi) process. In some embodiments, the recesses are filled using a growth process which is concurrent with an etch process where a growth rate of the growth process is greater than an etch rate of the etch process. In some embodiments, the recesses are filled using a combination of growth process and etch process. For example, a layer of material is grown in the recess and then the grown material is subjected to an etch process to remove a portion of the material. Then a subsequent growth process is performed on the etched material until a desired thickness of the material in the recess is achieved. In some embodiments, the growth process continues until a top surface of the material is above the top surface of the substrate. In some embodiments, the growth process is continued until the top surface of the material is co-planar with the top surface of the substrate. In some embodiments, a portion of the first well is removed by an isotropic or an anisotropic etch process. The etch process selectively etches the first well without etching a gate structure and any spacers. In some embodiments, the etch process is performed using a reactive ion etch (RIE), wet etching, or other suitable techniques. In some embodiments, a semiconductor material is deposited in the recesses to form the source/drain features. In some embodiments, an epi process is performed to deposit the semiconductor material in the recesses. In some embodiments, the epi process includes a selective epitaxy growth (SEG) process, CVD process, molecular beam epitaxy (MBE), other suitable processes, and/or combination thereof. The epi process uses gaseous and/or liquid precursors, which interacts with a composition of substrate. In some embodiments, the source/drain features include epitaxially grown silicon (epi Si), silicon carbide, or silicon germanium. Source/drain features of the IC device associated with the gate structure are in-situ doped or undoped during the epi process in some instances. When source/drain features are undoped during the epi process, source/drain features are doped during a subsequent process in some instances. The subsequent doping process is achieved by an ion implantation, plasma immersion ion implantation, gas and/or solid source diffusion, other suitable processes, and/or combination thereof. In some embodiments, source/drain features are further exposed to annealing processes after forming source/drain features and/or after the subsequent doping process.

In operation 1404 of method 1400, a first set of gates of the first set of transistor is fabricated.

In some embodiments, the first set of gates of the first set of transistors of method 1400 includes at least one of the set of gates 304, 324, 504, 524, 624 or 824.

In some embodiments, the first set of gates of the first set of transistors of method 1400 includes at least one of gates 304a, 304d, 504a or 504d.

In some embodiments, the first set of gates of the first set of transistors of method 1400 includes at least one of the gates labelled with a G1 in FIGS. 3A-9C.

In some embodiments, the first set of gates of the first set of transistors of method 1400 includes at least one of the gates labelled with a G2 in FIGS. 3A-9C.

In some embodiments, the first set of gates extends in the second direction Y. In some embodiments, the first set of gates is on the second level. In some embodiments, the first set of gates overlaps the first set of active regions. In some embodiments, the first set of gates corresponds to the first transistor.

In operation 1406 of method 1400, a second set of gates of the first set of transistors is fabricated.

In some embodiments, the second set of gates of the first set of transistors of method 1400 includes at least one of the set of gates 304, 324, 504, 524, 624 or 824.

In some embodiments, the second set of gates of the first set of transistors of method 1400 includes at least one of gates 304b, 304c, 504b or 504c.

In some embodiments, the second set of gates of the first set of transistors of method 1400 includes at least one of the gates labelled with a G2 in FIGS. 3A-9C.

In some embodiments, the second set of gates of the first set of transistors of method 1400 includes at least one of the gates labelled with a G1 in FIGS. 3A-9C.

In some embodiments, the second set of gates extends in the second direction Y. In some embodiments, the second set of gates is on the second level. In some embodiments, the second set of gates overlaps the first set of active regions. In some embodiments, the second set of gates corresponds to the first transistor.

In some embodiments, each gate of the first set of gates is separated from an adjacent gate of the second set of gates in the second direction by a first pitch. In some embodiments, the first pitch of method 1400 includes at least one of pitch CPP, CPP1, CPP2 or CPP3.

In some embodiments, each gate of the second set of gates is separated from an adjacent gate of the second set of gates in the second direction by a second pitch different from the first pitch. In some embodiments, the second pitch of method 1400 includes at least one of pitch CPP, CPP1, CPP2 or CPP3.

In some embodiments, at least one of the first set of gates or the second set of gates of method 1400 includes the pitches, lengths and/or widths of the present application.

In some embodiments, at least fabricating the first set of gates of operation 1404 or fabricating the second set of gates of operation 1406 includes performing one or more deposition processes to form one or more dielectric material layers. In some embodiments, a deposition process includes a chemical vapor deposition (CVD), a plasma enhanced CVD (PECVD), an atomic layer deposition (ALD), or other process suitable for depositing one or more material layers. In some embodiments, fabricating the first set of gates or the second set of gates includes performing one or more deposition processes to form one or more conductive material layers. In some embodiments, fabricating the first set of gates or the second set of gates includes forming gate electrodes or dummy gate electrodes. In some embodiments, fabricating the first set of gates or the second set of gates includes depositing or growing at least one dielectric layer. In some embodiments, the first set of gates or the second set of gates are formed using a doped or non-doped polycrystalline silicon (or polysilicon). In some embodiments, the the first set of gates or the second set of gates include a metal, such as Al, Cu, W, Ti, Ta, TiN, TaN, NiSi, CoSi, other suitable conductive materials, or combinations thereof.

In operation 1408 of method 1400, a first conductive material is deposited on a front-side of the substrate on a third level thereby forming a first set of contacts.

In some embodiments, the first set of contacts of method 1400 includes at least the set of contacts 306, 326, 406, 426 or 526.

In some embodiments, the first set of contacts is electrically coupled to the first set of active regions. In some embodiments, the third level is different from the first level. In some embodiments, the third level of method 1400 includes at least the MD level.

In some embodiments, operation 1408 includes at least depositing a first conductive region over the drain region thereby forming a drain contact of one or more transistors in the present application, and depositing a second conductive region over the source region thereby forming a source contact of one or more transistors in the present application.

In some embodiments, operation 1408 further includes depositing a third conductive region over one or more gates of one or more transistors in the present application thereby forming a gate contact of one or more transistors in the present application.

In some embodiments, at least one of the first conductive material, the first conductive region, the second conductive region or the third conductive region of method 1400 are formed using a combination of photolithography and material removal processes to form openings in an insulating layer (not shown) over the substrate. In some embodiments, the photolithography process includes patterning a photoresist, such as a positive photoresist or a negative photoresist. In some embodiments, the photolithography process includes forming a hard mask, an antireflective structure, or another suitable photolithography structure. In some embodiments, the material removal process includes a wet etching process, a dry etching process, an RIE process, laser drilling or another suitable etching process. The openings are then filled with conductive material, e.g., copper, aluminum, titanium, nickel, tungsten, or other suitable conductive material. In some embodiments, the openings are filled using CVD, PVD, sputtering, ALD or other suitable formation process.

In operation 1410 of method 1400, a first set of conductors is electrically coupled to the first set of gates, and a second set of conductors is electrically coupled to the second set of gates.

In some embodiments, the first set of conductors of method 1400 includes at least the set of conductors 1520.

In some embodiments, the second set of conductors of method 1400 includes at least one of the set of conductors 1522 or 1532.

In some embodiments, operation 1410 includes at least one of more of operations 1412, 1414 or 1416.

In operation 1412 of method 1400, a first set of vias is fabricated.

In some embodiments, the first set of vias is fabricated over the first set of gates. In some embodiments, the first set of vias is electrically coupled to the first set of gates.

In some embodiments, the first set of vias are formed on the front-side of the substrate.

In some embodiments, the first set of vias of method 1400 includes at least one or more portions of at least the set of vias 1510. In some embodiments, the first set of vias includes at least one or more vias in the VG level.

In some embodiments, operation 1412 includes forming a first set of self-aligned contacts (SACs) in the insulating layer over the front-side of the substrate or wafer.

The set of vias 1510 includes one or more of vias 1510a, 1510b, 1510c, 1510d, 1510e, 1510f, 1510g or 1510h.

In some embodiments, the set of vias 1510 are between the set of gates 524 and the set of conductors 1520. The set of vias 1510 is embedded in insulating region 303.

The set of vias 1510 is located where the set of gates 524 are overlapped by the set of conductors 1520.

Via 1510a, 1510b, 1510c or 1510d is between corresponding gate 524a, 524d, 524e or 524h and conductor 1520b.

Via 1510e, 1510f, 1510g or 1510h is between corresponding gate 524a, 524d, 524e or 524h and conductor 1520c.

The set of vias 1510 is configured to electrically couple the set of conductors 1520 and the set of gates 524.

In some embodiments, the set of vias 1510 is positioned at a via over gate (VG) level of one or more of integrated circuit 800A-800B. In some embodiments, the VG level is above the M0 and the POLY level. In some embodiments, the VG level is between the second layout level and the fourth layout level. Other layout levels are within the scope of the present disclosure.

Other configurations, arrangements on other layout levels or quantities of vias in the set of vias 1510 are within the scope of the present disclosure.

In operation 1414 of method 1400, a second set of vias is fabricated.

In some embodiments, the second set of vias is fabricated over the second set of gates. In some embodiments, the second set of vias is electrically coupled to the second set of gates.

In some embodiments, the second set of vias are formed on the front-side of the substrate. In some embodiments, the second set of vias of method 1400 includes at least one or more portions of at least the set of vias 1512 or 1514. In some embodiments, the second set of vias includes at least one or more vias in the VG level.

In some embodiments, operation 1412 includes forming a second set of self-aligned contacts (SACs) in the insulating layer over the front-side of the substrate or wafer.

The set of vias 1512 includes one or more of vias 1512a, 1512b, 1512c, 1512d, 1512e, 1512f, 1512g or 1512h.

In some embodiments, the set of vias 1512 are between the set of gates 524 and the set of conductors 1522. The set of vias 1512 is embedded in insulating region 303.

The set of vias 1512 is located where the set of gates 524 are overlapped by the set of conductors 1522.

Via 1512a, 1512b, 1512c or 1512d is between corresponding gate 524b, 524c, 524f or 524g and conductor 1522b.

Via 1512e, 1512f, 1512g or 1512h is between corresponding 524b, 524c, 524f or 524g and conductor 1522c.

The set of vias 1512 is configured to electrically couple the set of conductors 1522 and the set of gates 524.

In some embodiments, the set of vias 1512 is positioned at the VG level of one or more of integrated circuit 800A-800B.

Other configurations, arrangements on other layout levels or quantities of vias in the set of vias 1512 are within the scope of the present disclosure.

The set of vias 1514 includes one or more of vias 1512e, 1512f, 1512g or 1512h.

In some embodiments, the set of vias 1514 are between the set of gates 524 and the set of conductors 1532.

The set of vias 1514 is located where the set of gates 524 are overlapped by the set of conductors 1532.

The set of vias 1514 is configured to electrically couple the set of conductors 1532 and the set of gates 524.

In some embodiments, the set of vias 1514 is positioned at the VG level of one or more of integrated circuit 800B.

Other configurations, arrangements on other layout levels or quantities of vias in the set of vias 1514 are within the scope of the present disclosure.

In operation 1416 of method 1400, a second conductive material is deposited on a front-side of the substrate on a fourth level thereby forming a first set of conductors and a second set of conductors.

In some embodiments, the first set of conductors of method 1400 includes at least the set of conductors 1520.

The set of conductors 1520 includes one or more of conductors 1520a, 1520b or 1520c.

In some embodiments, the set of conductors 1520 corresponds to a set of conductive structures. The set of conductors 1520 is embedded in insulating region 303.

The set of conductors 1520 overlaps the set of gates 524.

Conductor 1520b overlaps at least one or more of gates 524a, 524b, 524c, 524d, 524c, 524f, 524g or 524h.

Conductor 1520b is electrically to at least one or more of gates 524a, 524d, 524e or 524h by corresponding via 1510a, 1510b, 1510c or 1510d.

Conductor 1520c overlaps at least one or more of gates 524a, 524b, 524c, 524d, 524c, 524f, 524g or 524h.

Conductor 1520c is electrically to at least one or more of gates 524a, 524d, 524e or 524h by corresponding via 1510e, 1510f, 1510g or 1510h.

The set of conductors 1520 extends in the first direction X and the second direction Y. Conductor 1520a extends in the second direction Y. Conductors 1520b and 1520c extend in the first direction X.

Each conductor in the set of conductors 1520 is separated from an adjacent conductor in the set of conductors 1520 in at least the first direction X or the second direction Y.

In some embodiments, the set of conductors 1520 is configured to provide the routing of signals, and are referred to as “signal lines.” For example, the set of conductors 1520 is configured to route signals to/from other portions of integrated circuit 800A or other devices (not shown for case of illustration) to the set of gates 524.

In some embodiments, the set of conductors 1520 are located on the front-side (not labelled) of integrated circuit 800A-800B. In some embodiments, the set of conductors 1520 is on a fourth level. In some embodiments, the fourth level is different from the first level, the second level and the third level. In some embodiments, the fourth level corresponds to the metal-0 (M0) level of one or more of integrated circuit 800A-800B. In some embodiments, the M0 level is above the OD level, the POLY level, the MD level, the VG level and the VD level. In some embodiments, the set of conductors 1520 are located on other metal layers (e.g., metal-1 (M1), metal-2 (M2), etc.).

Other configurations, arrangements on other layout levels or quantities of patterns in the set of conductors 1520 are within the scope of the present disclosure.

Other configurations, arrangements on other layout levels or quantities of conductors in the set of conductors 1520 are within the scope of the present disclosure.

In some embodiments, the second set of conductors of method 1400 includes at least the set of conductors 1522 or 1532.

The set of conductors 1522 includes one or more of conductors 1522a, 1522b or 1522c.

In some embodiments, the set of conductors 1522 corresponds to a set of conductive structures. The set of conductors 1522 is embedded in insulating region 303.

The set of conductors 1522 overlaps the set of gates 524.

Conductor 1522b overlaps at least one or more of gates 524a, 524b, 524c, 524d, 524c, 524f, 524g or 524h.

Conductor 1522b is electrically to at least one or more of gates 524b, 524c, 524f or 524g by corresponding via 1512a, 1512b, 1512c or 1512d.

Conductor 1522c overlaps at least one or more of gates 524a, 524b, 524c, 524d, 524e, 524f, 524g or 524h.

Conductor 1522c is electrically to at least one or more of 524b, 524c, 524f or 524g by corresponding via 1512e, 1512f, 1512g or 1512h.

The set of conductors 1522 extends in the first direction X and the second direction Y. Conductor 1522a extends in the second direction Y. Conductors 1522b and 1522c extend in the first direction X.

Each conductor in the set of conductors 1522 is separated from an adjacent conductor in the set of conductors 1522 in at least the first direction X or the second direction Y.

In some embodiments, the set of conductors 1522 is configured to provide the routing of signals, and are referred to as “signal lines.” For example, the set of conductors 1522 is configured to route signals to/from other portions of integrated circuit 800A or other devices (not shown for ease of illustration) to the set of gates 524.

In some embodiments, the set of conductors 1522 are located on the front-side (not labelled) of integrated circuit 800A-800B. In some embodiments, the set of conductors 1522 is on the fourth level.

Other configurations, arrangements on other layout levels or quantities of patterns in the set of conductors 1522 are within the scope of the present disclosure.

Other configurations, arrangements on other layout levels or quantities of conductors in the set of conductors 1522 are within the scope of the present disclosure.

The set of conductors 1532 includes conductor 1522c.

The set of conductors 1522 overlaps the set of gates 524.

In some embodiments, the set of conductors 1532 is on the fourth level.

Other configurations, arrangements on other layout levels or quantities of patterns in the set of conductors 1532 are within the scope of the present disclosure.

In some embodiments, the first set of conductors is electrically coupled to the first set of gates by the first set of vias.

In some embodiments, the second set of conductors is electrically coupled to the second set of gates by the second set of vias.

In some embodiments, the fourth level is different from the first level, the second level, and the third level. In some embodiments, the fourth level of method 1400 includes at least the M0, M1, M2, M3 level or other metallization levels.

In some embodiments, the second conductive material of method 1400 are formed using a combination of photolithography and material removal processes to form openings in an insulating layer (not shown) over the substrate. In some embodiments, the photolithography process includes patterning a photoresist, such as a positive photoresist or a negative photoresist. In some embodiments, the photolithography process includes forming a hard mask, an antireflective structure, or another suitable photolithography structure. In some embodiments, the material removal process includes a wet etching process, a dry etching process, an RIE process, laser drilling or another suitable etching process. The openings are then filled with conductive material, e.g., copper, aluminum, titanium, nickel, tungsten, or other suitable conductive material. In some embodiments, the openings are filled using CVD, PVD, sputtering, ALD or other suitable formation process.

In some embodiments, at least one or more operations of method 1400 is performed to fabricate at least one of transistor 102, 104, 202, 204, 210 or 212, and the operations are similar to that described above, and similar detailed description is therefore omitted. In some embodiments, one or more of the operations of method 1400 is performed to manufacture an integrated circuit similar to integrated circuit 100A, 100B, 200A, 200B, 300A, 300C, 400A, 400C, 500A, 500B, 600A, 600B, 700, 800 or 900, and then one or more of the operations of method 1400 is repeated to manufacture additional integrated circuits similar to integrated circuit 100A, 100B, 200A, 200B, 300A, 300C, 400A, 400C, 500A, 500B, 600A, 600B, 700, 800 or 900.

In some embodiments, method 1400 is usable to manufacture an integrated circuit 1500A with gate routing that utilizes CG gate routing designs. In some embodiments, gates 524a, 524d, 524c or 524h are coupled by the set of conductors 1520 in a 2-side connection thereby lowering the gate resistance (Rg) of integrated circuit 1500A compared to other approaches.

In some embodiments, gates 524b, 524c, 524f or 524g are coupled by the set of conductors 1522 in a 2-side connection thereby lowering the gate resistance (Rg) of integrated circuit 1500A compared to other approaches.

In some embodiments, method 1400 is usable to manufacture an integrated circuit 1500B with CG gate routing designs. In some embodiments, gates 524a, 524d, 524c or 524h are coupled by the set of conductors 1520 in a 2-side connection thereby lowering the gate resistance (Rg) of integrated circuit 1500B compared to other approaches.

In some embodiments, gates 524b, 524c, 524f or 524g are coupled by the set of conductors 1532 in a 1-side connection thereby lowering the parasitic capacitance of integrated circuit 1500B compared to other approaches.

In some embodiments, at least one or more operations of method 1400 is performed by system 1300 of FIG. 13. In some embodiments, at least one method(s), such as method 1400 discussed above, is performed in whole or in part by at least one manufacturing system, including system 1300.

One or more of the operations of method 1400 is performed by IC fab 1340 (FIG. 13) to fabricate IC device 1360. In some embodiments, one or more of the operations of method 1400 is performed by fabrication tools 1352 to fabricate wafer 1342.

In some embodiments, one or more of the operations of at least method 900, 1000A or 1100 is not performed. While method 1100 was described above with reference to FIGS. 3A-3D, it is understood that method 1100 utilizes the features of one or more of FIGS. 1A-2B & 4A-9C, in some embodiments. In these embodiments, other operations of method 1100 would be performed consistent with the description and operation of integrated circuit 300A or 300C.

Other transistor types or other numbers of transistors in at least integrated circuit 100A, 100B, 200A, 200B, 300A, 300C, 400A, 400C, 500A, 500B, 600A, 600B, 700, 800 or 900 are within the scope of the present disclosure.

Furthermore, various PMOS transistors shown in FIGS. 1A-14 are of a particular dopant type (e.g., N-type or P-type) and are for illustration purposes. Embodiments of the disclosure are not limited to a particular transistor type, and one or more of the PMOS or NMOS transistors shown in FIGS. 1A-14 can be substituted with a corresponding transistor of a different transistor/dopant type. Similarly, the low or high logical value of various signals used in the above description is also used for illustration. Embodiments of the disclosure are not limited to a particular logical value when a signal is activated and/or deactivated. Selecting different logical values is within the scope of various embodiments. Selecting different numbers of PMOS transistors in 1A-14 is within the scope of various embodiments.

One aspect of this description relates to an integrated circuit. In some embodiments, the integrated circuit includes a first set of active regions extending in a first direction, and being on a first level of a substrate, the first set of active regions corresponding to a first transistor. In some embodiments, the integrated circuit further includes a first set of gates extending in a second direction different from the first direction, the first set of gates being on a second level different from the first level, the first set of gates overlapping the first set of active regions, and the first set of gates corresponds to the first transistor. In some embodiments, the integrated circuit further includes a second set of gates extending in the second direction, being on the second level, overlapping the first set of active regions, and being separated from the first set of gates in the first direction. In some embodiments, each gate of the first set of gates is separated from an adjacent gate of the second set of gates in the second direction by a first pitch. In some embodiments, each gate of the second set of gates is separated from an adjacent gate of the second set of gates in the second direction by a second pitch different from the first pitch.

Another aspect of this description relates to an integrated circuit. In some embodiments, the integrated circuit includes a first set of active regions extending in a first direction, and being on a first level of a substrate, the first set of active regions corresponding to a first transistor or a second transistor. In some embodiments, the integrated circuit further includes a first set of gates extending in a second direction different from the first direction, the first set of gates being on a second level different from the first level, the first set of gates overlapping the first set of active regions, and the first set of gates corresponds to a gate of the first transistor. In some embodiments, the integrated circuit further includes a second set of gates extending in the second direction, being on the second level, overlapping the first set of active regions, and being separated from the first set of gates in the first direction, and the second set of gates corresponds to a gate of the second transistor. In some embodiments, each gate of the first set of gates is separated from an adjacent gate of the second set of gates in the second direction by a first pitch. In some embodiments, each gate of the second set of gates is separated from an adjacent gate of the second set of gates in the second direction by a second pitch different from the first pitch. In some embodiments, each gate of the first set of gates is separated from an adjacent gate of the first set of gates in the second direction by a third pitch different from the first pitch and the second pitch.

Yet another aspect of this description relates to a method of manufacturing an integrated circuit. In some embodiments, the method includes fabricating a first set of active regions of a first set of transistors, the first set of active regions being on a first level of a substrate, and extending in a first direction, and the first set of active regions corresponding to a first transistor of the first set of transistors. In some embodiments, the method further includes fabricating a first set of gates of the first set of transistors, the first set of gates extending in a second direction different from the first direction, the first set of gates being on a second level different from the first level, the first set of gates overlapping the first set of active regions, and the first set of gates corresponding to the first transistor. In some embodiments, the method further includes fabricating a second set of gates of the first set of transistors, the second set of gates extending in the second direction, the second set of gates being on the second level, the second set of gates overlapping the first set of active regions, and the second set of gates corresponding to the first transistor or a second transistor of the first set of transistors. In some embodiments, the method further includes electrically coupling a first set of conductors to the first set of gates, and a second set of conductors to the second set of gates. In some embodiments, each gate of the first set of gates is separated from an adjacent gate of the second set of gates in the second direction by a first pitch. In some embodiments, each gate of the second set of gates is separated from an adjacent gate of the second set of gates in the second direction by a second pitch different from the first pitch.

A number of embodiments have been described. It will nevertheless be understood that various modifications may be made without departing from the spirit and scope of the disclosure. For example, various transistors being shown as a particular dopant type (e.g., N-type or P-type Metal Oxide Semiconductor (NMOS or PMOS)) are for illustration purposes. Embodiments of the disclosure are not limited to a particular type. Selecting different dopant types for a particular transistor is within the scope of various embodiments. The low or high logical value of various signals used in the above description is also for illustration. Various embodiments are not limited to a particular logical value when a signal is activated and/or deactivated. Selecting different logical values is within the scope of various embodiments. In various embodiments, a transistor functions as a switch. A switching circuit used in place of a transistor is within the scope of various embodiments. In various embodiments, a source of a transistor can be configured as a drain, and a drain can be configured as a source. As such, the term source and drain are used interchangeably. Various signals are generated by corresponding circuits, but, for simplicity, the circuits are not shown.

Various figures show capacitive circuits using discrete capacitors for illustration. Equivalent circuitry may be used. For example, a capacitive device, circuitry or network (e.g., a combination of capacitors, capacitive elements, devices, circuitry, or the like) can be used in place of the discrete capacitor. The above illustrations include exemplary steps, but the steps are not necessarily performed in the order shown. Steps may be added, replaced, changed order, and/or eliminated as appropriate, in accordance with the spirit and scope of disclosed embodiments.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit comprising:
a first set of active regions extending in a first direction, and being on a first level of a substrate, the first set of active regions corresponding to a first transistor;
a first set of gates extending in a second direction different from the first direction, the first set of gates being on a second level different from the first level, the first set of gates overlapping the first set of active regions, and the first set of gates corresponds to the first transistor; and
a second set of gates extending in the second direction, being on the second level, overlapping the first set of active regions, and being separated from the first set of gates in the first direction;
wherein each gate of the first set of gates is separated from an adjacent gate of the second set of gates in the second direction by a first pitch; and
each gate of the second set of gates is separated from an adjacent gate of the second set of gates in the second direction by a second pitch different from the first pitch.

2. The integrated circuit of claim 1, wherein the second set of gates corresponds to the first transistor.

3. The integrated circuit of claim 2, wherein
each gate of the first set of gates has a first length in the first direction; and
each gate of the second set of gates has a second length in the first direction.

4. The integrated circuit of claim 3, wherein the first length is less than the second length.

5. The integrated circuit of claim 3, wherein the first length is equal to the second length.

6. The integrated circuit of claim 2, wherein
each gate of the first set of gates has a first width in the second direction; and
each gate of the second set of gates has a second width in the first direction.

7. The integrated circuit of claim 6, wherein the first width is greater than the second width.

8. The integrated circuit of claim 6, wherein the first width is equal to the second width.

9. The integrated circuit of claim 7, wherein the first set of active regions comprises:
a first active region extending in the first direction and being overlapped by the first set of gates, the first active region having a third width in the second direction; and
a second active region extending in the first direction and being overlapped by the second set of gates, the second active region having a fourth width in the second direction, the third width being greater than the fourth width.

10. An integrated circuit comprising:
a first set of active regions extending in a first direction, and being on a first level of a substrate, the first set of active regions corresponding to a first transistor or a second transistor;
a first set of gates extending in a second direction different from the first direction, the first set of gates being on a second level different from the first level, the first set of gates overlapping the first set of active regions, and the first set of gates corresponds to a gate of the first transistor; and
a second set of gates extending in the second direction, being on the second level, overlapping the first set of active regions, and being separated from the first set of gates in the first direction, and the second set of gates corresponds to a gate of the second transistor; and
wherein each gate of the first set of gates is separated from an adjacent gate of the second set of gates in the second direction by a first pitch;
each gate of the second set of gates is separated from an adjacent gate of the second set of gates in the second direction by a second pitch different from the first pitch; and
each gate of the first set of gates is separated from an adjacent gate of the first set of gates in the second direction by a third pitch different from the first pitch and the second pitch.

11. The integrated circuit of claim 10, wherein
each gate of the first set of gates has a first length in the first direction;
each gate of the second set of gates has a second length in the first direction

12. The integrated circuit of claim 11, wherein the first length is less than the second length.

13. The integrated circuit of claim 12, wherein
each gate of the first set of gates has a first width in the second direction;
each gate of the second set of gates has a second width in the first direction.

14. The integrated circuit of claim 13, wherein the first width is greater than the second width.

15. The integrated circuit of claim 14, wherein the first transistor and the second transistor are coupled together in a cascode structure.

16. The integrated circuit of claim 15, wherein
the first transistor is configured in a common gate (CG) configuration, and
the second transistor is configured in a common source (CS) configuration.

17. The integrated circuit of claim 16, wherein the first set of active regions comprises:
a first active region extending in the first direction and being overlapped by the first set of gates, the first active region including a first set of fins, the first set of fins having a third width in a third direction different from the first direction and the second direction.

18. The integrated circuit of claim 17, wherein the first set of active regions further comprises:
a second active region extending in the first direction and being overlapped by the second set of gates, the second active region including a second set of fins, the second set of fins having a fourth width in the third direction, the third width being greater than the fourth width.

19. A method of fabricating an integrated circuit, the method comprising:
fabricating a first set of active regions of a first set of transistors, the first set of active regions being on a first level of a substrate, and extending in a first direction, and the first set of active regions corresponding to a first transistor of the first set of transistors;
fabricating a first set of gates of the first set of transistors, the first set of gates extending in a second direction different from the first direction, the first set of gates being on a second level different from the first level, the first set of gates overlapping the first set of active regions, and the first set of gates corresponding to the first transistor;
fabricating a second set of gates of the first set of transistors, the second set of gates extending in the second direction, the second set of gates being on the second level, the second set of gates overlapping the first set of active regions, and the second set of gates corresponding to the first transistor or a second transistor of the first set of transistors; and
electrically coupling a first set of conductors to the first set of gates, and a second set of conductors to the second set of gates,
wherein each gate of the first set of gates is separated from an adjacent gate of the second set of gates in the second direction by a first pitch; and
each gate of the second set of gates is separated from an adjacent gate of the second set of gates in the second direction by a second pitch different from the first pitch.

20. The method of claim 19, wherein
each gate of the first set of gates has a first length in the first direction;
each gate of the second set of gates has a second length in the first direction, and
the first length is less than the second length.
